(19) United States
(12) Patent Application Publication
(10) Pub. No.: US 2026/0245883 A1
(43) Pub. Date: Aug. 20, 2026

(54) SECONDARY BATTERY

(71) Applicant: SEMICONDUCTOR ENERGY LABORATORY CO., LTD., Atsugi-shi, Kanagawa-ken (JP)

(72) Inventors: Shotaro MURATSUBAKI, Hachioji, Tokyo (JP); Kazutaka KURIKI, Ebina, Kanagawa (JP); Yosiharu ASADA, Odawara, Kanagawa (JP); Yumiko YONEDA, Isehara, Kanagawa (JP); Yuya MIYASHITA, Isehara, Kanagawa (JP); Shunpei YAMAZAKI, Setagaya, Tokyo (JP)

(21) Appl. No.: 19/161,827

(22) PCT Filed: Mar. 25, 2024
(86) PCT No.: PCT/IB2024/052815

§ 371 Date: Sep. 3, 2025

(30) Foreign Application Priority Data
Mar. 30, 2023 (JP) 2023-055823
Jul. 7, 2023 (JP) 2023-112480
Oct. 16, 2023 (JP) 2023-178349

(51) Int. Cl. H01M 4/505; G01R 31/389; H01M 4/02; H01M 4/1315; H01M 4/525; H01M 4/583; H01M 10/0525; H01M 10/0569; H01M 10/42; H01M 50/417

(52) U.S. Cl. CPC H01M 4/505; G01R 31/389; H01M 4/1315; H01M 4/525; H01M 4/583; H01M 10/0525; H01M 10/0569; H01M 10/4285; H01M 50/417; H01M 2004/021; H01M 2004/027; H01M 2004/028; H01M 2300/0037

(57) ABSTRACT

A highly safe secondary battery is provided. The secondary battery includes a positive electrode and a negative electrode. The positive electrode includes a positive electrode active material. The positive electrode active material includes lithium cobalt oxide including magnesium. Magnesium concentration in a surface portion of the positive electrode active material is higher than magnesium concentration in an inner portion of the positive electrode active material. The negative electrode includes a negative electrode active material. The negative electrode active material includes a carbon material. The secondary battery is subjected to AC impedance measurement in a state where charging is performed until a voltage reaches 4.5 V, an AC impedance value at a frequency of 1 kHz is less than 90 mΩ.

### TECHNICAL FIELD

One embodiment of the present invention relates to a secondary battery. The present invention is not limited to the above field and relates to a semiconductor device, a display device, a light-emitting device, a power storage device, a lighting device, an electronic device, a vehicle, and manufacturing methods thereof. The secondary battery of one embodiment of the present invention can be used as a power supply necessary for the above semiconductor device, display device, light-emitting device, power storage device, lighting device, electronic device, and vehicle. Examples of the above electronic device include an information terminal device provided with the secondary battery. Examples of the above power storage device include a stationary power storage device.

### BACKGROUND ART

In recent years, demand for secondary batteries (also simply referred to as batteries) with high output and high capacity has rapidly grown and the secondary batteries are essential as repeatedly-usable energy sources in modern society.

It is said that secondary batteries can hardly be safe when having high capacity. A positive electrode active material having a layered rock-salt crystal structure used in a lithium-ion secondary battery, which includes two-dimensional lithium ion diffusion paths, is expected to enable high capacity, for example. However, the positive electrode active material having a layered rock-salt crystal structure has been disadvantageous in terms of safety because the crystal structure will be collapsed by excessive extraction of lithium ions at the time of charging, easily resulting in thermal runaway. To suppress an increase in battery temperature under abnormal conditions, e.g., at the time of nail penetration that is conducted in safety testing called a nail penetration test, Patent Document 1 proposes a structure in which a protective layer is provided between a positive electrode composite layer and a positive electrode current collector, for example.

Lithium cobalt oxide (LiCoO₂) is one of known positive electrode active materials with a layered rock-salt crystal structure. In lithium cobalt oxide, which has a layered rock-salt crystal structure, lithium ions can move two-dimensionally between layers composed of CoO₆ octahedrons, leading to favorable cycle performance. However, lithium cobalt oxide has a problem of a phase change due to charging and discharging. For example, a phase change from the hexagonal phase to the monoclinic phase occurs in lithium cobalt oxide when lithium ions are extracted to some extent at the time of charging. Thus, to use lithium cobalt oxide such that it enables favorable cycle performance, the amount of lithium ions to be extracted has been limited. Patent Documents 2 to 4, for example, propose structures for solving these problems, in which an additive element is added to lithium cobalt oxide.

In addition, a crystal structure of a positive electrode active material has also been studied (Non-Patent Document 1 to Non-Patent Document 4). As one example of methods used for analysis of the crystal structure of a positive electrode active material, XRD (X-ray diffraction) is given. Analysis can be performed with the use of the ICSD (Inorganic Crystal Structure Database) introduced in Non-Patent Document 5 for XRD. For example, the ICSD can be referred to for the lattice constant of the lithium cobalt oxide described in Non-Patent Document 6. For Rietveld analysis, the analysis program RIETAN-FP (Non-Patent Document 7) can be used, for example.

As image processing software, for example, ImageJ (Non-Patent Document 8 to Non-Patent Document 10) is known. Using this software makes it possible to analyze the shape of a positive electrode active material, for example.

In order to identify a crystal structure of a positive electrode active material, particularly a crystal structure in a surface portion, nanobeam electron diffraction is also effective. For analysis of electron diffraction patterns, an analysis program called ReciPro (Non-Patent Document 11) can be used, for example.

Fluorides such as fluorite (calcium fluoride) have been used as fusing agents in iron manufacture and the like for a very long time, and the physical properties of fluorides have been studied (Non-Patent Document 12).

Lithium-ion secondary batteries are known to enter thermal runaway after going through several states when the temperature increases during charging (Non-Patent Document 13).

Various researches and developments have been conducted for the reliability and safety of lithium-ion secondary batteries. For example, Non-Patent Document 14 shows the thermal stability of a positive electrode active material and an electrolyte solution.

### REFERENCES

### Patent Documents

[Patent Document 1] Japanese Published Patent Application No. 2019-129009
[Patent Document 2] Japanese Published Patent Application No. 2019-179758
[Patent Document 3] International Publication WO 2020/026078
[Patent Document 4] Japanese Published Patent Application No. 2020-140954

### Non-Patent Documents

[Non-Patent Document 1] Toyoki Okumura et al., “Correlation of lithium ion distribution and X-ray absorption near-edge structure in O3- and O2-lithium cobalt oxides from first-principle calculation”, Journal of Materials Chemistry, 2012, 22, pp. 17340-17348
[Non-Patent Document 2] Motohashi, T. et al., “Electronic phase diagram of the layered cobalt oxide system LiₓCoO₂ (0.0≤x≤1.0)”, Physical Review B, 80 (16); 165114
[Non-Patent Document 3] Zhaohui Chen et al., “Staging Phase Transitions in LiₓCoO₂”, Journal of The Electrochemical Society, 2002, 149 (12), A1604-A1609
[Non-Patent Document 4] G. G. Amatucci et al., “CoO₂, The End Member of the LiₓCoO₂ Solid Solution”, J. Electrochem. Soc., 143 (3), 1114 (1996)
[Non-Patent Document 5] Belsky, A. et al., “New developments in the Inorganic Crystal Structure Database (ICSD): accessibility in support of materials research and design”, Acta Cryst., (2002) B58 364-369.
[Non-Patent Document 6] Akimoto, J.; Gotoh, Y.; Oosawa, Y. “Synthesis and structure refinement of LiCoO₂ single crystals”, Journal of Solid State Chemistry (1998) 141, pp. 298-302
[Non-Patent Document 7] F. Izumi and K. Momma, Solid State Phenom., 130, 15-20 (2007)
[Non-Patent Document 8] Rasband, W. S., ImageJ, U. S. National Institutes of Health, Bethesda, Maryland, USA, http://rsb.info.nih.gov/ij/, 1997-2012.
[Non-Patent Document 9] Schneider, C. A., Rasband, W. S., Eliceiri, K. W., “NIH Image to ImageJ: 25 years of image analysis”, Nature Methods, 9, 671-675, 2012.
[Non-Patent Document 10] Abramoff, M. D., Magelhaes, P. J., Ram, S. J., “Image Processing with ImageJ”, Biophotonics International, volume 11, issue 7, pp. 36-42, 2004.
[Non-Patent Document 11] Seto, Y. & Ohtsuka, M., “ReciPro: free and open-source multipurpose crystallographic software integrating a crystal model database and viewer, diffraction and microscopy simulators, and diffraction data analysis tools” (2022) J. Appl. Cryst., 55.
[Non-Patent Document 12] W. E. Counts, R. Roy, and E. F. Osborn, “Fluoride Model Systems: II, The Binary Systems CaF₂—BeF₂, MgF₂—BeF₂, and LiF—MgF₂”, Journal of the American Ceramic Society, 36 [1], 12-17 (1953).
[Non-Patent Document 13] Nobuo Eda, “2-4: Mechanism of Heat Generation” in “Learning Charging and Discharging Techniques of Li Ion Battery from Data”, CQ Publishing Co., Ltd., Apr. 4, 2020, pp. 68-72
[Non-Patent Document 14] Shinya Kitano et al., GS Yuasa Technical Report, Vol. 2, No. 2, December 2015, pp. 18-24

### SUMMARY OF THE INVENTION

### Problems to be Solved by the Invention

The lithium cobalt oxide (LiCoO₂, also referred to as LCO) described in Patent Document 2 to Patent Document 4 is said to have low thermal stability. In a lithium-ion secondary battery, when an internal short circuit is caused by a nail penetration test, which is one of safety tests for a lithium-ion secondary battery, Joule heat is generated, leading to thermal runaway in some cases. Thus, in the case where lithium cobalt oxide described above is used, safety measures for a secondary battery are essential. Patent Document 1 discloses the structure in which a protective layer is provided between a positive electrode current collector and a positive electrode composite layer to suppress an increase in battery temperature at the time of nail penetration.

In view of the above, an object of one embodiment of the present invention is to provide a highly safe battery. Another object of one embodiment of the present invention is to provide a highly safe battery having high capacity.

Note that the description of these objects does not preclude the existence of other objects. One embodiment of the present invention does not necessarily achieve all these objects. Other objects can be derived from the description of the specification, the drawings, and the claims.

### Means for Solving the Problems

One embodiment of the present invention is a secondary battery including a positive electrode and a negative electrode. The positive electrode includes a positive electrode active material; the positive electrode active material includes lithium cobalt oxide including magnesium. A magnesium concentration in a surface portion of the positive electrode active material is higher than a magnesium concentration in an inner portion of the positive electrode active material. The negative electrode includes a negative electrode active material. The negative electrode active material includes a carbon material. When the secondary battery is subjected to AC impedance measurement in a state where charging is performed until a voltage reaches 4.5 V, an AC impedance value at a frequency of 1 kHz is less than 90 mΩ

Another embodiment of the present invention is a secondary battery including a positive electrode, a negative electrode, a separator, and an electrolyte. The positive electrode includes a positive electrode active material. The positive electrode active material includes lithium cobalt oxide including magnesium. The positive electrode includes a positive electrode active material. The positive electrode active material includes lithium cobalt oxide including magnesium. A magnesium concentration in a surface portion of the positive electrode active material is higher than a magnesium concentration in an inner portion of the positive electrode active material. The negative electrode includes a negative electrode active material. The negative electrode active material includes a carbon material. A solvent of the electrolyte includes ethylene carbonate and diethyl carbonate. The separator includes polypropylene. When the secondary battery is subjected to AC impedance measurement in a state where charging is performed until a voltage reaches 4.5 V, an AC impedance value at a frequency of 1 kHz is less than 90 mΩ.

Another embodiment of the present invention is a secondary battery including a positive electrode and a negative electrode. The positive electrode includes a positive electrode active material. The positive electrode active material includes lithium cobalt oxide including magnesium. A magnesium concentration in a surface portion of the positive electrode active material is higher than a magnesium concentration in an inner portion of the positive electrode active material. The negative electrode includes a negative electrode active material. The negative electrode active material includes a carbon material. When the secondary battery is subjected to AC impedance measurement in a state where charging is performed until a voltage reaches 4.5 V and capacitance is higher than or equal to 2000 mAh, an AC impedance value at a frequency of 1 kHz is less than 90 mΩ.

Another embodiment of the present invention is a secondary battery including a positive electrode, a negative electrode, a separator, and an electrolyte. The positive electrode includes a positive electrode active material. The positive electrode active material includes lithium cobalt oxide including magnesium. A magnesium concentration in a surface portion of the positive electrode active material is higher than a magnesium concentration in an inner portion of the positive electrode active material. The negative electrode includes a negative electrode active material. The negative electrode active material includes a carbon material. A solvent of the electrolyte includes ethylene carbonate and diethyl carbonate. The separator includes polypropylene. When the secondary battery is subjected to AC impedance measurement in a state where a voltage is charged to 4.5 V and capacity is higher than or equal to 2000 mAh, an AC impedance value at a frequency of 1 kHz is less than 90 mΩ.

In the above-described embodiment of the present invention, when the secondary battery is subjected to a nail penetration test, the nail diameter is 3 mm and the nail penetration speed is 5 mm/sec, a temperature rise ΔT of the secondary battery is preferably less than or equal to 50° C.

In the above-described embodiment of the present invention, lithium cobalt oxide preferably further includes aluminum.

In the above-described embodiment of the present invention, lithium cobalt oxide preferably further includes nickel.

In the above-described embodiment of the present invention, lithium cobalt oxide preferably further includes fluorine.

### Effect of the Invention

According to one embodiment of the present invention, a highly safe secondary battery can be provided. Moreover, according to one embodiment of the present invention, a highly safe secondary battery having high capacity can be provided.

Note that the description of these effects does not preclude the existence of other effects. One embodiment of the present invention does not need to have all these effects. Other effects will be apparent from and can be derived from the description of the specification, the drawings, the claims, and the like.

### BRIEF DESCRIPTION OF THE DRAWINGS

FIG. 1A and FIG. 1B are diagrams illustrating a nail penetration test.

FIG. 2A and FIG. 2B are diagrams illustrating operation of a nail penetration test.

FIG. 3 is a graph showing a change in the time of an internal temperature increase of a secondary battery in which an internal short circuit has occurred.

FIG. 4 is a graph showing a change at the time of an internal temperature increase of a secondary battery.

FIG. 5A to FIG. 5C show examples of cross-sectional structures of a positive electrode active material.

FIG. 6 is an example of a TEM image showing crystal orientations substantially aligned with each other.

FIG. 7A is an example of a STEM image showing crystal orientations substantially aligned with each other. FIG. 7B shows an FFT pattern of a region of a rock-salt crystal RS, and FIG. 7C shows an FFT pattern of a region of a layered rock-salt crystal LRS.

FIG. 8 is a diagram showing crystal structures of a positive electrode active material.

FIG. 9 is a diagram showing crystal structures of a conventional positive electrode active material.

FIG. 10 is a diagram illustrating the charge depth and the c-axis length of a positive electrode active material.

FIG. 11 is a diagram showing XRD patterns calculated from crystal structures.

FIG. 12 is a diagram showing XRD patterns calculated from crystal structures.

FIG. 13A and FIG. 13B are diagrams showing XRD patterns calculated from crystal structures.

FIG. 14A to FIG. 14C show lattice constants calculated using XRD.

FIG. 15A and FIG. 15B are cross-sectional views of a positive electrode active material.

FIG. 16A and FIG. 16B are diagrams illustrating a laminated secondary battery.

FIG. 17 is a phase diagram showing a relation between temperature and compositions of lithium fluoride and magnesium fluoride.

FIG. 18 is a diagram illustrating a result of DSC measurement.

FIG. 19A to FIG. 19C are diagrams showing methods for manufacturing a positive electrode active material.

FIG. 20A to FIG. 20C are diagrams showing methods for manufacturing a positive electrode active material.

FIG. 21 is a diagram showing a method for manufacturing a positive electrode active material.

FIG. 22A to FIG. 22C are diagrams showing methods for manufacturing a positive electrode active material.

FIG. 23 is a diagram illustrating a heating furnace and heating conditions.

FIG. 24A and FIG. 24B are diagrams illustrating a positive electrode.

FIG. 25A to FIG. 25C are diagrams illustrating a coin-type secondary battery.

FIG. 26A to FIG. 26D are diagrams each illustrating a cylindrical secondary battery.

FIGS. 27A and 27B are diagrams each illustrating a wound secondary battery.

FIG. 28 is a diagram illustrating a wound secondary battery.

FIG. 29A to FIG. 29D are diagrams each illustrating an electronic device.

FIG. 30A to FIG. 30C are diagrams each illustrating an electronic device.

FIG. 31A to FIG. 31C are diagrams each illustrating a vehicle.

FIG. 32A to FIG. 32C are graphs each showing charge and discharge curves.

FIG. 33A is a graph showing results of an impedance test, and FIG. 33B is a graph showing an equivalent circuit used for analysis.

FIG. 34A to FIG. 34C are photographs each showing a result of a nail penetration test.

FIG. 35A to FIG. 35C are graphs each showing a result of a nail penetration test.

FIG. 36A to FIG. 36C are graphs each showing a result of a nail penetration test.

FIG. 37A to FIG. 37C are graphs each showing a result of a nail penetration test.

FIG. 38A to FIG. 38C are graphs each showing a result of a nail penetration test.

### MODE FOR CARRYING OUT THE INVENTION

Examples of embodiments for carrying out the present invention will be described below with reference to the drawings and the like. Note that the present invention should not be interpreted as being limited to the examples of embodiments given below. Embodiments for carrying out the invention can be changed unless they deviate from the spirit of the present invention.

In this specification and the like, a space group is represented using the short notation of the international notation (or the Hermann-Mauguin notation). In addition, the Miller index is used for the expression of crystal planes and crystal orientations. In the crystallography, a bar is placed over a number in the expression of space groups, crystal planes, and crystal orientations; in this specification and the like, because of format limitations, space groups, crystal planes, and crystal orientations are sometimes expressed by placing “−” (a minus sign) in front of the number instead of placing a bar over the number. Furthermore, an individual direction which shows an orientation in a crystal is denoted with “[ ]”, a set direction which shows all of the equivalent orientations is denoted with “< >”, an individual plane which shows a crystal plane is denoted with “( )”, and a set plane having equivalent symmetry is denoted with “{ }”. A trigonal system represented by the space group R-3m is generally represented by a composite hexagonal lattice for easy understanding of the structure, and the space group R-3m is represented by a composite hexagonal lattice also in this specification and the like unless otherwise specified. In some cases, not only (hkl) but also (hkil) is used as the Miller index. Here, i is −(h+k).

In this specification and the like, the space group of a crystal structure of a positive electrode active material or the like is identified by an X-ray diffraction (XRD) method, electron diffraction, neutron diffraction, or the like. Thus, in this specification and the like, belonging to a space group, being attributed to a space group, or being a space group can be rephrased as being identified as a space group.

A structure is referred to as a cubic close-packed structure when three layers of anions are shifted and stacked like “ABCABC”. Accordingly, anions do not necessarily form a precise cubic lattice structure. At the same time, actual crystals always have a defect and thus, analysis results are not necessarily consistent with the theory. For example, in an electron diffraction pattern or an FFT (fast Fourier transform) pattern of a TEM (Transmission Electron Microscope) image or the like, a spot may appear in a position slightly different from a theoretical position. For example, anions can be regarded as forming a cubic close-packed structure when a difference in orientation from a theoretical position is 5° or less or 2.5° or less.

In this specification and the like, particles are not necessarily spherical (with a circular cross section). Other examples of the cross-sectional shapes of particles include an ellipse, a rectangle, a trapezoid, a triangle, a quadrilateral with rounded corners, and an asymmetrical shape, and a particle may have an indefinite shape.

In this specification and the like, the theoretical capacity of a positive electrode active material refers to the amount of electricity for the case where lithium that can be inserted and extracted in the positive electrode active material is all extracted. For example, the theoretical capacity of LiCoO₂ is 274 mAh/g per weight of the positive electrode active material, the theoretical capacity of LiNiO₂ is 275 mAh/g per weight of the positive electrode active material, and the theoretical capacity of LiMn₂O₄ is 148 mAh/g per weight of the positive electrode active material.

In this specification and the like, the remaining amount of lithium that can be inserted into and extracted from a positive electrode active material is represented by x in a composition formula, e.g., x in LiₓMO₂. Note that M represents a transition metal and Mis cobalt and/or nickel unless otherwise specified in this specification and the like. In the case of a positive electrode active material in a lithium-ion secondary battery, x=(theoretical capacity−charge capacity)/theoretical capacity (each capacity is per weight of the positive electrode active material) can be satisfied. For example, in the case where a lithium-ion secondary battery using LiMO₂ as a positive electrode active material is charged to 219.2 mAh/g per weight of the positive electrode active material, the positive electrode active material can be represented by Li_{0.2}MO₂, i.e., x=0.2. Note that “x in LiₓMO₂ is small” means, for example, 0.1<x≤0.24. In the case where lithium cobalt oxide almost satisfies the stoichiometric proportion, lithium cobalt oxide is LiCoO₂ and x=1. When lithium cobalt oxide is used in a positive electrode, in a secondary battery after its discharge ends, it can be said that lithium cobalt oxide is LiCoO₂ with x=1. Here, “discharge ends” means a state in which the voltage becomes 3.0 V or 2.5 V or lower to a current of 100 mA/g or lower per weight of the positive electrode active material, for example.

Charge capacity and/or discharge capacity used for calculation of x in LiₓMO₂ are/is preferably calculated under the conditions where there is no effect of a short circuit and/or no effect of decomposition of the electrolyte solution in the lithium-ion secondary battery or the effects are small. For example, data of a lithium-ion secondary battery, suffering from a sudden change of capacity that seems to result from a short circuit, should not be used for the calculation of x.

In this specification and the like, segregation of a certain element refers to a state in which, in a solid made of a plurality of elements (e.g., A, B, and C), a certain element (for example, A) is non-uniformly distributed.

In this specification and the like, the distribution of an element indicates that the element is successively detected by a given analysis method to the extent that the detection value is no longer on the noise level. A continuous change in the concentration of the element is referred to as a concentration gradient in some cases. A maximum value of the distribution is referred to as a peak in some cases. Note that when a peak is specified, distribution limited to a certain region can be referred to. The above-described distribution is not limited to normal distributions. In the case where the distribution corresponds to a normal distribution, the half width of the distribution can also be determined.

In this specification and the like, uneven distribution means that the concentration of an element in a certain region differs from that in another region. This is synonymous with deviation or a mixture of a high-concentration portion and a low-concentration portion. The state of being dissolved and unevenly distributed is referred to as segregation.

Note that in this specification and the like, a surface portion of a positive electrode active material is a region of less than or equal to 20 nm or less than or equal to 50 nm from a surface toward an inner portion in a direction perpendicular or substantially perpendicular to the surface. The surface portion is synonymous with the vicinity of a surface and a region in the vicinity of a surface. Note that “perpendicular” or “substantially perpendicular” specifically means that an angle between a direction and a surface is greater than or equal to 80° and less than or equal to 100°. The inner portion refers to a region that is at a larger depth than the surface portion of a positive electrode active material. The inner portion is synonymous with a bulk or a core.

In this specification and the like, a positive electrode active material is sometimes referred to as a composite oxide, a positive electrode member, a positive electrode material, a secondary battery positive electrode member, a lithium-ion secondary battery positive electrode member, or the like. In this specification and the like, the positive electrode active material of one embodiment of the present invention preferably includes a compound. In this specification and the like, the positive electrode active material of one embodiment of the present invention preferably includes a composition. In this specification and the like, the positive electrode active material of one embodiment of the present invention preferably includes a composite.

Although features of the positive electrode active material are described in this specification and the like, not all the positive electrode active materials included in the positive electrode necessarily have the features. When three or more of five or more randomly selected particles of the positive electrode active material have the features, for example, it can be said that an effect of improving the characteristics of the positive electrode active material and a secondary battery including the positive electrode active material is sufficiently obtained.

In this specification and the like, an internal short circuit of a lithium-ion secondary battery refers to contact between a positive electrode and a negative electrode in the battery. An external short circuit of a secondary battery refers to contact between a positive electrode and a negative electrode outside the battery on the assumption that the battery is misused. An internal short circuit of the secondary battery can be intentionally caused by a nail penetration test.

In this specification and the like, ignition in a nail penetration test refers to a state where fire is observed outside an exterior body within one minute of nail penetration or a state where thermal runaway of a secondary battery has occurred within one minute of nail penetration. For example, a state where a positive electrode and/or a negative electrode are/is observed at a position that is more than or equal to 2 cm away from a penetration point after a nail penetration test is completed is referred to as a state where thermal runaway has occurred. The positive electrode and/or the negative electrode includes, for example, an aluminum oxide formed by oxidation of aluminum of a positive electrode current collector when an aluminum foil is used or copper oxide formed by oxidation of copper of a negative electrode current collector when a copper foil is used. A state where fire, a spark, and/or smoke that are/is observed remain(s) at a penetration point in a nail penetration test, i.e., fire does not spread, and thermal runaway of a secondary battery does not occur is not referred to as ignition. For example, a secondary battery that does not suffer from the above ignition even after undergoing a nail penetration test can be regarded as a secondary battery that does not ignite.

Note that in this specification and the like, the description is made on the assumption that materials (such as a positive electrode active material, a negative electrode active material, an electrolyte solution, and a separator) of a secondary battery have not deteriorated unless otherwise specified. A decrease in charge capacity and/or discharge capacity due to aging treatment and burn-in treatment during the manufacturing process of the secondary battery is not regarded as deterioration. For example, the case where discharge capacity is higher than or equal to 97% of the rated capacity of a secondary battery composed of a cell or an assembled battery can be regarded as a non-deteriorated state. The rated capacity conforms to JIS C 8711:2019 in the case of a secondary battery for a portable device. The rated capacity of other secondary batteries conform to JIS described above, JIS for electric vehicle propulsion, industrial use, and the like, standards defined by IEC, and the like.

In this specification and the like, a lithium-ion secondary battery refers to a battery in which lithium ions are used as carrier ions; however, carrier ions in the present invention are not limited to lithium ions. For example, as the carrier ions in the present invention, alkali metal ions or alkaline earth metal ions can be used; specifically, sodium ions or the like can be used. In that case, the present invention can be understood by replacing lithium ions with sodium ions or the like. Furthermore, in the case where there is no limitation on carrier ions, the term “secondary battery” is sometimes used.

In this specification and the like, the (001) plane, the (003) plane, and the like are sometimes collectively referred to as the (001) plane. The (001) plane is sometimes referred to as a C-plane, a basal plane, or the like. In lithium cobalt oxide, lithium ions have a two-dimensional diffusion path. That is, it can be said that the diffusion path of lithium ions exists along a plane. In this specification and the like, a plane where the diffusion path of lithium ions is exposed, i.e., a where lithium is inserted and extracted (specifically a plane other than the (001) plane), is sometimes referred to as an edge plane.

In this specification and the like, the loading level refers to the weight of a negative electrode active material per unit surface area of a negative electrode current collector. The loading level of a negative electrode active material can be adjusted in accordance with the capacity of a positive electrode. The above loading level is regarded as a loading level per surface of a current collector in the case where slurry including an active material is applied onto both surfaces of the current collector.

In this specification and the like, a secondary particle refers to a particle formed by aggregation of primary particles. In this specification and the like, a single particle refers to a particle whose appearance shows no grain boundary. In this specification and the like, a single crystal particle refers to a crystal whose inner portion has no grain boundary, whereas a polycrystal particle refers to a crystal particle whose inner portion has a grain boundary. A polycrystal particle may be regarded as a group of a plurality of crystallites, and a grain boundary may be regarded as an interface existing between two or more crystallites.

In this specification and the like, the phrase “A and/or B” is an example of an expression that comprehends only A, only B, and A and B.

### Embodiment 1

In a nail penetration test, a nail having a predetermined diameter in the range of 2 mm to 20 mm penetrates a secondary battery in a fully charged state at a predetermined speed. Fully charged refers to a state where the charge rate represented by Sate Of Charge (hereinafter referred to as SOC) is 100%. In this embodiment, first, a nail penetration test device will be described.

### <Nail Penetration Test Device>

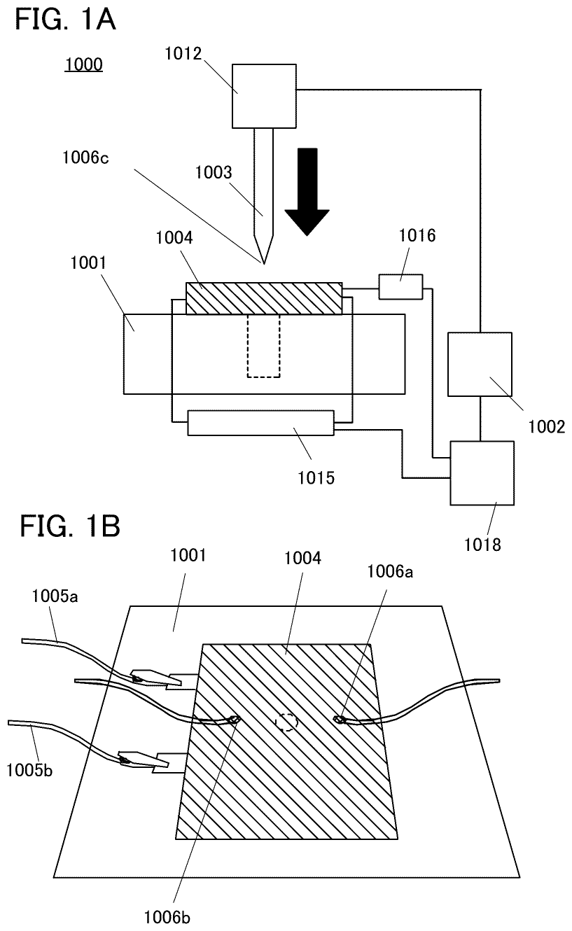

FIG. 1A is a cross-sectional view of a nail penetration test device 1000. The nail penetration test device 1000 includes a stage 1001, a driving portion 1002, a nail 1003, a voltage measuring device 1015, a temperature measuring device 1016, and a control portion 1018. The driving portion 1002 includes a driving mechanism 1012 for moving the nail 1003 in the arrow direction shown in the diagram. The driving mechanism 1012 operates so as to make the nail 1003 penetrate a secondary battery 1004 provided on the stage 1001. At this time, the secondary battery 1004 is in a fully charged state, and this operation is referred to as a nail penetration operation. Note that the dashed line in FIG. 1A indicates a concave portion of the stage 1001 for holding the nail 1003 that has penetrated the secondary battery 1004 in the nail penetration operation.

Data on the voltage of the secondary battery during the nail penetration operation is transmitted from the voltage measuring device 1015 to the control portion 1018. Specifically, the amount of change in voltage and the like are transmitted to the control portion 1018. Data on the temperature during the nail penetration operation is transmitted from the temperature measuring device 1016 to the control portion 1018. To control operation conditions of the nail 1003, the control portion 1018 can transmit a control signal to the driving portion 1002.

FIG. 1B is a perspective view illustrating the upper portion of the stage 1001 of the nail penetration test device 1000 and the vicinity of the upper portion. The secondary battery 1004 provided on the stage 1001 is electrically connected to a wiring 1005a and a wiring 1005b. The wiring 1005a and the wiring 1005b belong to the voltage measuring device 1015, and the wiring 1005a and the wiring 1005b are electrically connected to a positive electrode side tab and a negative electrode side tab of the secondary battery 1004, so that the voltage of the secondary battery 1004 can be measured. The voltage of the secondary battery 1004 is simply referred to as a voltage, or is referred to as a voltage value between positive and negative electrodes, a battery voltage, a cell voltage, or an open-circuit voltage. In the case where a temperature sensor 1006 is used as the temperature measuring device 1016, the temperature sensor is provided to be in contact with a surface of an exterior body of the secondary battery 1004.

Although FIG. 1B illustrates an example in which a first temperature sensor 1006a and a second temperature sensor 1006b are placed in the secondary battery 1004, and a third temperature sensor 1006c is further provided in the secondary battery 1004, one or three or more temperature sensors may be placed in the nail 1003 illustrated in FIG. 1A. In the secondary battery 1004, the first temperature sensor 1006a is provided on a side where the wiring 1005a and the wiring 1005b are not placed, and the second temperature sensor 1006b is provide on a side where the wiring 1005a and the wiring 1005b are placed. It is preferable to provide two or more temperature sensors in such a manner because in the case where one temperature sensor cannot be used owing to expansion of the exterior body or the like, at least one other temperature sensors can be used.

The side where the wiring 1005a and the wiring 1005b are placed has an adhesive region, whereas the side where the wiring 1005a and the wiring 1005b are not placed does not have the above adhesive region because the exterior body is bent at the latter side. This structure is preferable because it would inhibit expansion at the side where the wiring 1005a and the wiring 1005b are not placed if the exterior body expands, making the first temperature sensor 1006a less likely to be peeled off than the second temperature sensor 1006b.

The dashed line ellipse in FIG. 1B is a region in which the nail 1003 penetrates the secondary battery 1004 in the nail penetration operation. It is preferable that the first temperature sensor 1006a and the second temperature sensor 1006b provided in the secondary battery 1004 be provided in the regions that are equidistant from the region in which the nail 1003 penetrates the secondary battery. Typically, the first temperature sensor 1006a and the second temperature sensor 1006b are provided preferably less than or equal to 5 cm away from the region in which the nail 1003 penetrates the secondary battery, further preferably less than or equal to 2 cm away from the region. The provision of the sensor in such a manner is preferable because a temperature change in a region in which the nail 1003 penetrates and the vicinity thereof can be monitored. Here, the vicinity refers to a region that is within 1 cm from the region which the nail 1003 penetrates. Note that in the case where two or more temperature sensors are placed, the nail penetration operation is preferably started after it is verified that the difference between the temperatures shown by both temperature sensors is less than or equal to ±5° C., preferably less than or equal to ±2° C.

### <Secondary Battery in Nail Penetration Test>

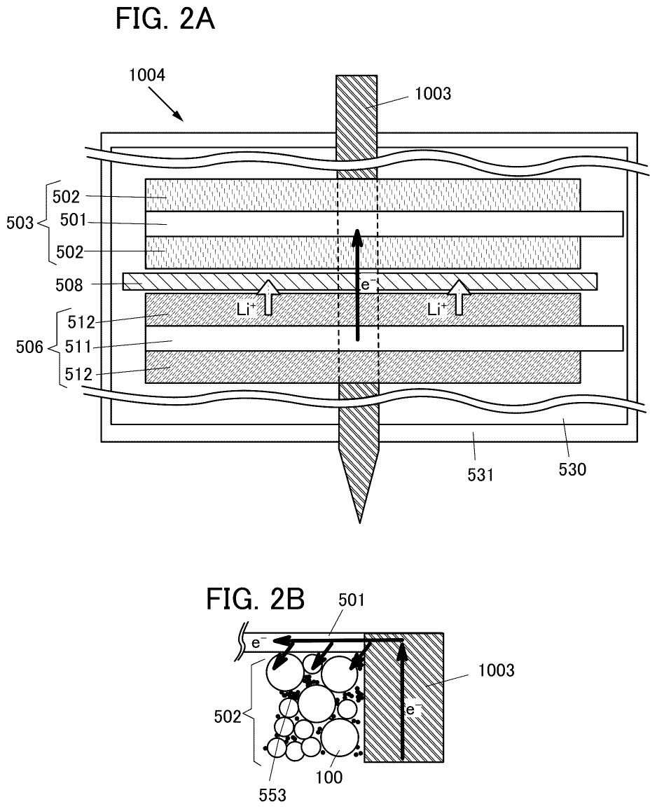

Next, the state of the secondary battery in the nail penetration test is described anew with reference to FIG. 2A, FIG. 2B, and the like. In the nail penetration test, the nail 1003 penetrates the secondary battery 1004 that is in a fully charged state at a predetermined speed. The diameter of the nail 1003 is greater than or equal to 2 mm and less than or equal to 10 mm. FIG. 2A illustrates a cross-sectional view of the state where the nail 1003 penetrates the secondary battery 1004. The secondary battery 1004 has a structure in which a positive electrode 503, a separator 508, a negative electrode 506, and an electrolyte solution 530 are held in an exterior body 531. The positive electrode 503 includes a positive electrode current collector 501 and positive electrode active material layers 502 formed on both surfaces of the positive electrode current collector 501, and the negative electrode 506 includes a negative electrode current collector 511 and negative electrode active material layers 512 formed on both surfaces of the negative electrode current collector 511. The positive electrode active material layer is at least a layer including a positive electrode active material, and includes a conductive material and/or a binder, for example. The negative electrode active material layer is at least a layer including a negative electrode active material, and includes a conductive material and/or a binder, for example. FIG. 2B illustrates an enlarged view of the nail 1003 and the positive electrode current collector 501 and the vicinity thereof, where a positive electrode active material 100 and a conductive material 553 included in the positive electrode active material layer 502 are clearly shown.

As illustrated in FIG. 2A and FIG. 2B, when the nail 1003 is sticked into the secondary battery 1004, or specifically, when the nail 1003 penetrates the positive electrode 503 and the negative electrode 506, an internal short circuit occurs. This makes the potential of the nail 1003 equal to the potential of the negative electrode 506, so that an electron (e) flows to the positive electrode 503 through the nail 1003 and the like as indicated by the black arrows, and Joule heat is generated in the portion of the internal short circuit and the vicinity thereof. Due to the internal short circuit, carrier ions extracted from the negative electrode 506, typically lithium ions (Li⁺), are released into the electrolyte solution as indicated by the white arrows. Note that since the temperature of the secondary battery rises rapidly owing to the Joule heat generated by the internal short circuit, the reductive decomposition of the electrolyte solution starts to occur on the negative electrode surface before all the lithium ions are released from the negative electrode. This is one of electrochemical reactions and is referred to as a reduction reaction of an electrolyte solution by a negative electrode.

In the case where the Joule heat increases the temperature of the secondary battery 1004 and lithium cobalt oxide is used as the positive electrode active material, the lithium cobalt oxide sometimes undergoes a phase change (i.e., a structural change) to an H1-3 type crystal structure or an O1 type crystal structure to generate heat due to the phase change. The H1-3 type structure and the O1 type structure will be described later. An internal short circuit causes heat generation one after another.

Then, as illustrated in FIG. 2A and FIG. 2B, the electron (e) that flows to the positive electrode 503 reduces Co, which is tetravalent in the lithium cobalt oxide in the charged state, to trivalent or divalent Co, and oxygen is released from the lithium cobalt oxide by this reduction reaction. An oxidation reaction due to the oxygen further decomposes the electrolyte solution 530. This is one of electrochemical reactions and is referred to as an oxidation reaction of an electrolyte solution by a positive electrode. The speed at which current flows into the positive electrode active material 100 and the like is considered to have an effect on the above electrochemical reaction, and the speed at which current flows can be delayed depending on the insulating property of the positive electrode active material.

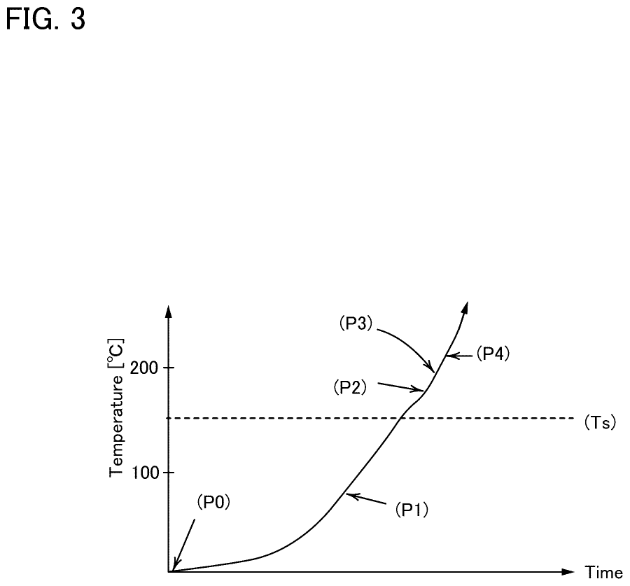

As described above, when an internal short circuit occurs in the secondary battery, it is considered that the temperature changes as shown in FIG. 3. FIG. 3 is the graph cited from [FIG. 2-12] on page 70 of Non-Patent Document 13, which is partly retouched and is a graph of the temperature (specifically, the internal temperature) of a secondary battery with respect to time. When an internal short circuit occurs at (P0), the temperature of the secondary battery rises with time. As shown in (P1), the Jouele heat generation continues until the temperature of the secondary battery reaches 100° C. and the vicinity thereof, exceeding the reference temperature (Ts). Then, reduction of an electrolyte solution by a negative electrode (the negative electrode is C₆Li when graphite is used) and heat generation are caused at (P2), oxidation of the electrolyte solution by a positive electrode and heat generation are caused at (P3), and heat generation due to thermal decomposition of the electrolyte solution is caused at (P4). Accordingly, the secondary battery enters thermal runaway, resulting in ignition.

### <Thermal Runaway of Secondary Battery>

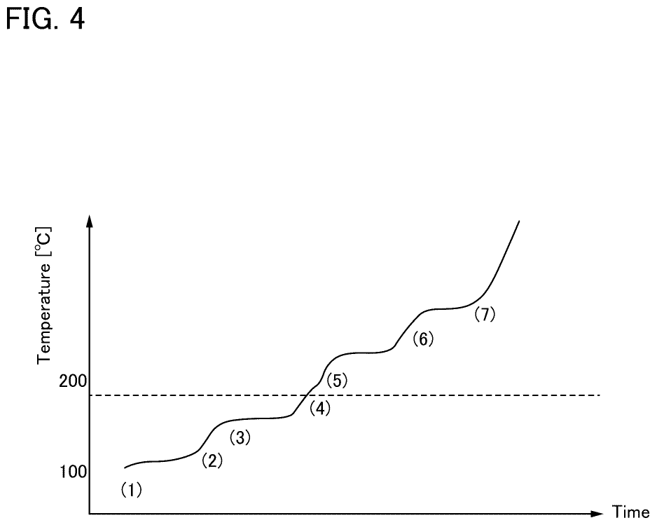

The mechanism of thermal runaway of a secondary battery is described with reference to FIG. 4 showing a graph cited from [FIG. 2-11] on page 69 of Non-Patent Document 13, which is partly retouched. A secondary battery as described above enters thermal runaway after passing through several states when the temperature (specifically, the internal temperature) increases during charging, for example. FIG. 4 is a graph showing the temperature of a secondary battery with respect to time. When the temperature of the secondary battery reaches 100° C. or the vicinity thereof, for example, (1) collapse of a SEI (Solid Electrolyte Interphase) of a negative electrode and heat generation are caused. When the temperature of the secondary battery exceeds 100° C., (2) reduction of an electrolyte solution by the negative electrode (the negative electrode is C₆Li when graphite is used) and heat generation are caused, and (3) oxidation of the electrolyte solution by a positive electrode and heat generation are caused at 150° C. and the vicinity thereof. When the temperature of the secondary battery reaches 180° C. or the vicinity thereof, (4) thermal decomposition of the electrolyte solution is caused and (5) oxygen release from the positive electrode and thermal decomposition of the positive electrode (the thermal decomposition includes a structural change in a positive electrode active material) are caused from the positive electrode. After that, when the temperature of the secondary battery exceeds 200° C., (6) decomposition of the negative electrode is caused, and finally, (7) the positive electrode and the negative electrode come into direct contact with each other. The secondary battery enters thermal runaway after passing through such states, specifically the state (5), the state (6), or the state (7).

To prevent thermal runaway, it is probably preferable that an increase in the temperature of the secondary battery be inhibited and the negative electrode, the positive electrode, and/or the electrolyte solution have stable characteristics at high temperatures. The structure that inhibits an increase in the temperature can be regarded as having a structure in which a current flows to the positive electrode active material at a low speed. The structure in which the positive electrode exhibits stable characteristics at high temperatures includes, specifically, a structure in which the positive electrode active material 100 releases no oxygen at high temperatures. In that case, a significant effect that thermal runaway is less likely to occur and thus ignition or the like is less likely to occur in the secondary battery can be obtained. As described later, the positive electrode active material 100 of one embodiment of the present invention can have both the above stable structure and the above structure in which a current flows at a low speed.

### [Positive Electrode Active Material]

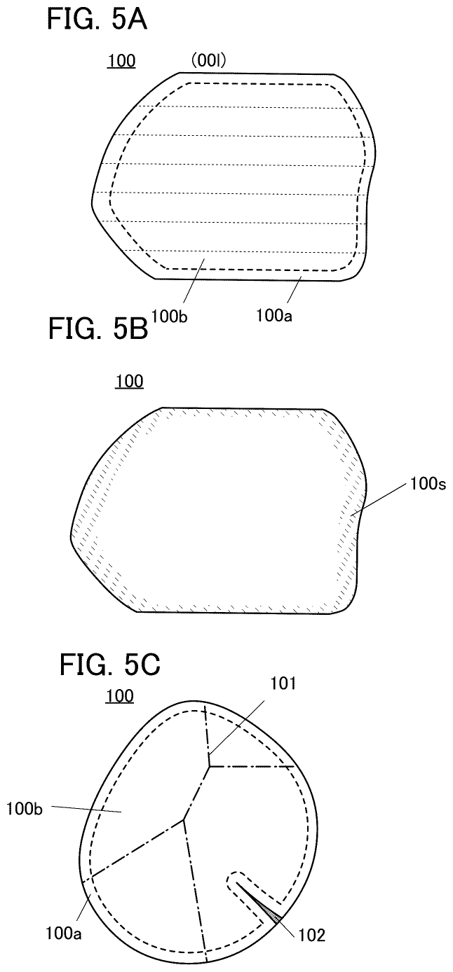

The positive electrode active material 100 of one embodiment of the present invention is described. As the positive electrode active material 100, a compound which includes oxygen and a transition metal, into and from which carrier ions, typically lithium ions (Li⁺), can be inserted and extracted, is used. As the transition metal, one or two or more selected from cobalt (Co), nickel (Ni), manganese (Mn), iron (Fe), and the like can be used. FIG. 5A illustrates an example of a cross-sectional structure of the positive electrode active material 100. The positive electrode active material 100 includes a surface portion 100a and an inner portion 100b, and the (00l) plane where lithium ions diffuse is denoted by a dashed line.

### <Main Component>

It is preferable that the positive electrode active material 100 of one embodiment of the present invention use cobalt as the main component of the transition metal M taking part in an oxidation-reduction reaction. In this specification and the like, the main component of the transition metal M refers to the component having the highest atomic ratio among the transition metal M. For example, as a compound in which Co is used as the transition metal, lithium cobalt oxide can be used for the positive electrode active material 100. Alternatively, the positive electrode active material 100 preferably includes lithium cobalt oxide (LiCoO₂) to which a later-described additive element is added. Note that the positive electrode active material 100 of one embodiment of the present invention preferably has a crystal structure described later. Thus, the composition of the lithium cobalt oxide is not strictly limited to Li:Co:O=1:1:2.

The positive electrode active material 100 of one embodiment of the present invention preferably includes a region having an insulating property or a region having high resistance. It is preferable that the above region have a narrow width of greater than or equal to 1 nm and less than or equal to 20 nm, further preferably greater than or equal to 2 nm and less than or equal to nm, still further preferably greater than or equal to 2 nm and less than or equal to 5 nm in a cross-sectional view of the positive electrode active material 100. The narrow region is sometimes referred to as a “shell” in this specification and the like. For the above cross-sectional view, a cross-sectional STEM (Scanning Transmission Electron Microscope) image can be used.

In a positive electrode active material at the nail penetration test, a reaction occurs in which electrons rapidly flowing into the positive electrode active material reduce cobalt in the tetravalence state to cobalt in the divalent state, whereby oxygen is released from the positive electrode active material. This reaction, which is an exothermic reaction, accelerates thermal runaway. In order to inhibit the above reaction, for example, the positive electrode active material 100 of the present invention has a structure in which a shell 100s described later inhibits oxygen release. When oxygen is not released from the positive electrode active material, the above reduction reaction (e.g., the reaction in which Co⁴⁺ becomes Co²⁺) is inhibited.

FIG. 5B illustrates the positive electrode active material 100 that includes the shell 100s. The positive electrode active material 100 including the shell 100s has increased resistance, in which case the speed of current flowing into the positive electrode active material 100 can be low even when a nail penetration test is performed, so that ignition or the like can be inhibited; thus, it is preferable. The shell 100s having high resistance is preferably positioned on the surface portion 100a of the positive electrode active material 100 so as to reduce the speed of current flowing into the positive electrode active material 100.

### <Additive Element>

The positive electrode active material 100 preferably includes an additive element. Examples of the added element include magnesium, fluorine, nickel, aluminum, titanium, zirconium, vanadium, iron, manganese, chromium, niobium, arsenic, zinc, silicon, sulfur, phosphorus, boron, bromine, and beryllium, and one or two or more selected from these additive elements are preferably used.

Note that as the additive element, magnesium, fluorine, nickel, aluminum, titanium, zirconium, vanadium, iron, manganese, chromium, niobium, arsenic, zinc, silicon, sulfur, phosphorus, boron, bromine, and beryllium is not necessarily included. When manganese is substantially absent in the positive electrode active material 100, for example, the above advantages such as relatively easy synthesis, easy handling, and excellent cycle performance are enhanced. The weight of manganese included in the positive electrode active material 100 is preferably less than or equal to 600 ppm, further preferably less than or equal to 100 ppm, for example.

Magnesium is one of the elements suitable for forming the shell 100s. Specifically, magnesium is suitable as the additive element inhibiting release of oxygen because oxygen closer to magnesium requires higher energy for release. Magnesium is suitable as the additive element because it has a function of stabilizing the crystal structure of the positive electrode active material. Magnesium can keep the crystal structure stable while making the speed of current flowing into the positive electrode active material 100 low.

Magnesium is preferably present within a region with a narrow width of greater than or equal to 1 nm and less than or equal to 20 nm, further preferably greater than or equal to 2 nm and less than or equal to 10 nm, still further preferably greater than or equal to 2 nm and less than or equal to 5 nm from the surface in a cross-sectional view of the positive electrode active material 100. Magnesium is preferably present in the shell 100s on the edge plane, in a larger amount, i.e., at a higher concentration than in the shell 100s on the basal plane.

The shell 100s includes at least magnesium, whereby release of oxygen from this region is inhibited and thermal stability is improved; thus, it can be said that this structure inhibits thermal runaway. Thus, although the shell 100s is preferably provided to sufficiently cover the entire positive electrode active material 100 as illustrated in FIG. 5A, the shell 100s is preferably formed in a region that is higher than or equal to 60%, further preferably higher than or equal to 80% of the positive electrode active material 100 in the cross-sectional view. Furthermore, the uniform shell 100s is preferably formed; however, a specific region of the positive electrode active material 100, e.g., a surface other than the (00l) plane, may be formed to have a large thickness.

However, as long as ignition does not occur in the nail penetration test, the shell 100s may be provided anywhere in the positive electrode active material 100; as long as insertion and extraction of lithium ions (Li⁺) are allowed and the speed at which current flows owing to an internal short circuit can be made lower, magnesium may be present in a portion other than the shell 100s, e.g., magnesium may be present in the inner portion 100b.

Furthermore, in consideration of rapid charge and discharge or the like, a region where the shell 100s is not provided is preferably provided in the positive electrode active material 100 in some cases.

In the case where magnesium is added to the positive electrode active material 100, magnesium fluoride can be suitably used as a magnesium source. When magnesium fluoride is used, fluorine can also be added to the positive electrode active material 100. That is, the positive electrode active material 100 preferably includes fluorine in addition to magnesium as the additive elements in some cases. Although lithium and fluorine sometimes react with each other in a nail penetration test or the like, the amount of generated heat can be smaller than that in the case where lithium reacts with oxygen; thus, an increase in the temperature of the secondary battery can be inhibited.

In some cases, nickel is preferably included in addition to magnesium as the additive elements of the positive electrode active material 100 of one embodiment of the present invention.

In other words, it is preferable that nickel also be present in the shell 100s. Nickel is preferably present in the shell 100s on the edge plane, in a larger amount, i.e., at a higher concentration than in the shell 100s on the basal plane. This structure can inhibit release of oxygen from the positive electrode active material or a structural change of the positive electrode active material.

Note that each of the above-described additive elements is preferably present in at least the shell 100s. In other words, at least the above-described additive element is preferably present in the surface portion 100a. The additive element contributing to the stability of the crystal structure of the positive electrode active material 100 is preferably present in the surface portion 100a, in which degradation is likely to start. The additive element is preferably present in the shell 100s on the edge plane, in a larger amount, i.e., at a higher concentration than in the shell 100s on the basal plane.

As a method for confirming whether the shell 100s is formed in the positive electrode active material 100, the resistivity of the powder (referred to as powder resistivity) to be the positive electrode active material is measured. In the case where the shell 100s is formed in the positive electrode active material 100, the powder resistivity value is greater than that in the case where the shell 100s is not formed. Typically, the shell 100s is presumed to be formed in the positive electrode active material 100 when the powder resistivity of the positive electrode active material including the additive element has a larger value than the powder resistivity of the positive electrode active material devoid of the additive element.

The shell 100s preferably includes cobalt in addition to the additive element. When at least the shell 100s includes cobalt, lithium ions (Li⁺) can be inserted and extracted. In addition, the shell 100s can reduce the speed at which a current flows owing to an internal short circuit. In terms of allowing insertion and extraction of lithium ions (Li⁺), the surface portion 100a also preferably includes the additive element and cobalt.

For example, the magnesium concentration is preferably higher than 0 and lower than or equal to 10 atomic %, further preferably higher than 0 and lower than or equal to 5 atomic %, still further preferably higher than 0 and lower than or equal to 2 atomic % in the shell 100s of lithium cobalt oxide. The above magnesium concentration can be specified by line analysis by energy dispersive X-ray spectroscopy (EDX), for example. Magnesium being present at a high concentration in the whole surface portion 100a would enhance the insulating property, making it difficult to achieve favorable battery characteristics in a charge and discharge cycle test or the like. Meanwhile, magnesium is preferably present at an appropriate concentration in an appropriate region especially as the shell 100s in the surface portion 100a, in which case the lithium cobalt oxide can be stabilized and ignition and the like in the above-described nail penetration test or the like can be inhibited. In addition, magnesium being present at an appropriate concentration in the shell 100s is expected to increase the hardness of the lithium cobalt oxide.

FIG. 5C illustrates the positive electrode active material 100 including a crystal grain boundary 101. The crystal grain boundary 101 refers to, for example, a portion where particles of the positive electrode active material 100 adhere to each other or a portion where a crystal orientation changes inside the positive electrode active material 100, i.e., a portion where repetition of bright lines and dark lines is discontinuous in a STEM image or the like, a portion including a large number of crystal defects, a portion with a disordered crystal structure, or the like. A crystal defect refers to a defect that can be observed in a cross-sectional TEM image, a cross-sectional STEM image, or the like, i.e., a structure including another atom between lattices, a cavity, or the like. The crystal grain boundary 101 can be regarded as one of plane defects. The vicinity of the crystal grain boundary 101 refers to a region of less than or equal to 10 nm from the crystal grain boundary 101.

FIG. 5C illustrates the positive electrode active material 100 including a crack 102. The crack 102 may include a region with a shifted crystal plane or a region cracked at a crystal plane, and is often generated along the (001) plane. It is preferable that the above-described crack 102 not be observed, but the crack 102 may be included as long as ignition or the like does not occur in the nail penetration test. As a structure in which ignition does not occur in the nail penetration test, a shell is preferably formed also in the surface portion newly formed when the crack 102 is generated. The vicinity of the crack 102 refers to a region within 10 nm from the crack 102.

### <Crystallinity>

The positive electrode active material 100 preferably has high crystallinity and is further preferably a single crystal or a polycrystal. It is particularly preferable that the positive electrode active material 100 include a single crystal, in which case a crack is unlikely to be generated even when the volume of the positive electrode active material 100 is changed due to charging and discharging. In other words, when the positive electrode active material 100 is a single crystal, a secondary battery using the positive electrode active material 100 is presumably unlikely to ignite and can have a high level of safety. The positive electrode active material 100 is preferably subjected to the later-described initial heating to have high crystallinity. The positive electrode active material 100 is preferably a single-particle (also referred to as a primary particle) rather than a secondary particle.

### <Median Diameter (D50) of Positive Electrode>

The median diameter (D50) of the positive electrode active material included in the highly-safe secondary battery is described. When the positive electrode active material is too small, application might be difficult to perform in the manufacture of the positive electrode. Alternatively, when the positive electrode active material is too small, the surface area becomes too large, which might cause an excessive reaction between a positive electrode active material surface and an electrolyte. Alternatively, when the positive electrode active material is too small, a large amount of conductive material sometimes needs to be mixed, which might lead to a decrease in capacity. In view of these, the median diameter (D50) of the positive electrode active material is preferably greater than or equal to 1 μm, further preferably greater than or equal to 5 μm, still further preferably greater than or equal to 9 μm. The positive electrode active material with a small median diameter (D50) is preferable because a shifted region is unlikely to be generated. The positive electrode active material with a small median diameter (D50) is preferable because a crack is unlikely to be caused even after pressing step.

However, there is a concern that only active materials with too small a median may cause a reduction of the density of the positive electrode active material layer or the promotion of a side reaction with the electrolyte solution, for example. In view of this, the median diameter (D50) of the positive electrode active material is preferably less than or equal to 20 μm, further preferably less than or equal to 18 μm, still further preferably less than or equal to 15 μm.

The above upper limits and the above lower limits of the median diameter (D50) of the positive electrode active material can be combined freely. For example, the above median diameter is greater than or equal to 1 μm and less than or equal to 20 μm, preferably greater than or equal to 1 μm and less than or equal to 18 μm, further preferably greater than or equal to 1 μm and less than or equal to 15 μm.

Note that above-described median diameter (D50) can be measured by observation using a SEM or a TEM or with a particle size distribution analyzer using a laser diffraction and scattering method, for example. When measured with a particle size distribution analyzer or the like using a laser diffraction and scattering method, the median diameter (D50) is the particle diameter when the cumulative amount is 50% in a cumulative curve obtained as a result of the particle size distribution measurement. Note that in a method for measuring the median diameter (D50) by analysis with a SEM, a TEM, or the like, for example, 20 or more particles are measured to make a cumulative curve, and a particle diameter when the accumulated amount accounts for 50% is obtained.

### <Surface of Positive Electrode Active Material>

The surface of the positive electrode active material 100 refers to a surface of a composite oxide including the surface portion 100a and the inner portion 100b. Such a surface can be observed in a cross section. Thus, the surface of the positive electrode active material 100 does not include a material to which a metal oxide that does not include a lithium site contributable to charging and discharging, such as aluminum oxide (Al₂O₃), is attached, and a carbonate, a hydroxy group, and the like which are chemically adsorbed after formation of the positive electrode active material. The attached metal oxide refers to, for example, a metal oxide having a crystal structure different from that of the inner portion 100b.

Since the positive electrode active material 100 is a composite oxide including oxygen and a transition metal into and from which lithium can be inserted and extracted, an interface between a region where oxygen and the transition metal M (e.g., Co, Ni, Mn, or Fe) that is oxidized or reduced due to insertion and extraction of lithium are present and a region where oxygen and the transition metal M are absent is considered as the surface of the positive electrode active material. When the positive electrode active material is analyzed, a protective film is attached on its surface in some cases; however, the protective film is not included in the positive electrode active material. As the protective film, a single-layer film or a multilayer film of carbon, a metal, an oxide, a resin, or the like is sometimes used.

Thus, a reference point in STEM-EDX line analysis or the like is a point that is 50% of the average value M_{AVE} of the detected amounts of the characteristic X-ray of the transition metal M in the positive electrode active material. In the case where the left side of the reference point is referred to as the outside of the positive electrode active material and the right side of the reference point is referred to as the inner portion of the positive electrode active material, the reference point is referred to as the position of the surface of the positive electrode active material in some cases. In STEM-EDX line analysis or the like, in the case where the detected amount of the characteristic X-ray of the transition metal M does not sufficiently decrease at the left side of the reference point, the detected amount of the characteristic X-ray of the transition metal M on the left side of the reference point is referred to as a background, and the reference point can be a point that is 50% of the sum of the average value M_{BG} of the detected amounts of the characteristic X-ray of the transition metal M of the background and the average value M_{AVE} of the detected amounts of the characteristic X-ray of the transition metal M in the inner portion in some cases. Instead of the transition metal M, the detected amount of characteristic X-rays of oxygen in the positive electrode active material may be used, in which case the reference point can be obtained by replacing the transition metal M with oxygen. Note that since oxygen is an element that is easily influenced by the outside of the positive electrode active material, the reference point is preferably calculated from 50% of the average value M_{AVE} of the detected amounts of characteristic X-ray of the transition metal M. In the case where the position of the reference point of 50% of the average value M_{AVE} of the detected amounts of the characteristic X-ray of the transition metal M in the inner portion and that of 50% of the average value M_{AVE} of the detected amounts of the characteristic X-ray of oxygen in the inner portion are different from each other, there is probably an influence of a metal oxide including oxygen, a carbonate, or the like attached to the surface of the positive electrode active material; thus, a point that is 50% of the average value M_{AVE} of the detected amounts of the characteristic X-ray of the inner portion of the transition metal M is preferably employed. In the case of a positive electrode active material including a plurality of the transition metals M, the reference point can be determined using M_{AVE} or M_{AVE} and M_{BG} of an element whose detection amount of the characteristic X-ray in the inner portion is the largest.

The average value M_{AVE} of the detected amounts of the characteristic X-ray of the transition metal M in the inner portion can be calculated by averaging the detected amounts in the range greater than or equal to 2 nm, preferably greater than or equal to 3 nm in a region that is at a depth larger than, by greater than or equal to 30 nm, preferably greater than 50 nm, the depth where the detected amount of the characteristic X-ray of the transition metal M or oxygen is stabilized, that is, saturated, specifically, a region where the detected amount of the characteristic X-ray of the transition metal M begins to increase or a region where the detected amount of the characteristic X-ray of oxygen begins to increase. The average value M_{BG} of the background values can be calculated by averaging the amounts in the range greater than or equal to 2 nm, preferably greater than or equal to 3 nm among the regions where the detected amount of the characteristic X-ray of the transition metal Mis stable avoiding the vicinity of the region where the detected amount of the characteristic X-ray of the transition metal M begins to increase, for example.

The surface of the positive electrode active material 100 in, for example, a cross-sectional STEM image is a boundary between a region where an image derived from the crystal structure of the positive electrode active material is observed and a region where the image is not observed, and is determined as the outermost surface of a region where an atomic column derived from an atomic nucleus of a metal element that has a greater atomic number than lithium among the metal elements constituting the positive electrode active material is confirmed.

The spatial resolution of STEM-EDX is at least approximately 1 nm. Thus, the peak position (also referred to as a local maximum value) of the detected amount of the characteristic X-ray corresponding to the additive element may be shifted by approximately 1 nm. For example, even when the peak position of the detected amount of the characteristic X-ray corresponding to the additive element such as magnesium is on the left side of the surface determined in the above-described manner, it can be said that a difference between the peak and the surface is within the margin of error when the difference is less than 1 nm.

A peak in STEM-EDX line analysis refers to a local maximum value or the maximum value of the characteristic X-ray corresponding to each element. Note that as a noise in STEM-EDX line analysis, a measured value having a half width smaller than or equal to spatial resolution (R), for example, smaller than or equal to R/2 can be given.

The adverse effect of a noise can be reduced by scanning the same portion a plurality of times under the same conditions. For example, an integrated value obtained by performing scanning six times can be used to make the graph of the characteristic X-ray of each element. The number of times of scanning is not limited to six and an average of measured values obtained by performing scanning seven or more times can be used to make the graph of the characteristic X-ray of each element.

STEM-EDX line analysis can be performed as follows, for example. First, a protective film is deposited by evaporation over a surface of a positive electrode active material in the air.

For example, carbon can be deposited by evaporation with a carbon coating unit of an ion sputtering apparatus (MC1000, manufactured by Hitachi High-Tech Corporation).

Next, the positive electrode active material is thinned to manufacture a cross-section sample to be subjected to STEM analysis. For example, the positive electrode active material can be thinned with an FIB-SEM apparatus (XVision 200TBS, manufactured by Hitachi High-Tech Corporation). Here, picking up can be performed by an MPS (micro probing system), and an acceleration voltage at final processing condition can be, for example, 10 kV.

The STEM-EDX line analysis can be performed using, for example, Octane T Ultra W (Dual EDS) of EDAX as an EDX detector installed in a STEM apparatus. In the EDX line analysis, the acceleration voltage of the STEM apparatus is set to 200 kV and the emission current is set to be in the range of 6 μA to 10 μA, and a portion of the thinned sample, which is not positioned at a deep level and has little unevenness, is measured. The magnification is 150,000 times, for example. The EDX line analysis can be performed under conditions where drift correction is performed, the line width is 42 nm, the pitch is 0.2 nm, and the number of frames is six or more.

### <Continuous Change in Crystal Structure>

It is preferable that the crystal structure continuously change from the inner portion 100b toward the surface owing to the above-described concentration gradient of the additive element. Alternatively, the crystal orientations of the surface portion 100a and the inner portion 100b are preferably substantially aligned with each other.

For example, the crystal structure preferably changes continuously from the inner portion 100b that has a layered rock-salt structure toward the surface and the surface portion 100a that have a rock-salt structure or have features of both a rock-salt crystal structure and a layered rock-salt crystal structure.

In this specification and the like, a layered rock-salt crystal structure, which belongs to the space group R-3m, of a composite oxide including lithium and the transition metal such as cobalt refers to a crystal structure in which a rock-salt ion arrangement where cations and anions are alternately arranged is included and lithium and the transition metal are regularly arranged to form a two-dimensional plane, so that lithium can be diffused two-dimensionally. Note that a defect such as a cation or anion vacancy may exist. Moreover, in the layered rock-salt crystal structure, strictly, a lattice of the rock-salt crystal structure is distorted and the symmetry of the layered rock-salt crystal structure is inferior to that of the rock-salt crystal structure in some cases.

A rock-salt crystal structure refers to a structure in which a cubic crystal structure such as a crystal structure belonging to the space group Fm-3m is included and cations and anions are alternately arranged. Note that a cation or anion vacancy may exist.

Having features of both a layered rock-salt crystal structure and a rock-salt crystal structure can be determined from electron diffraction, a TEM image, a cross-sectional STEM image, or the like.

There is no distinction among cation sites in a rock-salt structure; meanwhile, a layered rock-salt crystal structure has two types of cation sites: one type is mostly occupied by lithium, and the other is occupied by the transition metal. A stacked-layer structure where two-dimensional planes of cations and two-dimensional planes of anions are alternately arranged is the same in a rock-salt structure and a layered rock-salt structure. A stacked-layer structure where two-dimensional planes of cations and two-dimensional planes of anions are alternately arranged is the same in a rock-salt crystal structure and a layered rock-salt crystal structure. Given that the center spot (transmission spot) among bright spots in an electron diffraction pattern corresponding to crystal planes that form the two-dimensional planes is at the origin point 000, the bright spot nearest to the center spot is on the (111) plane in an ideal rock-salt crystal structure, for instance, and on the (003) plane in a layered rock-salt crystal structure, for instance. For example, when electron diffraction patterns of rock-salt MgO and layered rock-salt LiCoO₂ are compared to each other, the distance between the bright spots on the (003) plane of LiCoO₂ is observed at a distance approximately half the distance between the bright spots on the (111) plane of MgO. Thus, for instance, when two phases of rock-salt MgO and layered rock-salt LiCoO₂ are included in a region to be analyzed, a plane orientation in which bright spots with high luminance and bright spots with low luminance are alternately arranged is seen in an electron diffraction pattern. A bright spot common between the rock-salt structure and the layered rock-salt structure has high luminance, whereas a bright spot caused only in the layered rock-salt structure has low luminance.

When a layered rock-salt crystal structure is observed from a direction perpendicular to the c-axis in a cross-sectional STEM image and the like, layers observed with high luminance and layers observed with low luminance are alternately observed. Such a feature is not observed in a rock-salt structure because there is no distinction among cation sites therein. When a crystal structure having the features of both a rock-salt structure and a layered rock-salt structure is observed from a given crystal orientation, layers observed with high luminance and layers observed with low luminance are alternately observed in a cross-sectional STEM image and the like, and a metal that has a larger atomic number than lithium exists in part of the layers with low luminance, i.e., the lithium layers.

Anions of a layered rock-salt crystal and anions of a rock-salt crystal form a cubic close-packed structure (face-centered cubic lattice structure). Anions of an O3′ crystal and a monoclinic O1 (15) crystal described later are presumed to form a cubic close-packed structure. Thus, when a layered rock-salt crystal and a rock-salt crystal are in contact with each other, there is a crystal plane at which orientations of cubic close-packed structures composed of anions are aligned with each other.

The description can also be made as follows. Anions on the {111} plane of a cubic crystal structure have a triangle lattice. A layered rock-salt crystal structure, which belongs to the space group R-3m and is a rhombohedral structure, is generally represented by a composite hexagonal lattice for easy understanding of the structure, and the (0001) plane of the layered rock-salt crystal structure has a hexagonal lattice. The triangle lattice on the {111} plane of the cubic crystal has atomic arrangement similar to that of the hexagonal lattice on the (0001) plane of the layered rock-salt crystal structure. These lattices being consistent with each other can be expressed as “orientations of the cubic close-packed structures are aligned with each other”.

Note that a space group of the layered rock-salt crystal and the O3′ type crystal is R-3m, which is different from the space group Fm-3m of a rock-salt crystal (the space group of a general rock-salt crystal); thus, the Miller index of the crystal plane satisfying the above conditions in the layered rock-salt crystal and the O3′ type crystal is different from that in the rock-salt crystal. In addition, a state where three-dimensional structures have similarity, e.g., crystal orientations are substantially aligned with each other, or orientations are crystallographically the same is referred to as “topotaxy”.

The orientations of crystals in two regions being substantially aligned with each other can be judged, for example, from a TEM image, a STEM image, a HAADF-STEM (High-angle Annular Dark Field Scanning TEM) image, an ABF-STEM (Annular Bright-Field STEM) image, electron diffraction pattern, and FFT pattern of a TEM image, a STEM image, or the like. XRD, electron diffraction, neutron diffraction, and the like can also be used for judging.

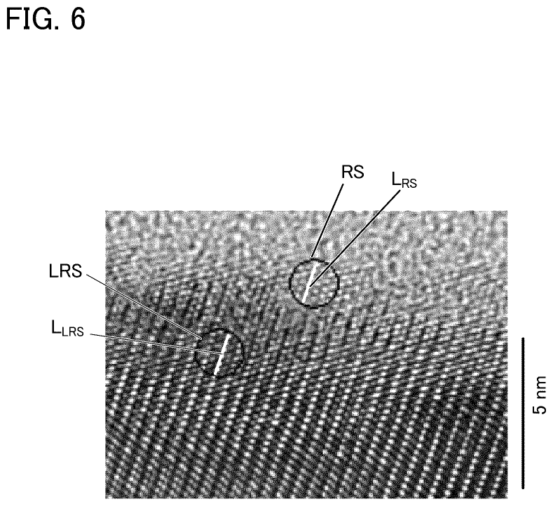

FIG. 6 shows an example of a TEM image in which orientations of a layered rock-salt crystal LRS and a rock-salt crystal RS are substantially aligned with each other. In a TEM image, a STEM image, a HAADF-STEM image, an ABF-STEM image, and the like, an image reflecting a crystal structure is obtained.

For example, in a high-resolution TEM image, a contrast derived from a crystal plane is obtained. When an electron beam is incident perpendicularly to the c-axis of a layered rock-salt type composite hexagonal lattice, for example, a contrast derived from the (0003) plane is obtained as repetition of bright bands (bright strips) and dark bands (dark strips) because of diffraction and interference of the electron beam. Thus, when repetition of bright lines and dark lines is observed and the angle between the bright lines (e.g., LRs and LLRS in FIG. 6) is 5° or less or 2.5° or less in the TEM image, it can be judged that the crystal planes are substantially aligned with each other, that is, orientations of the crystals are substantially aligned with each other. Similarly, when the angle between the dark lines is 5° or less or 2.5° or less, it can be judged that orientations of the crystals are substantially aligned with each other.

In a HAADF-STEM image, a contrast corresponding to the atomic number is obtained, and an element having a larger atomic number is observed to be brighter. For example, in the case of lithium cobalt oxide that has a layered rock-salt structure belonging to the space group R-3m, cobalt (atomic number: 27) has the largest atomic number; hence, an electron beam is strongly scattered at the position of a cobalt atom, and arrangement of the cobalt atoms is observed as bright lines or arrangement of high-luminance dots. Thus, when the lithium cobalt oxide having a layered rock-salt crystal structure is observed perpendicularly to the c-axis, arrangement of the cobalt atoms is observed as bright lines or arrangement of high-luminance dots, and arrangement of lithium atoms and oxygen atoms is observed as dark lines or a low-luminance region in the direction perpendicular to the c-axis. The same applies to the case where fluorine (atomic number: 9) and magnesium (atomic number: 12) are included as the additive elements of the lithium cobalt oxide.

Consequently, in the case where repetition of bright lines and dark lines is observed in two regions having different crystal structures and the angle between the bright lines is less than or equal to 5° or less than or equal to 2.5° in a HAADF-STEM image, it can be judged that arrangements of the atoms are substantially aligned with each other, that is, the crystal orientations are substantially aligned with each other. Similarly, when the angle between the dark lines is less than or equal to 5° or less than or equal to 2.5°, it can be judged that the crystal orientations are substantially aligned with each other.

With an ABF-STEM, an element having a smaller atomic number is observed to be brighter, but a contrast corresponding to the atomic number is obtained as with a HAADF-STEM; hence, in an ABF-STEM image, crystal orientations can be determined as in a HAADF-STEM image.

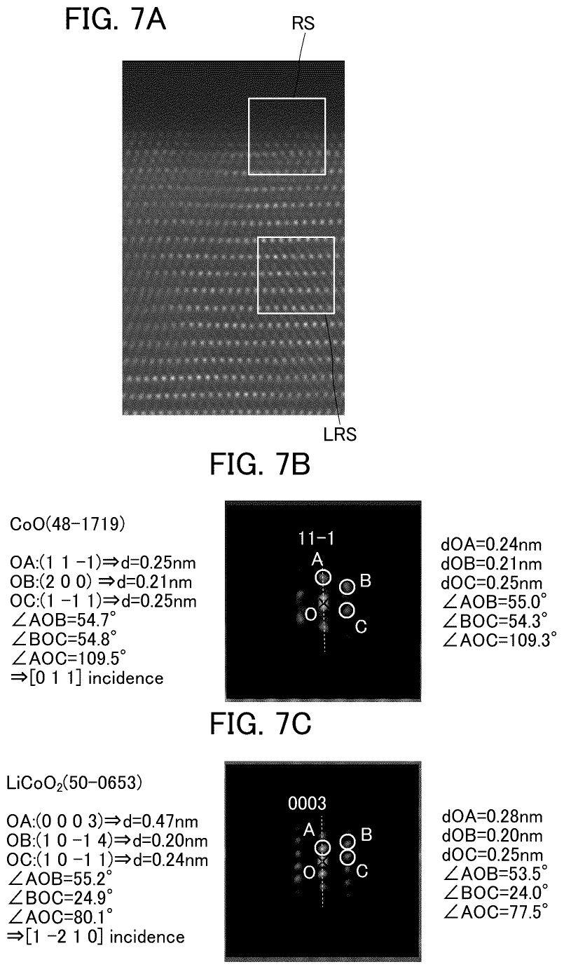

FIG. 7A shows an example of a STEM image in which orientations of the layered rock-salt crystal LRS and the rock-salt crystal RS are substantially aligned with each other. FIG. 7B shows an FFT pattern of a region of the rock-salt crystal RS, and FIG. 7C shows an FFT pattern of a region of the layered rock-salt crystal LRS. In FIG. 7B and FIG. 7C, the composition, the JCPDS card number, and d values and angles that are calculated from the JCPDS card data are shown on the left. The measured values are shown on the right. A spot denoted by O is zero-order diffraction.

A spot denoted by A in FIG. 7B is derived from 11-1 reflection of a cubic structure. A spot denoted by A in FIG. 7C is derived from 0003 reflection of a layered rock-salt structure. It is found from FIG. 7B and FIG. 7C that the direction of the 11-1 reflection of the cubic structure and the direction of the 0003 reflection of the layered rock-salt structure are substantially aligned with each other. That is, a straight line that passes through AO in FIG. 7B is substantially parallel to a straight line that passes through AO in FIG. 7C. Here, the terms “substantially aligned” and “substantially parallel” mean that the angle between the above straight lines is 5° or less or 2.5° or less.

When the orientations of the layered rock-salt crystal and the rock-salt crystal are substantially aligned with each other in the above manner in FFT pattern and electron diffraction pattern, the <0003> orientation of the layered rock-salt crystal and the <11-1> orientation of the rock-salt crystal may be substantially aligned with each other. In that case, it is preferable that these reciprocal lattice points be spot-shaped, that is, they be not connected to other reciprocal lattice points. The state where reciprocal lattice points are spot-shaped and not connected to other reciprocal lattice points means high crystallinity.

When the direction of the 11-1 reflection of the cubic structure and the direction of the 0003 reflection of the layered rock-salt structure are substantially aligned with each other as described above, a spot that is not derived from the 0003 reflection of the layered rock-salt structure may be observed, depending on the incident direction of the electron beam, on a reciprocal lattice space different from the direction of the 0003 reflection of the layered rock-salt structure. For example, a spot denoted by B in FIG. 7C is derived from 1014 reflection of the layered rock-salt structure. This is sometimes observed at a position where the difference in orientation from the reciprocal lattice point derived from the 0003 reflection of the layered rock-salt crystal structure (A in FIG. 7C) is greater than or equal to 52° and less than or equal to 56° (i.e., ∠AOB is greater than or equal to 52° and less than or equal to) 56° and a value dis greater than or equal to 0.19 nm and less than or equal to 0.21 nm. These indices are just examples, and the spot does not necessarily correspond with them. For example, the spot may be a reciprocal lattice point equivalent to 0003 and 1014.

Similarly, a spot that is not derived from the 11-1 reflection of the cubic structure may be observed on a reciprocal lattice space different from the direction where the 11-1 reflection of the cubic structure is observed. For example, a spot denoted by B in FIG. 7B is derived from 200 reflection of the cubic structure. This diffraction spot is sometimes observed at a position where the difference in orientation from the reciprocal lattice point derived from the 11-1 reflection of the cubic structure (A in FIG. 7B) is greater than or equal to 54° and less than or equal to 56° (i.e., ∠AOB is greater than or equal to 54° and less than or equal to) 56°. These indices are just examples, and the spot does not necessarily correspond with them. For example, the spot may be a reciprocal lattice point equivalent to 11-1 and 200.

It is known that in a layered rock-salt positive electrode active material, such as lithium cobalt oxide, the (0003) plane and a plane equivalent thereto and the (10-14) plane and a plane equivalent thereto are likely to be crystal planes. Thus, to observe the (0003) plane with a TEM or the like, for example, a positive electrode active material particle in which a crystal plane that is presumably the (0003) plane is observed with a SEM or the like is preferably selected first; then, the positive electrode active material particle is preferably processed to be thin using an FIB (Focused Ion Beam) or the like so that the (0003) plane can be observed with the TEM or the like with an electron beam thereof entering in [12-10]. To determine whether crystal orientations are aligned, the particle is preferably processed to be thin so that the (0003) plane of the layered rock-salt structure is easily observed.

### <Feature 1 of Secondary Battery in Nail Penetration Test>

In the case where AC impedance measurement is performed on the secondary battery in a fully charged state, the secondary battery preferably has an internal resistance with an AC impedance value of less than or equal to 100 mΩ, further preferably less than 90 mΩ at a frequency of 1 kHz. A secondary battery having such an internal resistance can be regarded as having high safety. The charge capacity of the secondary battery in a fully charged state is preferably higher than or equal to 2000 mAh, further preferably higher than or equal to 2400 mAh. Since the secondary battery in a fully charged state might be discharged over time, the AC impedance measurement is preferably performed within 24 hours, further preferably within 12 hours, still further preferably within 6 hours after the secondary battery has been fully charged.

### <Feature 2 of Secondary Battery in Nail Penetration Test>

An increase in the temperature of the secondary battery when the nail penetration test is performed, i.e., the difference between the temperature before the nail penetration test and the maximum temperature reached after the nail penetration (also referred to as temperature rise ΔT), is preferably less than or equal to 100° C., further preferably less than or equal to 70° C., still further preferably less than or equal to 50° C. The temperature is that at a position less than or equal to 5 cm away from the nail hole, preferably less than or equal to 2 cm away from the nail hole, and is specifically a value output with the use of the temperature sensor placed less than or equal to 5 cm away from the nail hole, preferably less than or equal to 2 cm away from the nail hole. In the case where the temperature sensor is provided in contact with the exterior body of the secondary battery, this temperature is equal to the temperature of the exterior body.

The temperature of the nail 1003 is preferably lower than or equal to 100° C., further preferably lower than or equal to 80° C., still further preferably lower than or equal to 60° C. This is a value output using the temperature sensor placed on the nail 1003.

The maximum temperature of the secondary battery at the time of the nail penetration test is preferably lower than or equal to 150° C., further preferably lower than or equal to 100° C., still further preferably lower than or equal to 80° C. Further preferably, the maximum temperature is lower than the temperature at which oxidation of the electrolyte solution by the positive electrode is caused. Further preferably, the maximum temperature is lower than the flash point of a mixed organic solvent used in the electrolyte solution. In the case where the flash point of the mixed organic solvent is unknown, the flash points of the organic solvents can be referred to.

### <Feature 3 of Secondary Battery in Nail Penetration Test>

The loading level of the positive electrode active material in the positive electrode of the secondary battery is preferably greater than or equal to 15 mg/cm² and less than or equal to 25 mg/cm², further preferably greater than or equal to 18 mg/cm² and less than or equal to 23 mg/cm², still further preferably greater than or equal to 20 mg/cm² and less than or equal to 22 mg/cm². The loading level in the above range makes it possible to provide a highly safe secondary battery.

In the secondary battery, the proportion of negative electrode capacity to positive electrode capacity is preferably higher than or equal to 75% and lower than or equal to 100%, further preferably higher than or equal to 80% and lower than or equal to 90%. The proportion of negative electrode capacity to positive electrode capacity in the above range makes it possible to provide a highly safe secondary battery. The proportion of negative electrode capacity to positive electrode capacity will be described later in Example.

### <Feature 4 of Secondary Battery in Nail Penetration Test>

Particles of the positive electrode active material included in the secondary battery preferably have few cracks. When the positive electrode active material particle is observed with a surface SEM or a cross-sectional SEM, for example, the number of observable cracks in each particle of the positive electrode active material is preferably greater than or equal to 0 and less than or equal to 5.

Generation of the crack is sometimes triggered by pressure application following application of slurry for the positive electrode on the positive electrode current collector. Thus, in the manufacturing process of the positive electrode of the present invention, the pressure of a press machine is preferably a linear pressure lower than or equal to 500 kN/m, further preferably a linear pressure lower than or equal to 300 kN/m, still further preferably a linear pressure lower than or equal to 250 kN/m, for example.

After the pressing, the thickness of the positive electrode active material layer is preferably greater than or equal to 70 μm and less than or equal to 80 μm, further preferably greater than or equal to 75 μm and less than or equal to 78 μm.

### <Crystal Structure of the Positive Electrode Active Material>

The crystal structure of the positive electrode active material 100 of one embodiment of the present invention is described, being compared with that of a conventional positive electrode active material.

<<When x in LiₓMO₂ is 1>>

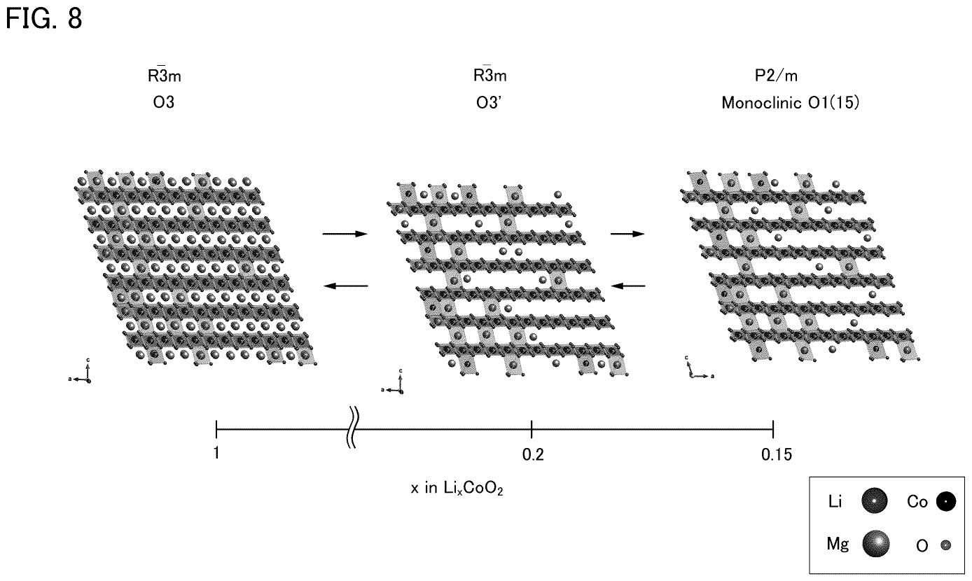

FIG. 8 illustrates crystal structures of the positive electrode active material 100 of one embodiment of the present invention. The positive electrode active material 100 of one embodiment of the present invention preferably has a layered rock-salt crystal structure belonging to the space group R-3m in a discharged state, i.e., a state where x in LiₓMO₂ (M is a transition metal or specifically, cobalt and/or nickel) is 1. A composite oxide having a layered rock-salt crystal structure is favorably used as a positive electrode active material of a secondary battery because it has high discharge capacity and a two-dimensional diffusion path for lithium ions and is thus suitable for insertion and extraction of lithium ions. For this reason, it is particularly preferable that the inner portion 100b, which accounts for the majority of the volume of the positive electrode active material 100, have a layered rock-salt crystal structure. In FIG. 8, the layered rock-salt crystal structure is denoted by R-3m 03. In the R-3m O3 type structure, the lattice constants are as follows: a=2.81610×10⁻¹⁰ (m), b=2.81610×10⁻¹⁰ (m), c=14.05360, a=90.0000, β=90.0000, and γ=120.0000; the coordinates of lithium, cobalt, and oxygen in a unit cell are represented by Li (0, 0, 0), Co (0, 0, 0.5), and O (0, 0, 0.23951), respectively (Non-Patent Document 10). In FIG. 8, “O3” is below the name of the space group, and this crystal structure, in which lithium occupies octahedral sites and a unit cell includes three MO₂ layers, is sometimes referred to as an O3 type crystal structure. Note that the MO₂ layer has a structure in which an octahedral structure with the transition metal M coordinated to six oxygen atoms continues on a plane in an edge-shared state. Such a layer is sometimes referred to as a layer formed of octahedrons of the transition metal M and oxygen. Although lithium ions are at all the lithium sites in FIG. 8, an ion of the additive element, e.g., a magnesium ion, may be positioned at a lithium site as described above.

Meanwhile, the surface portion 100a of the positive electrode active material 100 of one embodiment of the present invention preferably has a function of reinforcing the layered structure, which is formed of octahedrons of the transition metal M and oxygen, of the inner portion 100b so that the layered structure does not break even when lithium is extracted from the positive electrode active material 100 by charging. Alternatively, the surface portion 100a preferably functions as a barrier film of the positive electrode active material 100. Alternatively, the surface portion 100a, which is the outer portion of the positive electrode active material 100, preferably reinforces the positive electrode active material 100. Here, the term “reinforce” means inhibiting release of oxygen, a structural change of the surface portion 100a and the inner portion 100b of the positive electrode active material 100 such as a shift in the layered structure formed of octahedrons of the transition metal M and oxygen, and/or decomposition of an organic electrolyte solution or the like on the surface of the positive electrode active material 100.

Accordingly, the surface portion 100a preferably has a crystal structure different from that of the inner portion 100b. The surface portion 100a preferably has a more stable composition and a more stable crystal structure than those of the inner portion 100b at room temperature (25° C.). For example, at least part of the surface portion 100a of the positive electrode active material 100 of one embodiment of the present invention preferably has a rock-salt crystal structure. Alternatively, the surface portion 100a preferably has both a layered rock-salt crystal structure and a rock-salt crystal structure. Alternatively, the surface portion 100a preferably has features of both a layered rock-salt crystal structure and a rock-salt crystal structure.

The surface portion 100a is a region from which lithium ions are extracted initially in charge, and is a region that tends to have a lower concentration of lithium than the inner portion 100b. It can be said that bonds between atoms are partly cut on the surface of the particle of the positive electrode active material 100 included in the surface portion 100a. Therefore, the surface portion 100a is regarded as a region which is likely to be unstable and in which degradation of the crystal structure is likely to begin. For example, it is presumable that a shift in the crystal structure of the layered structure formed of octahedrons of the transition metal M and oxygen in the surface portion 100a has an influence on the inner portion 100b to cause a shift in the crystal structure of the layered structure in the inner portion 100b, leading to degradation of the crystal structure in the whole positive electrode active material 100. Meanwhile, if the surface portion 100a can have sufficient stability, the layered structure, which is formed of octahedrons of the transition metal M and oxygen, of the inner portion 100b is difficult to break even when x in LiₓCoO₂ is small, e.g., less than or equal to 0.24. Furthermore, a shift in layers, which are formed of octahedrons of the transition metal M and oxygen, of the inner portion 100b can be inhibited.

In the inner portion 100b of the positive electrode active material 100, the density of defects such as dislocation is preferably low. In the positive electrode active material 100, the crystallite size measured by XRD is preferably large. In other words, the inner portion 100b preferably has high crystallinity. Furthermore, the positive electrode active material 100 preferably has a smooth surface. These features are important factors for assuring the reliability of the positive electrode active material 100 in a secondary battery. A secondary battery can have a high upper limit of a charge voltage when a positive electrode active material is highly reliable and thereby can have high charge and discharge capacity.

Dislocation in the inner portion 100b can be observed with a TEM, for example. Defects such as dislocation are sometimes not observed in a specific 1-μm² region of an observation sample in the case where the density of defects such as dislocation is sufficiently low. Note that dislocation is a kind of crystal defect and is different from a point defect.

The crystallite size measured by XRD is preferably larger than or equal to 300 nm, for example. The larger the crystallite size is, the more easily the O3′ type structure is maintained and contraction of the c-axis length is inhibited in the state where x in LiₓCoO₂ is small as described later.

It is presumed that the crystallite size measured by XRD is larger when less defects such as dislocation are observed with a TEM.

An XRD diffraction pattern for calculation of the crystallite size is preferably obtained in a state of the positive electrode active material alone, or may be obtained in a state of a positive electrode including a current collector, a binder, a conductive material, and the like in addition to the positive electrode active material. Note that the positive electrode active material particles in the positive electrode may be oriented such that the crystal planes of the positive electrode active material particles are oriented in the same direction owing to, for example, pressure application in a manufacturing process. Due to the high orientation, the crystallite size may fail to be calculated accurately; thus, it is further preferable that to obtain an XRD diffraction pattern, a positive electrode active material layer be taken out of the positive electrode, the binder and the like in the positive electrode active material layer be eliminated to some extent using a solvent or the like, and the positive electrode active material layer be put in a sample holder, for example. Alternatively, a powder sample of the positive electrode active material or the like may be attached onto a reflection-free silicon plate to which grease is applied, for example.

The crystallite size can be calculated from, for example, the Scherrer equation shown below.

$$Crystallite size [ nm ] = \frac{Scherrer constant \times X - ray wavelength [ nm ]}{Half width [ rad ] \times cos ( \frac{Peak diffraction angle [ rad ]}{2} )} \qquad [ Formula 1 ]$$

The crystallite size can be calculated using ICSD coll. code. 172909 as a literature value of lithium cobalt oxide and a diffraction pattern that is obtained with Bruker D8 ADVANCE, for example, under the following conditions: CuKα radiation is used as an X-ray, the 20 range is from 15° to 90°, an increment is 0.005, and a detector is LYNXEYE XE-T. Analysis can be conducted using DIFFRAC.TOPAS ver. 6 as crystal structure analysis software, and exemplary settings are as follows.

Emission Profile: CuKα5.1 am
Background: Chebychev polynomial of degree 5
Instrument
   Primary radius: 280 mm
   Secondary radius: 280 mm
   Linear PSD
      2Th angular range: 2.9
      FDS angle: 0.3
Full Axial Convolution
   Filament length: 12 mm
   Sample length: 15 mm
   Receiving Slit length: 12 mm
   Primary Sollers: 2.5
   Secondary Sollers: 2.5
Corrections
   Specimen displacement: Refine
   LP Factor: 0

A value of LVol-IB, which is a crystallite size calculated by the above method, is preferably employed as a crystallite size. Note that in a sample whose preferred orientation is calculated to be less than 0.8, too many particles are oriented in the same direction; thus, this sample is not suitable for calculation of a crystallite size in some cases.

### [Distribution]

The distribution of the additive element in the positive electrode active material 100 in a discharged state is described as an example. To obtain a stable composition and a stable crystal structure of the surface portion 100a, the surface portion 100a preferably includes the additive element, further preferably a plurality of the additive elements. The surface portion 100a preferably has a higher concentration of one or two or more selected from the additive elements than the inner portion 100b. The one or two or more selected from the additive elements included in the positive electrode active material 100 preferably have a concentration gradient. In addition, it is further preferable that the additive elements included in the positive electrode active material 100 be distributed in a different manner. For example, it is preferable that peaks of detected amounts of the additive elements be exhibited at different depths from the surface. The peak of the detected amount here refers to a maximum value of the detected amount, and the peak of the detected amount in the surface portion 100a refers to the maximum value of the detected amount in the surface portion 100a. In some cases, the detected amount is referred to as intensity when the vertical axis in EDX line analysis represents count and is referred to as concentration when the vertical axis represents atomic %, for example.

The detected amount of magnesium among the additive elements is preferably larger in the surface portion 100a than in the inner portion 100b. A peak of the detected amount of magnesium is preferably observed in a region of the surface portion 100a that is closer to the surface.

As in the case of magnesium, the detected amount of fluorine among the additive elements is preferably larger in the surface portion 100a than in the inner portion 100b. A peak of the detected amount of fluorine is preferably observed in a region of the surface portion 100a that is closer to the surface.

The detected amount of nickel among the additive elements is preferably larger in the surface portion 100a than in the inner portion 100b. A peak of the detected amount of nickel is preferably observed in a region of the surface portion 100a that is closer to the surface. For example, it is preferable that in the surface portion 100a, the detected amount of nickel in the shell be larger than that of nickel in a region located inward from the shell, and a peak of the detected amount of nickel be observed in the shell. Here, the ratio of the number of nickel (Ni) atoms to the number of cobalt (Co) atoms (Ni/Co) in the shell of the surface portion 100a is less than 1. That is, the number of nickel (Ni) atoms is smaller than that of cobalt (Co) atoms in the shell of the surface portion 100a. The ratio of the number of nickel (Ni) atoms to the number of cobalt (Co) atoms (Ni/Co) at a peak of the detected amount of nickel is less than 1. Furthermore, the ratio of the number of nickel (Ni) atoms to the number of cobalt (Co) atoms (Ni/Co) in the region located inward from the shell is less than the ratio of the number of nickel (Ni) atoms to the number of cobalt (Co) atoms (Ni/Co) in the shell. Note that the detected amount of nickel in the inner portion 100b is sometimes much smaller than that of nickel in the surface portion 100a. As described above, the number of nickel (Ni) atoms is smaller than that of cobalt (Co) atoms in each of the surface portion 100a and the inner portion 100b. The number of nickel (Ni) atoms is smaller than that of cobalt (Co) atoms in the positive electrode active material 100.

In the case where both magnesium and nickel are included, the distribution of magnesium and that of nickel preferably overlap with each other. Note that when the distributions overlap with each other, the peak of the detected amount of magnesium and that of nickel may be the same or the difference between the peaks may be less than or equal to 3 nm, and the whole peaks do not necessarily overlap with each other. For example, the peak of the detected amount of magnesium may be closer to the surface, or the peak of the detected amount of nickel may be closer to the surface.

The detected amount of titanium among the additive elements is also preferably larger in the surface portion 100a than in the inner portion 100b. A peak of the detected amount of titanium is preferably observed in a region of the surface portion 100a that is closer to the surface.

The detected amount(s) of silicon, phosphorus, boron, and/or calcium among the additive elements are/is also preferably larger in the surface portion 100a than in the inner portion 100b. A peak(s) of the detected amount(s) of silicon, phosphorus, boron, and/or calcium are/is preferably observed in a region of the surface portion 100a that is closer to the surface.

A peak of the detected amount of aluminum among the additive elements is preferably observed in a region that is located inward from a region in which a peak of the detected amount of magnesium is observed. The distribution of magnesium and that of aluminum may overlap with each other; alternatively, there may be almost no overlap between the distribution of magnesium and that of aluminum. Note that when the distributions overlap with each other, the peak of the detected amount of magnesium and the peak of the detected amount of aluminum may be the same or the difference between the peaks may be less than or equal to 3 nm, and the whole peaks do not necessarily overlap with each other. The peak of the detected amount of aluminum may be located in the surface portion 100a or may be located deeper than the surface portion 100a. When the peak of the detected amount of aluminum is located deeper than the surface portion 100a, there is almost no overlap between the distribution of magnesium and that of aluminum in some cases. For example, aluminum preferably has a peak in a region of greater than or equal to 5 nm and less than or equal to 30 nm toward the inner portion from the surface. Aluminum is distributed more inwardly than magnesium probably because aluminum diffuses more easily than magnesium.

The distribution of aluminum is not normal distribution in some cases. For example, when the curve of the distribution of aluminum is divided by the maximum value Max_{A1}, the length of the tail on the surface side is sometimes different from that of the tail on the inner portion side. When the peak width at the height (⅕ Max_{A1}) that is ⅕ of the height of the maximum value (Max_{A1}) of the detected amount of aluminum is divided into two parts by a perpendicular extending from the maximum value to the horizontal axis, the peak width (W_{c}) on the inner portion side is sometimes larger than the peak width (Wₛ) on the surface side.

Meanwhile, the amount of aluminum detected is small in the region that is closest to the surface presumably because aluminum is more stable in a region other than the region where magnesium or the like forms a solid solution at a high concentration. To be more specific, in a region having a layered rock-salt structure belonging to the space group R-3m or a cubic rock-salt structure, the distance between a cation and oxygen in a region where magnesium at a high concentration forms a solid solution is longer than the distance between a cation and oxygen in LiAlO₂ having a layered rock-salt structure, and aluminum is thus likely to be unstable. In the vicinity of cobalt, valence change due to substitution of Mg²⁺ for Li⁺ can be compensated for by Co³⁺ becoming Co²⁺, so that cation balance can be maintained. By contrast, Al is always trivalent and is thus presumed to be unlikely to coexist with magnesium in a rock-salt or layered rock-salt crystal structure.

As in the case of aluminum, a peak of the detected amount of manganese among the additive elements is preferably observed in a region that is located inward from a region in which a peak of the detected amount of magnesium is observed.

Note that the additive elements do not necessarily have similar distributions throughout the surface portion 100a of the positive electrode active material 100.

For example, the distribution of the additive element in a region having a surface having a (001) orientation of the positive electrode active material 100 may be different from that in a region having a surface having an orientation other than a (001) orientation. For example, the surface having the (001) orientation and the surface portion 100a thereof may have a smaller detected amount of one or two or more selected from the additive elements than a surface having an orientation other than the (001) orientation. Specifically, the detected amount of nickel may be smaller. Especially in the case of an analysis method, e.g., EDX, by which characteristic X-rays are detected, the energy of KB for cobalt is close to that of Kα for nickel and it is thus difficult to detect a slight amount of nickel in a material whose main element is cobalt; accordingly, it is preferable to confirm the presence of nickel by point analysis in addition to line analysis. Alternatively, the peak(s) of one or two or more selected from the additive elements in the region having a surface having the (001) orientation may be positioned shallower from the surface than the peaks(s) in the region having a surface having an orientation other than the (001) orientation. Specifically, the peak positions of magnesium and aluminum may be shallow from the surface. The region having the above-described surface is included in the surface portion 100a.

The reason why the peak positions of magnesium and aluminum in the region having the surface having the (001) orientation become shallower from the surface is considered. In a layered rock-salt crystal structure belonging to R-3m, cations are arranged parallel to the (001) plane. In other words, CoO₂ layers and lithium layers are alternately stacked parallel to the (001) plane. Accordingly, a diffusion path of lithium ions also exists parallel to the (001) plane. The CoO₂ layer is relatively stable and thus, the surface of the positive electrode active material 100 is more stable when having a (001) orientation. Thus, magnesium and aluminum are less likely to diffuse, and the positions of these peaks become shallow from the surface.

In addition, a main diffusion path of lithium ions in charging and discharging is not exposed at the (001) plane. By contrast, a diffusion path of lithium ions is exposed at a surface having an orientation other than the (001) orientation. Thus, the surface having an orientation other than the (001) orientation and the surface portion 100a thereof easily lose stability because they are regions where extraction of lithium ions starts as well as important regions for maintaining a diffusion path of lithium ions. It is thus preferable to reinforce at least the surface having an orientation other than the (001) orientation and the surface portion 100a thereof so that the crystal structure of the whole positive electrode active material 100 is maintained.

In view of this, in the positive electrode active material 100, attention is sometimes focused on the concentration distribution of the additive element at the surface having an orientation other than the (001) orientation and the surface portion 100a thereof. In particular, among the additive elements, magnesium is preferably detected at the surface having an orientation other than the (001) orientation and the surface portion 100a thereof. By contrast, at the surface having the (001) orientation and the surface portion 100a thereof, the concentration of the additive element may be low as described above or the additive element may be absent. Nickel is not necessarily present at the surface having the (001) orientation and the surface portion 100a thereof.

For example, the half width of the distribution of magnesium at the surface having the (001) orientation and the surface portion 100a thereof is preferably greater than or equal to 10 nm and less than or equal to 200 nm, further preferably greater than or equal to 50 nm and less than or equal to 150 nm, still further preferably greater than or equal to 80 nm and less than or equal to 120 nm. The half width of the distribution of magnesium at the surface not having the (001) orientation and the surface portion 100a thereof is preferably greater than 200 nm and less than or equal to 500 nm, further preferably greater than 200 nm and less than or equal to 300 nm, still further preferably greater than or equal to 230 nm and less than or equal to 270 nm. That is, in some cases, the half width of the distribution of magnesium at the surface having an orientation other than the (001) orientation and the surface portion 100a thereof is larger than that at the surface having the (001) orientation and the surface portion 100a thereof.

The half width of the distribution of nickel at the surface not having the (001) orientation and the surface portion 100a thereof is preferably greater than or equal to 30 nm and less than or equal to 150 nm, further preferably greater than or equal to 50 nm and less than or equal to 130 nm, still further preferably greater than or equal to 70 nm and less than or equal to 110 nm.

As described in the following embodiment, in the manufacturing method in which heating is performed after the additive element is mixed, the additive element may spread mainly through a diffusion path of lithium ions. Thus, in order that the distribution of the additive element at the surface having an orientation other than the (001) orientation and the surface portion 100a thereof can fall within a preferred range, it is preferable that formation of lithium cobalt oxide having high purity or formation of lithium cobalt oxide having a smooth surface precede mixing of the additive element and heating.

### [Magnesium]

Magnesium is divalent and aluminum or nickel as the additive element is stable at cobalt sites in a layered rock-salt crystal structure; thus, magnesium ions are likely to be at lithium sites, not cobalt sites, i.e., magnesium ions are likely to enter lithium sites. An appropriate magnesium concentration in the lithium sites of the surface portion 100a can facilitate the maintenance of the layered rock-salt crystal structure. This is probably because magnesium in the lithium sites serves as a column supporting the CoO₂ layers. Moreover, magnesium can inhibit release of oxygen therearound and thermal decomposition in a state where x in LiₓCoO₂ is, for example, less than or equal to 0.24. Magnesium is also expected to increase the density of the positive electrode active material 100. In addition, a high magnesium concentration in the surface portion 100a probably increases the corrosion resistance to hydrofluoric acid generated by the decomposition of the organic electrolyte solution or the like.

An appropriate magnesium concentration can bring the above-described advantages without an adverse effect on insertion and extraction of lithium in charging and discharging. However, excess magnesium might adversely affect insertion and extraction of lithium. Furthermore, the effect of stabilizing the crystal structure might be reduced. This is probably because magnesium enters the cobalt sites in addition to the lithium sites. Moreover, an undesired magnesium compound (e.g., an oxide and fluoride) which is substituted for neither the lithium site nor the cobalt site might segregate at the surface of the positive electrode active material or the like to serve as a resistance component of a secondary battery. As the magnesium concentration of the positive electrode active material increases, the discharge capacity of the positive electrode active material decreases in some cases. This is probably because excess magnesium enters the lithium sites and the amount of lithium contributing to charging and discharging decreases.

Thus, the entire positive electrode active material 100 preferably includes an appropriate amount of magnesium. The number of magnesium atoms is preferably greater than or equal to 0.002 times and less than or equal to 0.06 times, further preferably greater than or equal to 0.005 times and less than or equal to 0.03 times, still further preferably approximately 0.01 times the number of cobalt atoms, for example. The amount of magnesium included in the entire positive electrode active material 100 here may be a value obtained by element analysis on the entire positive electrode active material 100 using GD-MS (glow discharge mass spectrometry), ICP-MS (inductively coupled plasma mass spectrometry), or the like, or may be a value based on the ratio of the raw materials mixed in the formation process of the positive electrode active material 100, for example.

### [Fluorine]

When fluorine is a monovalent anion and is adsorbed onto the surface of the positive electrode active material 100, the energy required for lithium extraction from the positive electrode active material 100 is lowered. As long as this energy is lowered, fluorine may be substituted for some oxygen atoms of the surface portion 100a. This is because the oxidation-reduction potential of cobalt ions associated with lithium extraction differs depending on whether fluorine is present. That is, when fluorine is not included, cobalt ions change from a trivalent state to a tetravalent state owing to lithium extraction. Meanwhile, when fluorine is included, cobalt ions change from a divalent state to a trivalent state owing to lithium extraction. The oxidation-reduction potential of cobalt ions differs in these cases. This facilitates smooth extraction and insertion of lithium ions in the vicinity of fluorine; thus, fluorine is preferably included at the surface or surface portion of the positive electrode active material 100. A secondary battery including the positive electrode active material 100 including fluorine can have improved charge and discharge characteristics, improved large current characteristics, or the like. When fluorine is present at the surface or surface portion, which is to be in contact with an electrolyte solution, or when a fluoride is adsorbed onto or attached to the surface, an overreaction between the positive electrode active material 100 and the electrolyte solution can be inhibited. In addition, the corrosion resistance to hydrofluoric acid can be effectively increased.

### [Nickel]

Nickel can be present in both the cobalt site and the lithium site. Since nickel has a lower oxidation-reduction potential than cobalt, the presence of nickel at a cobalt site facilitates release of lithium during charging, for example. As a result, the charge and discharge speed is expected to be increased.

In addition, when nickel is present at a lithium site, a shift in the layered structure formed of octahedrons of cobalt and oxygen can be inhibited. Moreover, a change in volume in charging and discharging is inhibited. Furthermore, an elastic modulus becomes large, i.e., hardness increases. This is probably because nickel at the lithium sites also serves as a column supporting the CoO₂ layers. Therefore, in particular, the crystal structure is expected to be more stable in a charged state at high temperatures, e.g., 45° C. or higher, which is preferable.

Nickel can be present in both the cobalt site and the lithium site. Since nickel has a lower oxidation-reduction potential than cobalt, the presence of nickel at a cobalt site can facilitate release of lithium and electrons during discharging, for example. Thus, the charge and discharge speed is expected to be increased, or in other words, the charge and discharge rate characteristics are expected to be improved.

The distance between a cation and an anion of nickel oxide (NiO) is closer to the average of the distance between a cation and an anion of LiCoO₂ than those of MgO and CoO, and the orientations of NiO and LiCoO₂ are likely to be aligned with each other.

Ionization tendency is the lowest in nickel and higher in the order of cobalt, aluminum, and magnesium (Mg>Al>Co>Ni). Therefore, it is considered that in charging, nickel is less likely to be dissolved into an electrolyte solution than the other elements described above. Accordingly, nickel is considered to have a high effect of stabilizing the crystal structure of the surface portion in a charged state.

Furthermore, in nickel, Ni²⁺ is more stable than Ni³⁺ and Ni⁴⁺, and nickel has higher trivalent ionization energy than cobalt. Thus, it is known that a spinel crystal structure does not appear only with nickel and oxygen. Therefore, nickel is considered to have an effect of inhibiting a phase change from a layered rock-salt crystal structure to a spinel crystal structure.

Meanwhile, excess nickel increases the influence of distortion due to the Jahn-Teller effect, which is not preferable. Moreover, excess nickel might adversely affect insertion and extraction of lithium.

Thus, the entire positive electrode active material 100 preferably includes an appropriate amount of nickel. For example, in the positive electrode active material 100, the number of nickel atoms is smaller than that of cobalt atoms, and is preferably greater than 0% and less than or equal to 7.5%, further preferably greater than or equal to 0.05% and less than or equal to 4%, still further preferably greater than or equal to 0.1% and less than or equal to 2%, yet still further preferably greater than or equal to 0.2% and less than or equal to 1% of the number of cobalt atoms. Alternatively, the number of nickel atoms is preferably greater than 0% and less than or equal to 4%, greater than 0% and less than or equal to 2%, greater than or equal to 0.05% and less than or equal to 7.5%, greater than or equal to 0.05% and less than or equal to 2%, greater than or equal to 0.1% and less than or equal to 7.5%, or greater than or equal to 0.1% and less than or equal to 4% of the number of cobalt atoms. The amount of nickel described here may be a value obtained by entirely performing element analysis on the positive electrode active materials with GD-MS, ICP-MS, or the like, or may be a value based on the ratio of the raw materials mixed in the formation process of the positive electrode active materials, for example.

### [Aluminum]

Aluminum can be present at a cobalt site in a layered rock-salt crystal structure. Since aluminum is a trivalent representative element and its valence does not change, lithium around aluminum is less likely to move even in charging and discharging. Thus, aluminum and lithium around aluminum serve as columns to inhibit a change in the crystal structure. This would inhibit degradation of the positive electrode active material 100 if force of expansion and contraction of the positive electrode active material 100 in the c-axis direction operates owing to insertion and extraction of lithium ions, i.e., owing to a change in charge depth or charge rate, as described later.

Furthermore, aluminum has an effect of inhibiting dissolution of cobalt around aluminum and improving continuous charging tolerance. Moreover, an Al—O bond is stronger than a Co—O bond and thus release of oxygen around aluminum can be inhibited. These effects improve thermal stability. Therefore, a secondary battery that includes the positive electrode active material 100 including aluminum as the additive element can have higher level of safety. Furthermore, the positive electrode active material 100 can have a crystal structure that is unlikely to be broken by repeated charge and discharge.

Meanwhile, excess aluminum might adversely affect insertion and extraction of lithium.

Thus, the entire positive electrode active material 100 preferably includes an appropriate amount of aluminum. For example, in the entire positive electrode active material 100, the number of aluminum atoms is preferably greater than or equal to 0.05% and less than or equal to 4%, further preferably greater than or equal to 0.1% and less than or equal to 2%, still further preferably greater than or equal to 0.3% and less than or equal to 1.5% of the number of cobalt atoms. Alternatively, it is preferably greater than or equal to 0.05% and less than or equal to 2%. Alternatively, it is preferably greater than or equal to 0.1% and less than or equal to 4%. The amount included in the entire positive electrode active material 100 here may be a value obtained by element analysis on the entire positive electrode active material 100 with GD-MS, ICP-MS, or the like or may be a value based on the ratio of the raw materials mixed in the formation process of the positive electrode active material 100, for example.

An oxide of titanium is known to have superhydrophilicity. Accordingly, the positive electrode active material 100 that includes titanium oxide in the surface portion 100a presumably has good wettability with respect to a high-polarity solvent. In a secondary battery formed using this positive electrode active material 100, the positive electrode active material 100 and a high-polarity electrolyte solution can have favorable contact at the interface therebetween, which may inhibit an internal resistance increase.

The surface portion 100a preferably includes phosphorus, in which case a short circuit can be sometimes inhibited while a state with small x in LiₓCoO₂ is maintained. For example, a compound including phosphorus and oxygen is preferably present in the surface portion 100a.

The positive electrode active material 100 preferably includes phosphorus, in which case phosphorus can react with hydrogen fluoride that is generated by the decomposition of the electrolyte solution or a lithium salt and the hydrogen fluoride concentration in the electrolyte solution can be reduced.

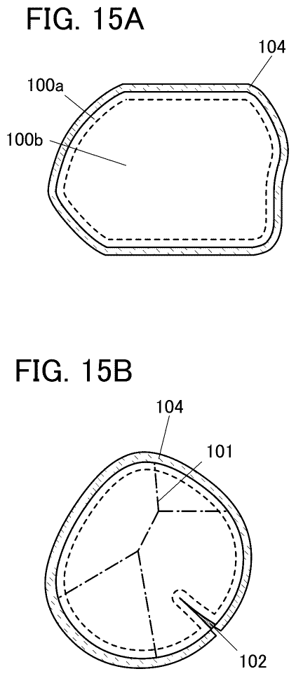

In the case where the lithium salt includes LiPF₆, hydrogen fluoride might be generated by hydrolysis. In addition, hydrogen fluoride might be generated by the reaction of poly(vinylidene fluoride) (PVDF) used as a component of the positive electrode and alkali. The decrease in hydrogen fluoride concentration in the organic electrolyte solution may inhibit corrosion of a current collector and/or separation of a coating portion 104 (see FIG. 15) or may inhibit a reduction in adhesion properties due to gelling and/or insolubilization of PVDF.

The positive electrode active material 100 preferably includes magnesium and phosphorus, in which case the crystal structure is extremely stable in a state with small x in LiₓCoO₂. In the case where the positive electrode active material 100 includes phosphorus, the number of phosphorus atoms is preferably greater than or equal to 1% and less than or equal to 20%, further preferably greater than or equal to 2% and less than or equal to 10%, still further preferably greater than or equal to 3% and less than or equal to 8% of the number of cobalt atoms. Alternatively, it is preferably greater than or equal to 1% and less than or equal to 10%. Alternatively, it is preferably greater than or equal to 1% and less than or equal to 8%. Alternatively, it is preferably greater than or equal to 2% and less than or equal to 20%. Alternatively, it is preferably greater than or equal to 2% and less than or equal to 8%. Alternatively, it is preferably greater than or equal to 3% and less than or equal to 20%. Alternatively, it is preferably greater than or equal to 3% and less than or equal to 10%. In addition, the number of magnesium atoms is preferably greater than or equal to 0.1% and less than or equal to 10%, further preferably greater than or equal to 0.5% and less than or equal to 5%, still further preferably greater than or equal to 0.7% and less than or equal to 4% of the number of cobalt atoms. Alternatively, it is preferably greater than or equal to 0.1% and less than or equal to 5%. Alternatively, it is preferably greater than or equal to 0.1% and less than or equal to 4%. Alternatively, it is preferably greater than or equal to 0.5% and less than or equal to 10%. Alternatively, it is preferably greater than or equal to 0.5% and less than or equal to 4%. Alternatively, it is preferably greater than or equal to 0.7% and less than or equal to 10%. Alternatively, it is preferably greater than or equal to 0.7% and less than or equal to 5%. The phosphorus concentration and the magnesium concentration described here may each be a value obtained by element analysis on the entire positive electrode active material 100 using GD-MS, ICP-MS, or the like, or may be a value based on the ratio of the raw materials mixed in the process of forming the positive electrode active material 100, for example.

In the case where the crack 102 is formed at part of the surface of the positive electrode active material 100, crack development can be sometimes inhibited by phosphorus, more specifically, a compound including phosphorus and oxygen, or the like that exists in the filling portion in contact with the part of the surface.

### [Synergistic Effect of a Plurality of Elements]

When the surface portion 100a includes both magnesium and nickel, divalent nickel might be able to exist more stably in the vicinity of divalent magnesium. Thus, even when x in LiₓCoO₂ is small, dissolution of magnesium might be inhibited. This might contribute to stabilization of the surface portion 100a.

For a similar reason, when the additive element is added to lithium cobalt oxide in the formation process, magnesium is preferably added in a step before a step where nickel is added. Alternatively, magnesium and nickel are preferably added in the same step. Magnesium has a large ion radius and thus easily remains in the surface portion of lithium cobalt oxide regardless of in which step magnesium is added, but nickel may be widely diffused to the inner portion of lithium cobalt oxide when magnesium does not exist. Thus, when nickel is added before magnesium is added, nickel might be diffused to the inner portion of lithium cobalt oxide and a preferable amount of nickel might not remain in the surface portion.

Additive elements that are differently distributed are preferably included at a time, in which case the crystal structure of a wider region can be stabilized. For example, the crystal structure can be stabilized in a wider region in the case where the positive electrode active material 100 includes all of magnesium, nickel, and aluminum, than in the case where only one or two of the elements are included. In the case where the positive electrode active material 100 includes the additive elements that are differently distributed as described above, the surface can be sufficiently stabilized by magnesium, nickel, and the like; thus, aluminum is not necessary for the surface. It is preferable that aluminum be widely distributed in a deeper region. For example, it is preferable that aluminum be continuously detected in a region of greater than or equal to 1 nm and less than or equal to 25 nm in a depth direction from the surface. Aluminum is preferably widely distributed in a region of greater than or equal to 0 nm and less than or equal to 100 nm, further preferably a region of greater than or equal to 0.5 nm and less than or equal to 50 nm, in which case the crystal structure of a wider region can be stabilized.

When a plurality of the additive elements are included as described above, the effects of the additive elements contribute synergistically to further stabilization of the surface portion 100a. In particular, magnesium, nickel, and aluminum are preferably included, in which case a high effect of stabilizing the composition and the crystal structure can be obtained.

Note that the surface portion 100a occupied by only a compound of an additive element and oxygen is not preferred because this surface portion 100a would make insertion and extraction of lithium difficult. For example, it is not preferable that the surface portion 100a be occupied by only MgO, a structure in which MgO and NiO (II) form a solid solution, and/or a structure in which MgO and CoO (II) form a solid solution. Thus, the surface portion 100a should include at least cobalt, and also include lithium in a discharged state to have the path through which lithium is inserted and extracted.

To ensure the sufficient path through which lithium is inserted and extracted, the concentration of cobalt is preferably higher than that of magnesium in the surface portion 100a. For example, when measurement by XPS (X-ray photoelectron spectroscopy) is performed from the surface of the positive electrode active material 100, the ratio of the number of magnesium (Mg) atoms to the number of cobalt (Co) atoms (Mg/Co) is preferably less than or equal to 0.62. The concentration of cobalt is preferably higher than that of nickel in the surface portion 100a. The concentration of cobalt is preferably higher than that of aluminum in the surface portion 100a. The concentration of cobalt is higher than that of fluorine in the surface portion 100a.

Moreover, excess nickel might hinder diffusion of lithium; thus, the magnesium concentration is preferably higher than that of nickel in the surface portion 100a. For example, when measurement by XPS is performed from the surface of the positive electrode active material 100, the number of nickel atoms is preferably ⅙ or less of that of magnesium atoms.

It is preferable that some additive elements, in particular, magnesium, nickel, and aluminum have higher concentrations in the surface portion 100a than in the inner portion 100b and exist randomly also in the inner portion 100b to have low concentrations. When magnesium and aluminum exist in the lithium sites of the inner portion 100b at appropriate concentrations, an effect of facilitating maintenance of the layered rock-salt crystal structure can be obtained in a manner similar to the above. When nickel exists in the inner portion 100b at an appropriate concentration, a shift in the layered structure formed of octahedrons of the transition metal M and oxygen can be inhibited in a manner similar to the above. Also in the case where both magnesium and nickel are included, a synergistic effect of inhibiting dissolution of magnesium can be expected in a manner similar to the above.

<<State where x in LiₓMO₂ is Small>>

Since the positive electrode active material 100 of one embodiment of the present invention has the above-described additive element distribution and/or crystal structure, the positive electrode active material 100 is different from a conventional positive electrode active material in the crystal structure in a state where x in LiₓMO₂ is small, i.e., a high-voltage charged state. Here, “x is small” means 0.1<x≤0.24. A high voltage in a charged state means a voltage higher than or equal to 4.5 V, preferably higher than or equal to 4.6 V, further preferably higher than or equal to 4.8 V.

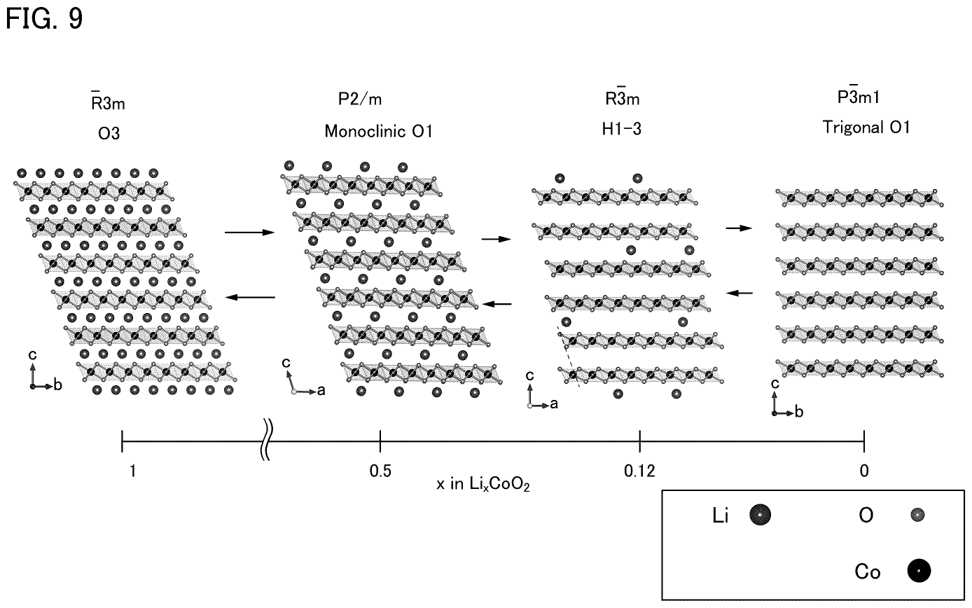

A conventional positive electrode active material and the positive electrode active material 100 of one embodiment of the present invention are compared, and changes in the crystal structures owing to a change in x in LiₓMO₂ will be described with reference to FIG. 8 and FIG. 9.

A change in the crystal structure of the conventional positive electrode active material is illustrated in FIG. 9. The conventional positive electrode active material shown in FIG. 9 is lithium cobalt oxide (LiCoO₂) including no additive element. A change in the crystal structure of lithium cobalt oxide including no additive element is described in Non-Patent Document 1 to Non-Patent Document 3 and the like.

In FIG. 9, the crystal structure of the lithium cobalt oxide in a discharged state, i.e., with x in LiₓCoO₂ of 1, is denoted by R-3m O3. In the discharged state, the conventional lithium cobalt oxide has the same crystal structure as the positive electrode active material 100 of one embodiment of the present invention.

Conventional lithium cobalt oxide with x of approximately 0.5 is known to have an improved symmetry of lithium and have a monoclinic crystal structure belonging to the space group P2/m. This structure includes one CoO₂ layer in a unit cell. Thus, this structure is referred to as an O1 type structure or a monoclinic (indicated as monoclinic in the drawing) O1 type structure in some cases.

A positive electrode active material with x of 0 has the trigonal crystal structure belonging to the space group P-3 ml and includes one CoO₂ layer in a unit cell. Hence, this crystal structure is referred to as an O1 type structure or a trigonal O1 type structure (indicated as trigonal in the drawing) in some cases. Moreover, in some cases, this crystal structure is referred to as a hexagonal O1 type structure when the trigonal crystal is converted into a composite hexagonal lattice.

Conventional lithium cobalt oxide with x of approximately 0.12 has the crystal structure belonging to the space group R-3m. This structure can also be regarded as a structure in which CoO₂ structures such as a trigonal O1 type structure and LiCoO₂ structures such as an R-3m O3 type structure are alternately stacked. Thus, this crystal structure is sometimes referred to as an H1-3 type structure (indicated as H1-3 in the drawing). Note that since insertion and extraction of lithium do not necessarily uniformly occur in the positive electrode active material in reality, the lithium concentrations can vary; thus, the H1-3 type crystal structure is started to be observed when x is approximately 0.25 experimentally. The number of cobalt atoms per unit cell in the actual H1-3 type crystal structure is twice that in other structures.

For the H1-3 type structure, as disclosed in Non-Patent Document 3, the coordinates of cobalt and oxygen in the unit cell can be expressed as follows, for example: Co (0, 0, 0.42150±0.00016), O1 (0, 0, 0.27671±0.00045), and O2 (0, 0, 0.11535±0.00045). O1 and O2 are each an oxygen atom. A unit cell that should be used for representing a crystal structure in a positive electrode active material can be judged by Rietveld analysis of XRD patterns, for example. For example, a unit cell such that the value of GOF (goodness of fit) is close to 1 is preferably employed.

When charging making x in LiₓCoO₂ be less than or equal to 0.24, which enables experimental observation of the H1-3 type structure, and discharging are repeated, the crystal structure of the conventional lithium cobalt oxide repeatedly changes between the H1-3 type structure and the R-3m O3 type structure in a discharged state (i.e., an unbalanced phase change). There is a large shift in the CoO₂ layers between these two crystal structures. As denoted by the dotted lines in FIG. 9, the CoO₂ layer in the H1-3 type structure largely shifts from that in the R-3m O3 type structure in a discharged state. Such a dynamic structural change can adversely affect the stability of the crystal structure.

A difference in volume between these two crystal structures is also large. The difference in volume per the same number of cobalt atoms between the R-3m O3 type crystal structure in a discharged state and the H1-3 type crystal structure is greater than 3.5%, typically greater than or equal to 3.9%.

In addition, a structure in which CoO₂ layers are arranged continuously, as in the trigonal O1 type structure, included in the H1-3 type structure is highly likely to be unstable.

Accordingly, when charging that makes x be less than or equal to 0.24 and discharging are repeated, the crystal structure of conventional lithium cobalt oxide is gradually broken. The broken crystal structure triggers degradation of the cycle performance. This is because the broken crystal structure has a smaller number of sites where lithium can exist stably and makes it difficult to insert and extract lithium.

Meanwhile, in the positive electrode active material 100 of one embodiment of the present invention shown in FIG. 8, a change in the crystal structure between a discharged state with x in LiₓMO₂ of 1 and a state with x of less than or equal to 0.24 is smaller than that in a conventional positive electrode active material. Specifically, a shift in the MO₂ layers between the state with x of 1 and the state with x of less than or equal to 0.24 can be small. When the positive electrode active material 100 and the conventional positive electrode active material that have the same number of atoms of the transition metal M are compared, the positive electrode active material 100 changes in volume less than the conventional positive electrode active material. Thus, in the positive electrode active material 100 of one embodiment of the present invention, the crystal structure is unlikely to be broken and the site at which lithium can be stable is maintained even when charging that makes x be less than or equal to 0.24 and discharging are repeated; accordingly, excellent cycle performance can be achieved.

In addition, the positive electrode active material 100 of one embodiment of the present invention with x in LiₓMO₂ of less than or equal to 0.24 can have a more stable crystal structure than a conventional positive electrode active material with x in LiₓMO₂ of less than or equal to 0.24. Thus, in the positive electrode active material 100 of one embodiment of the present invention, oxygen is not easily released even when the state where x in LiₓMO₂ is less than or equal to 0.24 is maintained, which can inhibit a thermal decomposition reaction. In other words, a secondary battery preferably includes the positive electrode active material 100 of one embodiment of the present invention to have improved safety.

FIG. 8 shows crystal structures of the inner portion 100b of the positive electrode active material 100 in a state where x in LiₓMO₂ is approximately 1, in a state where x in LiₓCoO₂ is approximately 0.2, and in a state where x in LiₓCoO₂ is approximately 0.15. The inner portion 100b, accounting for the majority of the volume of the positive electrode active material 100, largely contributes to charging and discharging and is accordingly a portion where a shift in MO₂ layers and a volume change matter most.

As described above, the positive electrode active material 100 with x being 1 has the crystal structure of R-3m O3, which is the same as that of conventional lithium cobalt oxide. However, the positive electrode active material 100 has a crystal structure different from the H1-3 type crystal structure when x is less than or equal to 0.24, e.g., approximately 0.2 or approximately 0.15, with which conventional lithium cobalt oxide has the H1-3 type crystal structure.

The positive electrode active material 100 of one embodiment of the present invention with x being approximately 0.2 has a trigonal crystal structure belonging to the space group R-3m. The symmetry of the MO₂ layers of this structure is the same as that of 03. Thus, this crystal structure is called an O3′ type crystal structure. Although this crystal structure is not a spinel structure, an XRD pattern similar to that of the spinel structure appears in some cases, and this crystal structure is referred to as a pseudo-spinel structure in some cases. In FIG. 8, this crystal structure is denoted by R-3m O3′. As will be described later, the positive electrode active material 100 sometimes has the H1-3 type structure after having the O3′ type structure; however, it is presumed that the positive electrode active material 100 that has once had the O3′ type structure can have the effect of inhibiting oxygen release even when having the H1-3 type structure, for example, so that a lithium-ion secondary battery that includes the positive electrode active material 100 is less likely to ignite even when subjected to a nail penetration test.

Note that in the unit cell of the O3′ type structure where Mis cobalt, the coordinates of cobalt and oxygen can be represented by Co (0, 0, 0.5) and O (0, 0, x) within the range of 0.20≤x≤0.25. In the unit cell, the lattice constant of the a-axis is preferably 2.797×10⁻¹⁰≤a≤2.837×10⁻¹⁰ (m), further preferably 2.807×10⁻¹⁰≤a≤2.827×10⁻¹⁰ (m), typically a=2.817×10⁻¹⁰ (m). The lattice constant of the c-axis is preferably 13.681× 10-10≤c≤13.881×10⁻¹⁰ (m), further preferably 13.751×10⁻¹⁰≤c≤13.811×10⁻¹⁰ (m), typically, c=13.781×10⁻¹⁰ (m).

When x is approximately 0.15, the positive electrode active material 100 of one embodiment of the present invention has a monoclinic crystal structure belonging to the space group P2/m. In this structure, a unit cell includes one CoO₂ layer. The expression “x is approximately 0.15” may mean that lithium in the positive electrode active material 100 is approximately 15 atomic % of that in a discharged state. Thus, this crystal structure is referred to as a monoclinic O1 (15) type structure. In FIG. 9, this crystal structure is denoted by P2/m monoclinic O1 (15).

In the unit cell of the monoclinic O1 (15) type structure where Mis cobalt, the coordinates of cobalt and oxygen can be represented by:
Co1 (0.5, 0, 0.5),
Co2 (0, 0.5, 0.5),
O1 (X_{O1}, 0, Z_{O1}),
within the ranges of 0.23≤X_{O1}≤0.24 and 0.61≤Z_{O1}≤0.65, and
O2 (X_{O2}, 0.5, Z_{O2})
within the ranges of 0.75≤X_{O2}≤0.78 and 0.68≤Z_{O2}≤0.71. Lattice constants of the unit cell is:

$$a = 0.488 \pm 0.0 \; 05 nm ,$$

$$b = 0.2817 \pm 0.0 \; 05 nm ,$$

$$c = 0. 4839 \pm 0.0 \; 05 nm ,$$

$$α = 90 ° ,$$

$$β = 10 \; 9.6 \pm 0.1 ° , and$$

$$γ = 90 ° .$$

Note that this crystal structure can have the lattice constants even when belonging to the space group R-3m if a certain error is allowed in Rietveld analysis or the like. In this case, the coordinates of cobalt and oxygen in the unit cell can be represented by:
Co (0, 0, 0.5), and
O (0, 0, Z_{O}),
within the range of 0.21≤Z_{O}≤0.23. Lattice constants of the unit cell is:

$$a = 0.2817 \pm 0.0 \; 02 nm , and$$

$$c = 1.368 \pm 0.01 nm .$$

In each of the O3′ type structure and the monoclinic O1 (15) type structure, an ion of cobalt, nickel, magnesium, or the like occupies a site coordinated to six oxygen atoms. Note that a light element such as lithium or magnesium sometimes occupies a site coordinated to four oxygen atoms.

The MO₂ layers hardly shift between the R-3m O3 type structure in a discharged state, the O3′ type structure, and the monoclinic O1 (15) type structure.

The R-3m O3 type structure in a discharged state and the O3′ type structure that include the same number of cobalt atoms have a difference in volume of less than or equal to 2.5%, specifically less than or equal to 2.2%, typically 1.8%.

The R-3m O3 type structure in a discharged state and the monoclinic O1 (15) type structure that include the same number of cobalt atoms have a difference in volume of less than or equal to 3.3%, specifically less than or equal to 3.0%, typically 2.5%.

The table below shows a difference in volume per cobalt atom between the R-3m O3 type structure in a discharged state, the O3′ type structure, the monoclinic O1 (15) type structure, the H1-3 type structure, and the trigonal O1 type structure. For the lattice constants of the R-3m O3 type structure in a discharged state and the trigonal O1 type structure in the table below, which are used for the calculation, ICSD coll. code. 172909 and 88721 can be referred to. For the lattice constants of the H1-3 type structure, Non-Patent Document 3 can be referred to. The lattice constants of the O3′ type structure and the monoclinic O1 (15) type structure can be calculated from the experimental values of XRD.

TABLE 1

| | | | | | Volume | | Volume |
|---|---|---|---|---|---|---|---|
| | | | | | of unit | Volume | change |
| Crystal | Lattice constant | | | | cell | per Co | rate |
| structure | α (Å) | b (Å) | c (Å) | β (°) | (Å³) | (Å³) | (%) |
| R-3m O3 | 2.8156 | 2.8156 | 14.0542 | 90 | 96.49 | 32.16 | — |
| (LiCoO₂) | | | | | | | |
| O3′ | 2.818 | 2.818 | 13.78 | 90 | 94.76 | 31.59 | 1.8 |
| Monoclinic | 4.881 | 2.817 | 4.839 | 109.6 | 62.69 | 31.35 | 2.5 |
| O1(15) | | | | | | | |
| H1-3 | 2.82 | 2.82 | 26.92 | 90 | 185.4 | 30.90 | 3.9 |
| Trigonal O1 | 2.8048 | 2.8048 | 4.2509 | 90 | 28.96 | 28.96 | 10.0 |
| (CoO_{1.92}) | | | | | | | |

As described above, in the positive electrode active material 100 of one embodiment of the present invention, a change in the crystal structure caused when x in LiₓCoO₂ is small, i.e., when a large amount of lithium is extracted, is smaller than that in a conventional positive electrode active material. In addition, when the positive electrode active material 100 and the conventional positive electrode active material having the same number of cobalt atoms are compared, the positive electrode active material 100 changes in volume less than the conventional positive electrode active material. Thus, the crystal structure of the positive electrode active material 100 does not easily break even when charging that makes x be less than or equal to 0.24 and discharging are repeated. Thus, the positive electrode active material 100 inhibits a decrease in charge and discharge capacity in charge and discharge cycles. Furthermore, the positive electrode active material 100 can stably use a large amount of lithium than a conventional positive electrode active material and thus enables high discharge capacity per weight and per volume. Thus, with use of the positive electrode active material 100, a secondary battery with high discharge capacity per weight and per volume can be manufactured.

Note that the positive electrode active material 100 actually has the O3′ type structure in some cases when x in LiₓMO₂ is greater than or equal to 0.15 and less than or equal to 0.24, and is assumed to have the O3′ type structure even when x is greater than 0.24 and less than or equal to 0.27. In addition, the positive electrode active material 100 is confirmed to have the monoclinic O1 (15) type crystal structure in some cases when x in LiₓMO₂ is greater than 0.1 and less than or equal to 0.2, typically greater than or equal to 0.15 and less than or equal to 0.17. However, the crystal structure is influenced by not only x in LiₓMO₂ but also the number of charge and discharge cycles, a charge current and a discharge current, temperature, an electrolyte solution, and the like, so that the range of x is not limited to the above.

Thus, when x in LiₓMO₂ is greater than 0.1 and less than or equal to 0.24, the positive electrode active material 100 may have only the O3′ type crystal structure, only the monoclinic O1 (15) type crystal structure, or both of them. Not all particles in the inner portion 100b of the positive electrode active material 100 necessarily has the O3′ type crystal structure and/or the monoclinic O1 (15) type crystal structure. The positive electrode active material may include another crystal structure or may be partly amorphous.

In order to make x in LiₓMO₂ small, charging at a high charge voltage is necessary in general. Thus, the state where x in LiₓMO₂ is small can be rephrased as a state where charge at a high charge voltage has been performed. For example, when CC/CV charging is performed at a voltage of 4.6 V or higher with reference to the potential of a lithium metal in a 25° C. environment, the H1-3 type crystal structure appears in a conventional positive electrode active material. Thus, a charge voltage of higher than or equal to 4.6 V can be regarded as a high charge voltage with reference to the potential of a lithium metal. In this specification and the like, unless otherwise specified, a charge voltage is shown with reference to the potential of a lithium metal.

Thus, in other words, the positive electrode active material 100 of one embodiment of the present invention is preferable because the crystal structure with the symmetry of R-3m O3 can be maintained even when charging at a high charge voltage of higher than or equal to 4.6 V is performed at 25° C., for example. In other words, the positive electrode active material 100 of one embodiment of the present invention is preferable because the O3′ type crystal structure can be obtained when charge at a higher charge voltage, e.g., a voltage higher than or equal to 4.65 V and lower than or equal to 4.7 V is performed at 25° C. In other words, the positive electrode active material 100 of one embodiment of the present invention is preferable because the monoclinic O1 (15) type crystal structure can be obtained when charge at an even higher charge voltage, e.g., a voltage higher than 4.7 V and lower than or equal to 4.8 V is performed at 25° C.

At a far higher charge voltage, the H1-3 type structure is eventually observed in the positive electrode active material 100 of one embodiment of the present invention in some cases. As described above, the crystal structure is influenced by the number of charge and discharge cycles, a charge current and a discharge current, temperature, an electrolyte solution, and the like, so that the positive electrode active material 100 of one embodiment of the present invention sometimes has the O3′ type structure even at a lower charge voltage, e.g., a charge voltage higher than or equal to 4.5 V and lower than 4.6 V at 25° C. Similarly, the positive electrode active material 100 sometimes has the monoclinic O1 (15) type structure when charging is performed at a voltage higher than or equal to 4.65 V and lower than or equal to 4.7 V at 25° C.

Note that in the case where graphite is used as a negative electrode active material in a secondary battery, the voltage of the secondary battery is lower than the above-mentioned voltages by the potential of graphite. The potential of graphite is approximately 0.05 V to 0.2 V with reference to the potential of a lithium metal. Therefore, in the case of a secondary battery using graphite as a negative electrode active material, a crystal structure similar to the above-described crystal structure is obtained at a voltage corresponding to a difference between the above-described voltage and the potential of the graphite.

Although a chance of the existence of lithium at all lithium sites is the same in the O3′ type structure and the monoclinic O1 (15) type structure in FIG. 8, the present invention is not limited thereto. Lithium may exist unevenly at only some of the lithium sites. For example, lithium may symmetrically exist as in the monoclinic O1 type structure (Li_{0.5}CoO₂) in FIG. 9. The distribution of lithium can be analyzed by neutron diffraction, for example.

Each of the O3′ type structure and the monoclinic O1 (15) type structure can be regarded as a crystal structure that includes lithium between layers randomly and is similar to a CdCl₂ crystal structure. The crystal structure similar to the CdCl₂ crystal structure is close to a crystal structure of lithium nickel oxide that is charged to be Li_{0.06}NiO₂; however, pure lithium cobalt oxide or a layered rock-salt positive electrode active material including a large amount of cobalt is known not to have the CdCl₂ crystal structure generally.

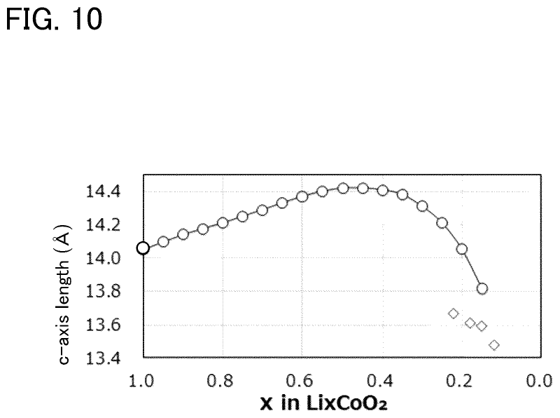

As already described above, the crystal structure of each of conventional lithium cobalt oxide and the positive electrode active material 100 of one embodiment of the present invention changes in accordance with a change in charge depth, i.e., a change in x in LiₓCoO₂. FIG. 10 shows a change in c-axis length of conventional lithium cobalt oxide described in Non-Patent Document 12. Circular markers indicate a hexagonal phase and rhombic markers indicate a monoclinic phase.

Note that a change in c-axis length of lithium cobalt oxide corresponds to a change in the angle at which a peak of, for example, the (003) plane of lithium cobalt oxide appears in an XRD pattern. It is known that a peak of the (003) plane of lithium cobalt oxide appears at around 2θ=19° to 20° in XRD using CuKα1 radiation (obtained by removing CuKα2 radiation).

### <<Crystal Grain Boundary>>

It is further preferable that the additive element included in the positive electrode active material 100 of one embodiment of the present invention have the above-described distribution and be at least partly unevenly distributed at the crystal grain boundary 101 and the vicinity thereof. As already described above, the vicinity of the crystal grain boundary 101 refers to a region of less than or equal to 10 nm from the crystal grain boundary 101.

For example, the magnesium concentration at the crystal grain boundary 101 and the vicinity thereof in the positive electrode active material 100 is preferably higher than that in the other regions in the inner portion 100b. In addition, the fluorine concentration at the crystal grain boundary 101 and the vicinity thereof is preferably higher than that in the other regions in the inner portion 100b. In addition, the nickel concentration at the crystal grain boundary 101 and in the vicinity thereof is preferably higher than that in the other region of the inner portion 100b. In addition, the aluminum concentration at the crystal grain boundary 101 and in the vicinity thereof is preferably higher than that in the other region of the inner portion 100b.

The crystal grain boundary 101 is a type of plane defect. Thus, the crystal grain boundary 101 tends to be unstable and the crystal structure easily starts to change like the surface of the particle. Hence, the higher the concentration of the additive element at the crystal grain boundary 101 and the vicinity thereof is, the more effectively the change in the crystal structure can be reduced.

When the magnesium concentration and the fluorine concentration are high at the crystal grain boundary 101 and the vicinity thereof, the magnesium concentration and the fluorine concentration in the surface and the vicinity thereof generated by a crack are also high even when the crack is generated along the crystal grain boundary 101 of the positive electrode active material 100 of one embodiment of the present invention. Thus, the positive electrode active material having a crack can also have an increased corrosion resistance to hydrofluoric acid.

### <Analysis Method>

Whether or not a given positive electrode active material is the positive electrode active material 100 of one embodiment of the present invention, which has the O3′ type crystal structure and/or monoclinic O1 (15) type crystal structure when x in LiₓCoO₂ is small, can be determined by analyzing a positive electrode including the positive electrode active material with small x in LiₓCoO₂ by XRD, electron diffraction, neutron diffraction, electron spin resonance (ESR), nuclear magnetic resonance (NMR), or the like.

XRD is particularly preferable because the symmetry of a transition metal such as cobalt included in the positive electrode active material can be analyzed with high resolution, the degrees of crystallinity and the crystal orientations can be compared, the distortion of lattice periodicity and the crystallite size can be analyzed, and a positive electrode itself obtained by disassembling a secondary battery can be measured with sufficient accuracy, for example. A diffraction peak reflecting the crystal structure of the inner portion 100b of the positive electrode active material 100, which accounts for the majority of the volume of the positive electrode active material 100, is obtained through XRD, in particular, powder XRD.

In the case where the crystallite size is measured by powder XRD, the measurement is preferably performed while the influence of orientation of positive electrode active material particles due to pressure application or the like is removed. For example, it is preferable that the positive electrode active material layer be taken out from a positive electrode obtained from a disassembled secondary battery and then the measurement be performed. The measurement may be performed after the positive electrode active material is taken out from the positive electrode active material layer.

As described above, the positive electrode active material 100 of one embodiment of the present invention has a feature of a small change in the crystal structure between when x in LiₓCoO₂ is 1 and when x is less than or equal to 0.24. A material 50% or more of which has the crystal structure to be largely changed by high-voltage charge is not preferable because the material cannot withstand repetition of high-voltage charge and discharge.

It should be noted that the O3′ type crystal structure or the monoclinic O1 (15) type crystal structure is not obtained in some cases only by addition of the additive element. For example, although the positive electrode active material has a commonality in lithium cobalt oxide including magnesium and fluorine or lithium cobalt oxide including magnesium and aluminum, when x in LiₓCoO₂ is less than or equal to 0.24, the positive electrode active material forms the O3′ type crystal structure and/or the monoclinic O1 (15) type crystal structure at 60% or more in some cases, and forms the H1-3 type crystal structure at 50% or more in other cases, depending on the concentration and distribution of the additive element.

In addition, in the case where x is too small, e.g., less than or equal to 0.1, or under the condition where charge voltage is higher than 4.9 V, the positive electrode active material 100 of one embodiment of the present invention sometimes has the H1-3 type crystal structure or the trigonal O1 type crystal structure. Thus, determining whether or not a positive electrode active material is the positive electrode active material 100 of one embodiment of the present invention requires analysis of the crystal structure by XRD and other methods and data such as charge capacity or charge voltage.

Note that a positive electrode active material with small x sometimes causes a change in the crystal structure when exposed to the air. For example, the O3′ type crystal structure and the monoclinic O1 (15) type crystal structure change into the H1-3 type crystal structure in some cases.

For that reason, all samples subjected to analysis of crystal structures are preferably handled in an inert atmosphere such as an argon atmosphere.

For example, analysis using XPS, EDX, EPMA (electron probe microanalysis), or the like can be used to determine whether the distribution of the additive element A included in a given positive electrode active material is in the above-described state.

The crystal structure of the surface portion 100a, the crystal grain boundary 101, or the like can be analyzed by electron diffraction of a cross section of the positive electrode active material 100, for example.

### <<Charge Method>>

Whether or not a composite oxide is the positive electrode active material 100 of one embodiment of the present invention can be determined by charging a coin cell (CR2032 type with a diameter of 20 mm and a height of 3.2 mm) that is formed using the composite oxide and a lithium metal respectively for a positive electrode and a counter electrode, for example. The coin cell includes an electrolyte solution, a separator, a positive electrode can, and a negative electrode can.

More specifically, a positive electrode can be formed by applying a slurry in which the composite oxide as a positive electrode active material, a conductive material, and a binder are mixed to a positive electrode current collector made of aluminum foil.

A lithium metal can be used for the counter electrode as described above, but a material other than a lithium metal may be alternatively used. When a material other than the lithium metal is used, the potential of a secondary battery differs from the potential of the positive electrode. Unless otherwise specified, the voltage and the potential in this specification and the like refer to a potential of a positive electrode.

As a lithium salt included in the electrolyte solution, 1 mol/L lithium hexafluorophosphate (LiPF₆) can be used. As the electrolyte solution, an electrolyte solution in which ethylene carbonate (EC) and diethyl carbonate (DEC) at EC:DEC=3:7 (volume ratio) and vinylene carbonate (VC) at 2 wt % are mixed can be used.

As a separator, a 25-μm-thick polypropylene porous film can be used.

A positive electrode can and a negative electrode can each formed of stainless steel (SUS) can be used.

The coin cell manufactured with the above conditions is charged up to a given voltage (e.g., 4.5 V, 4.55 V, 4.6 V, 4.65 V, 4.7 V, 4.75 V, or 4.8 V). The charge method is not particularly limited as long as charging up to a given voltage can be performed for sufficient time. In the case of CCCV charging, for example, CC charging can be performed with a current higher than or equal to 20 mA/g and lower than or equal to 100 mA/g. CV charging can be ended with a current higher than or equal to 2 mA/g and lower than or equal to 10 mA/g. To observe a phase change of the positive electrode active material, charge with such a small current value is preferably performed. The temperature is set to 25° C., since it is difficult to perform XRD measurement at a temperature lower than or equal to 0° C. Note that 25° C. is an exemplary temperature. After charging is performed in this manner, the coin cell is disassembled in a glove box with an argon atmosphere to take out the positive electrode, whereby the positive electrode active material with a given charge capacity can be obtained. In order to inhibit a reaction with components in the external environment, the positive electrode is preferably enclosed in an argon atmosphere in performing various analyses later. For example, XRD measurement can be performed on the positive electrode active material enclosed in an airtight container with an argon atmosphere. After the charge is completed, it is preferable that the positive electrode be taken out immediately and later-described XRD analysis be started. Specifically, the positive electrode is preferably subjected to analysis within 1 hour, further preferably within 30 minutes after the completion of charge.

In the case where the crystal structure in a charged state after charging and discharging are performed multiple times is analyzed, the conditions of the charging and discharging performed multiple times may be different from the above-described charge conditions. For example, as charging, constant current charging to a given voltage (e.g., 4.6 V, 4.65 V, 4.7 V, 4.75 V, or 4.8 V) at a current value higher than or equal to 20 mA/g and lower than or equal to 100 mA/g can be performed and then constant voltage charging can be performed until the current value becomes higher than or equal to 2 mA/g and lower than or equal to 10 mA/g, and as discharging, constant current discharging can be performed until the voltage reaches 2.5 V at higher than or equal to 20 mA/g and lower than or equal to 100 mA/g.

Also in the case where the crystal structure in a discharged state after charging and discharging are performed multiple times is analyzed, the discharging conditions in the charging and discharging performed multiple times can be as follows, for example: constant current discharging is performed at 2.5 V and a current value higher than or equal to 20 mA/g and lower than or equal to 100 mA/g, for example.

### <<XRD>>

The apparatus and conditions of the XRD measurement are not particularly limited as long as appropriate adjustment and calibration are performed. The measurement can be performed with the apparatus and conditions as described below, for example.
XRD apparatus: D8 ADVANCE manufactured by Bruker AXS Inc.
X-ray: CuKα ray, CuKα₁ ray
Output: 40 kV, 40 mA
Angle of divergence: Div. Slit, 0.5°
Detector: LynxEye
Scanning method: 2θ/θ continuous scanning
Measurement range (2θ): from 15° to 90° Step width (2θ): 0.01°
Counting time: one second/step
Rotation of sample stage: 15 rpm
As a standard sample used for the adjustment and calibration, a standard sintered alumina plate SRM 1976 from NIST (National Institute of Standards and Technology) can be used, for example.

In the case where the measurement sample is a powder, the sample can be set by, for example, being put on a glass sample holder or being sprinkled on a reflection-free silicon plate to which grease is applied. In the case where the measurement sample is a positive electrode, the positive electrode can be set in the following manner: the positive electrode is attached to a substrate with a double-sided adhesive tape and the position of the positive electrode active material layer can be adjusted to the measurement plane required by the apparatus.

Characteristic X-rays may be monochromatized with the use of a filter or the like or may be monochromatized with XRD data analysis software after an XRD pattern is obtained. For example, a peak due to CuKα₂ radiation can be eliminated and only a peak due to CuKα₁ radiation can be extracted by using DIFFRAC.EVA (XRD data analysis software manufactured by Bruker Corporation). This software can also be used to eliminate the background, for example.

Data processing for a 2θ value of a diffraction peak in this specification and the like is described. First, a calculation model is fitted for an XRD pattern with the use of crystal structure analysis software to obtain a pattern after calculation. Then, the 2θ value at which a peak top of the diffraction peak appears in the pattern after the calculation is defined as the 2θ value of the diffraction peak. There is no particular limitation on the crystal structure analysis software used for the fitting; for example, it is possible to use TOPAS ver. 3 (crystal structure analysis software manufactured by Bruker Corporation).

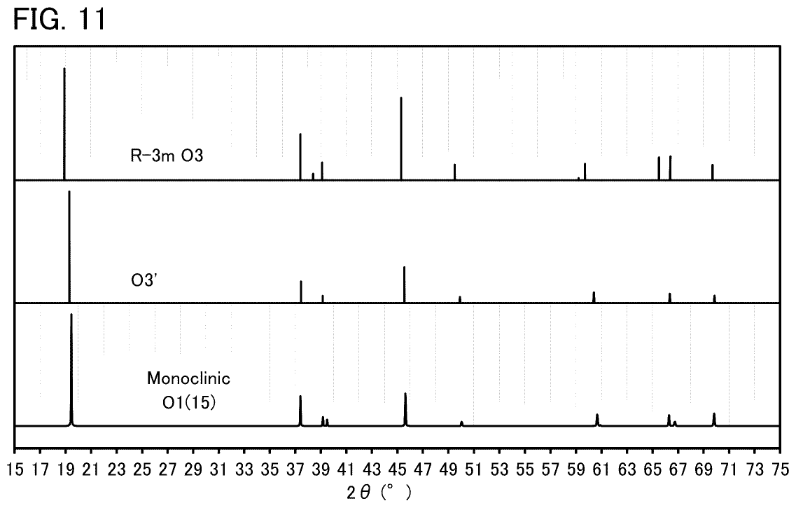

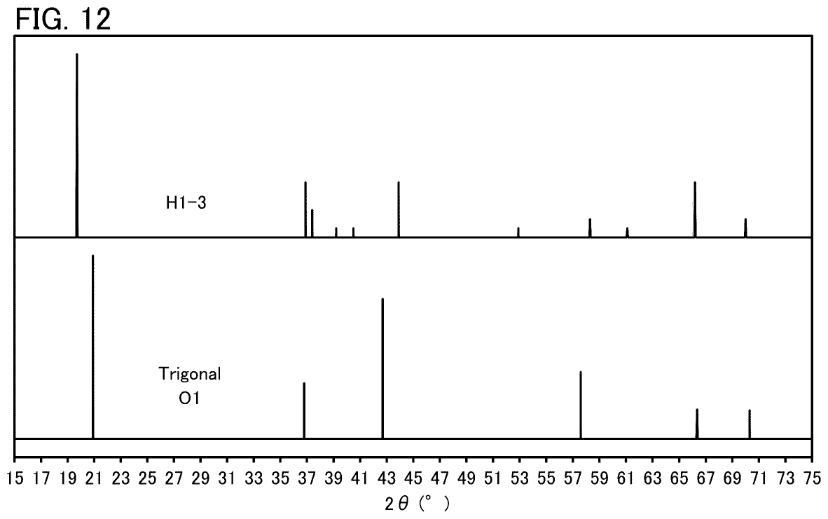

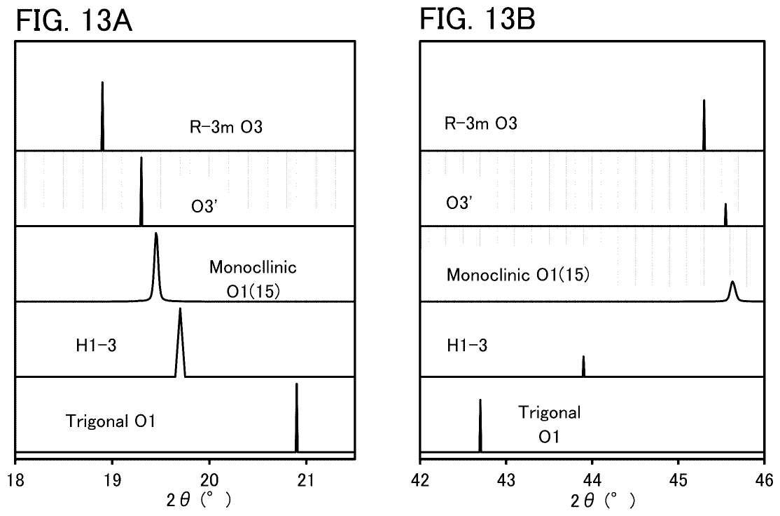

FIG. 11 shows XRD patterns corresponding to the O3 type crystal structure, the O3′ type crystal structure, and the monoclinic O1 (15) type crystal structure of the case where CuKα₁ radiation is used. FIG. 12 shows an ideal powder XRD pattern with CuKα₁ radiation calculated from a model of the H1-3 type crystal structure and an ideal XRD pattern with CuKα₁ radiation calculated from the trigonal O1 type crystal structure with x of 0. FIG. 13A and FIG. 13B show all the XRD patterns described above. Note that the patterns in the range of 20 of 18° to 21°, and the range of 20 of 42° to 46° are shown. Note that the patterns of LiCoO₂ (O3) and CoO₂ (O1) are made from crystal structure data obtained from ICSD (Inorganic Crystal Structure Database) (see Non-Patent Document 5) using Reflex Powder Diffraction, which is a module of Materials Studio (BIOVIA). At this time, the 20 range was from 15° to 75°, the step size was 0.01, the wavelength λ was 1.54×10⁻¹⁰ m, and a single monochromator was used. The pattern of the H1-3 type crystal structure is similarly made from the crystal structure data disclosed in Non-Patent Document 3. The patterns of the O3′ type crystal structure and the monoclinic O1 (15) type crystal structure are obtained in the following manner: the crystal structures are estimated from the XRD pattern of the positive electrode active material 100 of one embodiment of the present invention, and fitting is performed with TOPAS ver. 3 (crystal structure analysis software manufactured by Bruker Corporation).

As shown in FIG. 11 and FIG. 13A and FIG. 13B, the O3′ type structure exhibits diffraction peaks at 2θ of 19.25±0.12° (greater than or equal to 19.13° and less than) 19.37° and of 45.47±0.10° (greater than or equal to 45.37° and less than 45.57°).

The monoclinic O1 (15) type structure exhibits diffraction peaks at 2θ of 19.47±0.10° (greater than or equal to 19.37° and less than or equal to 19.
57°) and 2θ of 45.62±0.05° (greater than or equal to 45.57° and less than or equal to 45.67°).

However, as shown in FIG. 12 and FIG. 13A and FIG. 13B, the H1-3 type structure and the trigonal O1 type structure do not exhibit peaks at these positions. Thus, exhibiting the peak at 2θ of greater than or equal to 19.13° and less than 19.37° and/or the peak at 2θ of greater than or equal to 19.37° and less than or equal to 19.57° and the peak at 2θ of greater than or equal to 45.37° and less than 45.57° and/or the peak at 2θ of greater than or equal to 45.57° and less than or equal to 45.67° in a state with small x in LiₓCoO₂ can be the feature of the positive electrode active material 100 of one embodiment of the present invention.

It can be said that the position of an XRD diffraction peak exhibited by the crystal structure with x of 1 is close to that of an XRD diffraction peak exhibited by the crystal structure with x of less than or equal to 0.24. More specifically, it can be said that a difference in 2θ between the main diffraction peak exhibited by the crystal structure with x=1 and the main diffraction peak exhibited by the crystal structure with x=0.24, which are exhibited at 2θ of greater than or equal to 42° and less than or equal to 46°, is less than or equal to 0.7°, preferably less than or equal to 0.5°.

Although the positive electrode active material 100 of one embodiment of the present invention has the O3′ type structure and/or the monoclinic O1 (15) type structure when x in LixCoO2 is small, not all the particles necessarily have the O3′ type structure and/or the monoclinic O1 (15) type structure. The positive electrode active material may include another crystal structure or may be partly amorphous. Note that when the XRD patterns are subjected to Rietveld analysis, the O3′ type crystal structure and/or the monoclinic O1 (15) type crystal structure preferably account(s) for greater than or equal to 50%, further preferably greater than or equal to 60%, still further preferably greater than or equal to 66%. The positive electrode active material in which the O3′ type crystal structure and/or the monoclinic O1 (15) type crystal structure account(s) for greater than or equal to 50%, preferably greater than or equal to 60%, further preferably greater than or equal to 66% enables sufficiently good cycle performance.

Furthermore, even after 100 or more cycles of charge and discharge after the measurement starts, the O3′ type crystal structure and/or the monoclinic O1 (15) type crystal structure preferably account(s) for greater than or equal to 35%, further preferably greater than or equal to 40%, still further preferably greater than or equal to 43% when Rietveld analysis is performed.

In addition, the H1-3 type crystal structure and the O1 type crystal structure preferably account for less than or equal to 50% in Rietveld analysis performed in a similar manner. Alternatively, the H1-3 type crystal structure and the O1 type crystal structure further preferably account for less than or equal to 34%. It is further preferable that substantially no H1-3 type crystal structure and substantially no O1 type crystal structure be observed.

Sharpness of a diffraction peak in an XRD pattern indicates the degree of crystallinity. It is thus preferable that the diffraction peaks after charge be sharp, in other words, have a small half width, e.g., a small full width at half maximum. Even peaks that are derived from the same crystal phase have different half widths depending on the XRD measurement conditions and the value. In the case of the above-described measurement conditions, the peak observed at 20 greater than or equal to 43° and less than or equal to 46° preferably has a full width at half maximum of less than or equal to 0.2°, further preferably less than or equal to 0.15°, still further preferably less than or equal to 0.12°. Note that not all peaks need to fulfill the requirement. A crystal phase can be regarded as having high crystallinity when some peaks fulfill the requirement. Such high crystallinity sufficiently contributes to stability of the crystal structure after charge.

The crystallite sizes of the O3′ type crystal structure and the monoclinic O1 (15) type crystal structure included in the positive electrode active material 100 do not decrease to less than approximately one-twentieth that of LiCoO₂ (O3) in a discharged state. Thus, a clear peak(s) of the O3′ type crystal structure and/or the monoclinic O1 (15) type crystal structure can be observed when x in LiₓCoO₂ is small, even under the same XRD measurement conditions as those of a positive electrode before charge and discharge. In contrast, conventional LiCoO₂ has a small crystallite size and a broad and small peak even when it can have a structure part of which is similar to the O3′ type crystal structure and/or the monoclinic O1 (15) type crystal structure. The crystallite size can be calculated from the half width of the XRD peak.

As described above, the influence of the Jahn-Teller effect is preferably small in the positive electrode active material 100 of one embodiment of the present invention. The positive electrode active material 100 may include a transition metal such as nickel or manganese as the additive element in addition to cobalt as long as the influence of the Jahn-Teller effect is small.

The proportions of nickel and manganese and the range of the lattice constants in each of which the influence of the Jahn-Teller effect is presumed to be small in the positive electrode active material are examined by XRD analysis.

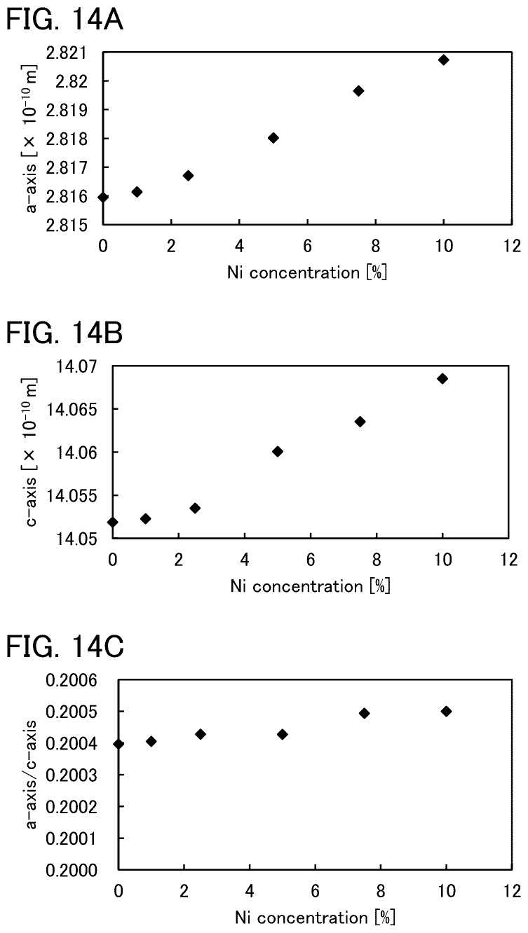

FIG. 14A to FIG. 14C show the calculation results of the lattice constants of the a-axis and the c-axis by XRD in the case where the positive electrode active material 100 of one embodiment of the present invention has a layered rock-salt crystal structure and includes cobalt and nickel. FIG. 14A shows the results of the a-axis, and FIG. 14B shows the results of the c-axis. Note that the XRD patterns of a powder after the synthesis of the positive electrode active material before incorporation into a positive electrode are used for the calculation. The nickel concentration on the horizontal axis represents a nickel concentration with the sum of cobalt atoms and nickel atoms assumed as 100%.

FIG. 14C shows values obtained by dividing the lattice constants of the a-axis by the lattice constants of the c-axis (a-axis/c-axis) in the positive electrode active material, whose results of the lattice constants are shown in FIG. 14A and FIG. 14B.

As shown in FIG. 14C, the value of a-axis/c-axis tends to significantly change between nickel concentrations of 5% and 7.5%, and the distortion of the a-axis becomes large at a nickel concentration of 7.5%. This distortion may be derived from the Jahn-Teller distortion of trivalent nickel. It is suggested that an excellent positive electrode active material with small Jahn-Teller distortion can be obtained at a nickel concentration lower than 7.5%.

Note that the nickel concentration in the surface portion 100a is not limited to the above range. In other words, the nickel concentration in the surface portion 100a may be higher than the above concentration.

Examination of preferable ranges of the lattice constants of the positive electrode active material of one embodiment of the present invention based on the above revealed that, in the layered rock-salt crystal structure of the positive electrode active material 100 in a discharged state or a state where charging and discharging are not performed, which can be estimated from the XRD patterns, the a-axis lattice constant is preferably greater than 2.814×10⁻¹⁰ m and less than 2.817×10⁻¹⁰ m, and the lattice constant of the c-axis is preferably greater than 14.05×10⁻¹⁰ m and less than 14.07×10⁻¹⁰ m. The state where charging and discharging are not performed may be the state of powder before the manufacture of a positive electrode of a secondary battery.

Alternatively, in the layered rock-salt crystal structure of the positive electrode active material 100 in a discharged state or the state where charging and discharging are not performed, the value obtained by dividing the lattice constant of the a-axis by the lattice constant of the c-axis (a-axis/c-axis) is preferably greater than 0.20000 and less than 0.20049.

Alternatively, when the layered rock-salt crystal structure of the positive electrode active material 100 in the discharged state or the state where charging and discharging are not performed is subjected to XRD analysis, a first peak is observed at 20 of greater than or equal to 18.50° and less than or equal to 19.30° and a second peak is observed at 20 of greater than or equal to 38.00° and less than or equal to 38.80°, in some cases.

### <<XPS>>

In an inorganic oxide, a region from the particle surface to a depth of approximately 2 nm to 8 nm (typically, less than or equal to 5 nm) can be analyzed by XPS using monochromatic aluminum Kα radiation as an X-ray; thus, the concentrations of elements in a region to approximately half the depth of the surface portion 100a can be quantitatively analyzed. The bonding states of the elements can be analyzed by narrow scanning.

In the positive electrode active material 100 of one embodiment of the present invention, the concentration of one or two or more selected from the additive elements is preferably higher in the surface portion 100a than in the inner portion 100b. This means that the concentration of one or two or more selected from the additive elements in the surface portion 100a is preferably higher than the average concentration of the selected element(s) in the entire positive electrode active material 100. For this reason, for example, it is preferable that the concentration of one or more additive elements selected from the surface portion 100a, which is measured by XPS or the like, be higher than the average concentration of the additive element(s) in the entire positive electrode active material 100, which is measured by ICP-MS, GD-MS, or the like. For example, the magnesium concentration in at least part of the surface portion 100a, which is measured by XPS or the like, is preferably higher than the average magnesium concentration in the entire positive electrode active material 100. The nickel concentration in at least part of the surface portion 100a is preferably higher than the average nickel concentration in the entire positive electrode active material 100. The aluminum concentration in at least part of the surface portion 100a is preferably higher than the average aluminum concentration in the entire positive electrode active material 100. The concentration of fluorine in at least part of the surface portion 100a is preferably higher than the average concentration of fluorine in the entire positive electrode active material 100.

Note that the surface and the surface portion 100a of the positive electrode active material 100 of one embodiment of the present invention do not include a carbonate, a hydroxy group, or the like which is chemically adsorbed after manufacture of the positive electrode active material 100. Furthermore, an electrolyte solution, a binder, a conductive material, and a compound originating from any of these that are attached to the surface of the positive electrode active material 100 are not included either. Thus, in quantification of the elements included in the positive electrode active material, correction may be performed to exclude carbon, hydrogen, excess oxygen, excess fluorine, and the like that might be detected in surface analysis such as XPS. For example, in XPS, the kinds of bonds can be identified by analysis, and a C—F bond originating from a binder may be excluded by correction.

Furthermore, before any of various kinds of analyses is performed, a sample such as a positive electrode active material and a positive electrode active material layer may be washed, for example, to eliminate an electrolyte solution, a binder, a conductive material, and a compound originating from any of these that are attached to the surface of the positive electrode active material. Although lithium might be dissolved into a solvent or the like used in the washing at this time, the additive element is not easily dissolved even in that case; thus, the atomic ratio of the additive element is not affected.

The concentration of the additive element may be compared using the ratio of the additive element to cobalt. The ratio of the additive element to cobalt is preferably used, in which case comparison can be performed while reducing the influence of a carbonate or the like that is chemically adsorbed after formation of the positive electrode active material. For example, in the XPS analysis, the ratio of the number of magnesium atoms to the number of cobalt atoms (Mg/Co) is preferably greater than or equal to 0.4 and less than or equal to 1.5. In the ICP-MS analysis, Mg/Co is preferably greater than or equal to 0.001 and less than or equal to 0.06.

Similarly, to ensure the sufficient path through which lithium is inserted and extracted, the concentrations of lithium and cobalt are preferably higher than those of the additive elements in the surface portion 100a of the positive electrode active material 100. This means that the concentrations of lithium and cobalt in the surface portion 100a are preferably higher than the concentration of one or more selected from the additive elements included in the surface portion 100a, which is measured by XPS or the like. For example, the concentration of cobalt in at least part of the surface portion 100a, which is measured by XPS or the like, is preferably higher than the magnesium concentration in at least part of the surface portion 100a, which is measured by XPS or the like. Similarly, the concentration of lithium is preferably higher than the magnesium concentration. In addition, the concentration of cobalt is preferably higher than the nickel concentration. Similarly, the concentration of lithium is preferably higher than the nickel concentration. The concentration of cobalt is preferably higher than the aluminum concentration. Similarly, the concentration of lithium is preferably higher than the aluminum concentration. The concentration of cobalt is preferably higher than the concentration of fluorine. Similarly, the concentration of lithium is preferably higher than the concentration of fluorine.

It is further preferable that the additive element such as aluminum be widely distributed in a deep region, for example, in a region at a depth greater than or equal to 5 nm and less than or equal to 50 nm from the surface. Therefore, the additive element such as aluminum is detected by analysis on the entire positive electrode active material 100 by ICP-MS, GD-MS, or the like, and its concentration may be different from the results of analysis by XPS or the like on a region of approximately 5 nm from the surface.

Furthermore, when XPS analysis is performed on the positive electrode active material 100 of one embodiment of the present invention, the number of magnesium atoms is preferably greater than or equal to 0.4 times and less than or equal to 1.2 times, further preferably greater than or equal to 0.65 times and less than or equal to 1.0 times the number of cobalt atoms. The number of nickel atoms is preferably less than or equal to 0.15 times, further preferably greater than or equal to 0.03 times and less than or equal to 0.13 times the number of cobalt atoms. The number of aluminum atoms is preferably less than or equal to 0.12 times, further preferably less than or equal to 0.09 times the number of cobalt atoms. The number of fluorine atoms is preferably greater than or equal to 0.1 times and less than or equal to 1.1 times, further preferably greater than or equal to 0.3 times and less than or equal to 0.9 times the number of cobalt atoms. When the number is within the above range, it can be said that the additive element is not attached to the surface of the positive electrode active material 100 in a narrow range but widely distributed at a preferable concentration in the surface portion 100a of the positive electrode active material 100.

In the XPS analysis, monochromatic aluminum Ko radiation can be used as an X-ray, for example. An extraction angle is, for example, 45°, and measurement can be performed with the following apparatus and conditions.
Measurement apparatus: Quantera II manufactured by PHI, Inc.
X-ray: monochromatic Al Kα (1486.6 eV)
Detection area: 100 μmφ
Detection depth: approximately 4-5 nm (extraction angle) 45°
Measurement spectrum: wide scanning, narrow scanning of each detected element

In addition, when the positive electrode active material 100 of one embodiment of the present invention is analyzed by XPS, a peak indicating the bonding energy of fluorine with another element is preferably at greater than or equal to 682 eV and less than 685 eV, further preferably approximately 684.3 eV. The above value is different from 685 eV, which is the bonding energy of lithium fluoride, and 686 eV, which is the bonding energy of magnesium fluoride.

Furthermore, when the positive electrode active material 100 of one embodiment of the present invention is analyzed by XPS, a peak indicating the bonding energy of magnesium with another element is preferably at greater than or equal to 1302 eV and less than 1304 eV, further preferably at approximately 1303 eV. The above value is different from 1305 eV, which is the bonding energy of magnesium fluoride, and is close to the bonding energy of magnesium oxide.

### <<EDX>>

The one or two or more selected from the additive elements included in the positive electrode active material 100 preferably have a concentration gradient. It is further preferable that the additive elements included in the positive electrode active material 100 exhibit concentration peaks at different depths from the surface. The concentration gradient of the additive element can be evaluated by, for example, exposing a cross section of the positive electrode active material 100 using an FIB or the like and analyzing the cross section using EDX, EPMA, or the like.

In the EDX measurement, to measure a region while scanning is performed and evaluate the region two-dimensionally is referred to as EDX area analysis. The measurement for evaluation of the atomic concentration distribution in a positive electrode active material by line scan is referred to as line analysis. Furthermore, extracting data of a linear region from EDX area analysis is referred to as line analysis in some cases. The measurement of a region without scanning is referred to as point analysis.

By EDX area analysis (e.g., element mapping), the concentrations of the additive elements in the surface portion 100a, the inner portion 100b, the crystal grain boundary 101 and the vicinity thereof, and the like of the positive electrode active material 100 can be quantitatively analyzed. By EDX line analysis, the concentration distribution and the highest additive element concentration can be analyzed. An analysis method in which a thinned sample is used, such as STEM-EDX, is preferable because the method makes it possible to analyze the concentration distribution in the depth direction from the surface toward the center in a specific region of the positive electrode active material regardless of the distribution in the front-back direction.

Thus, EDX area analysis or EDX point analysis of the positive electrode active material 100 of one embodiment of the present invention preferably reveals that the concentration of the additive element such as magnesium in the surface portion 100a is higher than that in the inner portion 100b.

For example, EDX area analysis or EDX point analysis of the positive electrode active material 100 including magnesium as the additive element preferably reveals that the magnesium concentration in the surface portion 100a is higher than the magnesium concentration in the inner portion 100b. In the EDX line analysis, a peak of the magnesium concentration in the surface portion 100a is preferably present at a depth of less than or equal to 3 nm, further preferably less than or equal to 1 nm, still further preferably less than or equal to 0.5 nm toward the center from the surface of the positive electrode active material 100. In addition, the magnesium concentration preferably attenuates, at a depth of 1 nm from the point where the concentration reaches the peak, to less than or equal to 60% of the peak concentration. In addition, the magnesium concentration preferably attenuates, at a depth of 2 nm from the point where the concentration reaches the peak, to less than or equal to 30% of the peak concentration. Here, a “peak of concentration” refers to the local maximum value of concentration.

When the positive electrode active material 100 includes magnesium and fluorine as the additive elements, the distribution of fluorine preferably overlaps with the distribution of magnesium. For example, a difference in the depth direction between a peak of the concentration of fluorine and a peak of the magnesium concentration is preferably within 10 nm, further preferably within 3 nm, still further preferably within 1 nm.

In the EDX line analysis, a peak of the fluorine concentration in the surface portion 100a is preferably present at a depth of less than or equal to 3 nm, further preferably less than or equal to 1 nm, still further preferably less than or equal to 0.5 nm toward the center from the surface of the positive electrode active material 100. It is further preferable that a peak of the fluorine concentration be exhibited slightly closer to the surface side than a peak of the magnesium concentration is, which increases resistance to hydrofluoric acid. For example, it is preferable that a peak of the fluorine concentration be exhibited closer to the surface side than a peak of the magnesium concentration is by 0.5 nm or more, further preferably 1.5 nm or more.

When the positive electrode active material 100 including nickel as the additive element, a peak of the nickel concentration in the surface portion 100a is preferably present at a depth of less than or equal to 3 nm, further preferably less than or equal to 1 nm, still further preferably less than or equal to 0.5 nm toward the center from the surface of the positive electrode active material 100. When the positive electrode active material 100 includes magnesium and nickel, the distribution of nickel preferably overlaps with the distribution of magnesium. For example, a difference in the depth direction between a peak of the nickel concentration and a peak of the magnesium concentration is preferably 10 nm or less, further preferably less than or equal to 3 nm, still further preferably less than or equal to 1 nm.

In the case where the positive electrode active material 100 includes aluminum as the additive element, in the EDX line analysis, the peak of the magnesium concentration, the nickel concentration, or the fluorine concentration is preferably closer to the surface than the peak of the aluminum concentration is in the surface portion 100a. For example, the peak of the aluminum concentration is preferably present at a depth that is greater than or equal to 0.5 nm and less than or equal to 50 nm, further preferably greater than or equal to 5 nm and less than or equal to 50 nm toward the center from the surface of the positive electrode active material 100.

EDX line, area, or point analysis of the positive electrode active material 100 preferably reveals that the ratio of the number of magnesium (Mg) atoms to the number of cobalt (Co) atoms (Mg/Co) at a peak of the magnesium concentration is less than 1, preferably greater than or equal to 0.05 and less than or equal to 0.6, further preferably greater than or equal to 0.1 and less than or equal to 0.4. The ratio of the number of aluminum (Al) atoms to the number of cobalt (Co) atoms (Al/Co) at a peak of the aluminum concentration is less than 1, preferably greater than or equal to 0.05 and less than or equal to 0.6, further preferably greater than or equal to 0.1 and less than or equal to 0.45. The ratio of the number of nickel (Ni) atoms to the number of cobalt (Co) atoms (Ni/Co) at a peak of the nickel concentration is less than 1, preferably greater than or equal to 0 and less than or equal to 0.2, further preferably greater than or equal to 0.01 and less than or equal to 0.1. Alternatively, Ni/Co is preferably greater than or equal to 0.1 and less than or equal to 0.5. The ratio of the number of cobalt (Co) atoms to the number of nickel (Ni) atoms (Co: Ni) preferably ranges from 90:10 to 80:20 or 70:30. The ratio of the number of fluorine (F) atoms to the number of cobalt (Co) atoms (F/Co) at a peak of the fluorine concentration is less than 1, preferably greater than or equal to 0 and less than or equal to 1.6, further preferably greater than or equal to 0.1 and less than or equal to 1.4.

According to results of the EDX line analysis, where the surface of the positive electrode active material 100 is can be estimated in the following manner. A point where the detected amount of an element which uniformly exists in the inner portion 100b of the positive electrode active material 100, e.g., oxygen or cobalt, is ½ of the detected amount thereof in the inner portion 100b is assumed as the surface.

Since the positive electrode active material 100 is a composite oxide, the detected amount of oxygen can be used to estimate where the surface is. Specifically, an average value Oₐᵥₑ of the oxygen concentration in a region of the inner portion 100b where the detected amount of oxygen is stable is calculated first. At this time, in the case where oxygen O_{bg} which is probably led from chemical adsorption or the background is detected in a region that is obviously outside the surface, O_{bg} is subtracted from the measurement value to obtain the average value Oₐᵥₑ of the oxygen concentration. The measurement point where the measurement value which is closest to ½ of the average value Oₐᵥₑ, or Oₐᵥₑ/2, is obtained can be estimated to be the surface of the positive electrode active material.

The detected amount of cobalt can also be used to estimate where the surface is as in the above description. Alternatively, the sum of the detected amounts of the transition metals can be used for the estimation in a similar manner. The detected amount of the transition metal such as cobalt is unlikely to be affected by chemical adsorption and is thus suitable for the estimation of where the surface is.

When the positive electrode active material 100 is subjected to line analysis or area analysis, the ratio of the number of atoms of an additive element A to the number of cobalt (Co) atoms (A/Co) in the crystal grain boundary 101 or vicinity thereof is preferably greater than or equal to 0.020 and less than or equal to 0.50. Furthermore, it is preferably greater than or equal to 0.025 and less than or equal to 0.30. Furthermore, it is preferably greater than or equal to 0.030 and less than or equal to 0.20. Alternatively, it is preferably greater than or equal to 0.020 and less than or equal to 0.30. Alternatively, it is preferably greater than or equal to 0.020 and less than or equal to 0.20. Alternatively, it is preferably greater than or equal to 0.025 and less than or equal to 0.50. Alternatively, it is preferably greater than or equal to 0.025 and less than or equal to 0.20. Alternatively, it is preferably greater than or equal to 0.030 and less than or equal to 0.50. Alternatively, it is preferably greater than or equal to 0.030 and less than or equal to 0.30.

In the case where the additive element is magnesium, for example, when the positive electrode active material 100 is subjected to line analysis or area analysis, the ratio of the number of magnesium atoms to the number of cobalt atoms (Mg/Co) in the crystal grain boundary 101 or vicinity thereof is preferably greater than or equal to 0.020 and less than or equal to 0.50. Furthermore, it is preferably greater than or equal to 0.025 and less than or equal to 0.30. Furthermore, it is preferably greater than or equal to 0.030 and less than or equal to 0.20. Alternatively, it is preferably greater than or equal to 0.020 and less than or equal to 0.30. Alternatively, it is preferably greater than or equal to 0.020 and less than or equal to 0.20. Alternatively, it is preferably greater than or equal to 0.025 and less than or equal to 0.50. Alternatively, it is preferably greater than or equal to 0.025 and less than or equal to 0.20. Alternatively, it is preferably greater than or equal to 0.030 and less than or equal to 0.50. Alternatively, it is preferably greater than or equal to 0.030 and less than or equal to 0.30. When the ratio is within the above range in a plurality of portions, e.g., three or more portions of the positive electrode active material 100, it can be said that the additive element is not attached to the surface of the positive electrode active material 100 in a narrow range but widely distributed at a preferable concentration in the surface portion 100a of the positive electrode active material 100.

A coating portion may be attached to at least part of the surface of the positive electrode active material 100. FIGS. 15A and 15B respectively show the positive electrode active material 100 in FIG. 5A and that in FIG. 5C to which the coating portion 104 is attached.

The coating portion 104 is preferably formed by deposition of decomposition products of a lithium salt, an organic electrolyte solution, and the like due to charging and discharging, for example. A coating portion originating from an organic electrolyte solution, which is formed on the surface of the positive electrode active material 100, is expected to improve charge and discharge cycle performance particularly when charge that makes x in LiₓCoO₂ be less than or equal to 0.24 is repeated. This is because an increase in impedance of the surface of the positive electrode active material is inhibited or dissolution of cobalt is inhibited, for example. The coating portion 104 preferably includes carbon, oxygen, and fluorine, for example. The coating portion can have high quality easily when the electrolyte solution includes LiBOB and/or suberonitrile (SUN), for example. Accordingly, the coating portion 104 preferably includes one or more selected from boron, nitrogen, sulfur, and fluorine to possibly have high quality. The coating portion 104 does not necessarily cover the positive electrode active material 100 entirely. For example, the coating portion 104 covers greater than or equal to 50%, preferably greater than or equal to 70%, further preferably greater than or equal to 90% of the surface of the positive electrode active material 100. In a portion without the coating portion 104, fluorine may be adsorbed onto the surface of the positive electrode active material 100.

### <Laminated Secondary Battery>

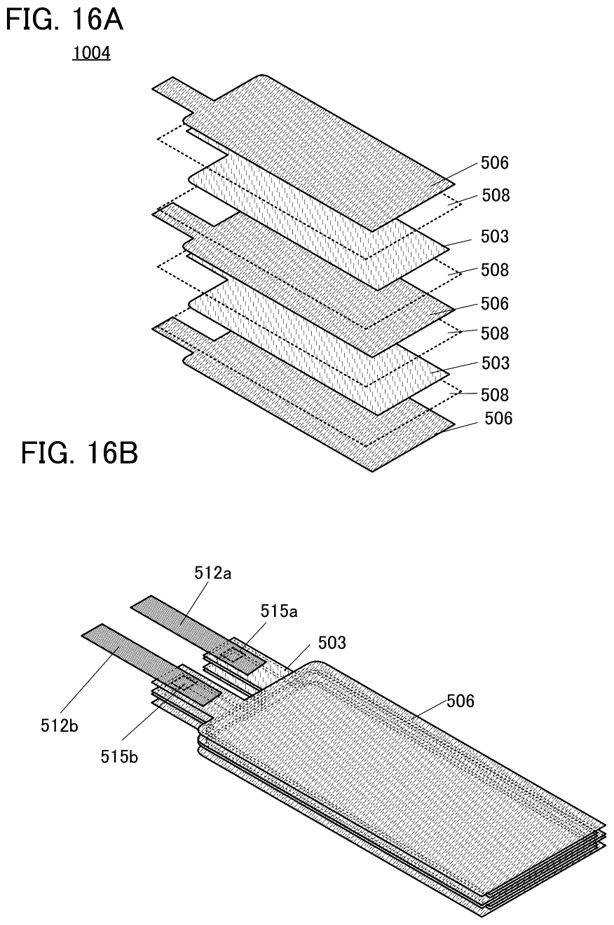

A secondary battery of one embodiment of the present invention will be described. First, a typical laminated secondary battery is described with reference to FIGS. 16A and 16B and the like.

As illustrated in FIG. 16A, the secondary battery 1004 includes a plurality of the positive electrodes 503, a plurality of the negative electrodes 506, and a plurality of the separators 508. The separator 508 is provided between the positive electrode 503 and the negative electrode 506; in FIG. 16A, the separators 508 are indicated with dotted lines for clarity. In some cases, the separators 508 each include an electrolyte, or specifically, a liquid electrolyte (also referred to as an electrolyte solution). The secondary battery 1004 does not necessarily include the separators 508 when including a solid electrolyte or a semisolid electrolyte as an electrolyte.

The positive electrode 503 and the negative electrode 506 each include a protruding tab portion and a portion other than the tab portion. To the tab portions, the wiring 1005a, the wiring 1005b, and the like can be electrically connected in the nail penetration test device. The positive electrode 503 includes the positive electrode current collector and the positive electrode active material layer formed on the positive electrode current collector; it is preferable that the positive electrode active material layers be formed on both surfaces of the positive electrode current collector. The negative electrode 506 includes the negative electrode current collector and the negative electrode active material layer formed on the negative electrode current collector; it is preferable that the negative electrode active material layers be formed on both surfaces of the negative electrode current collector.

As shown in FIG. 16B, the plurality of positive electrodes 503, the plurality of negative electrodes 506, and the plurality of separators 508 are stacked, which are sometimes referred to as a stack as a whole in this specification and the like. The tab portions of the plurality of negative electrodes 506 are bonded together with a lead 512b at a bonding portion 515b and are electrically connected to each other. The tab portions of the plurality of positive electrodes 503 are bonded together with a lead 512a at a bonding portion 515a and are electrically connected to each other. The positive electrode active material layer and the negative electrode active material layer (simply referred to as active material layers) have a better insulating property than the positive electrode current collector and the negative electrode current collector (simply referred to as current collectors); thus, it is preferable that no active material layer be formed at the tab portions. The lead 512a and the lead 512b can be formed using a material selected from aluminum, nickel, copper, titanium, and an alloy thereof. Bonding at the bonding portion can be performed using ultrasonic welding. For the nail penetration test, the lead 512a and the lead 512b are optional; in the case where the nail penetration test is performed with the lead 512a and the lead 512b provided, the wiring 1005a and the wiring 1005b are electrically connected to the lead 512a and the lead 512b, respectively.

The secondary battery 1004 further includes the exterior body (not shown), and the stack shown in FIG. 16A is held in the exterior body. Then, an electrolyte solution in which a lithium salt is dissolved, for example, is poured into the exterior body. That is, the electrolyte solution includes carrier ions, typically lithium ions. The secondary battery including the lithium ions is referred to as a lithium-ion secondary battery.

The exterior body is preferably in the form of a film in terms of weight reduction, and the secondary battery that includes an exterior body in the form of a film can be referred to as a laminated secondary battery. In terms of achieving a high cooling performance, the exterior body may be formed using a high-thermal-conductivity stack of a polymer and a metal. Specifically, it is preferable that the polymer and the metal be respectively polypropylene and aluminum, and nylon or the like may be disposed outside the exterior body. The exterior body may be alternatively a metal can case, and the secondary battery whose exterior body is a circular can case is referred to as a coin-type secondary battery.

This embodiment can be used in combination with the other embodiments.

### Embodiment 2

In this embodiment, an example of a method for manufacturing the positive electrode active material 100 of one embodiment of the present invention will be described.

A way of adding the additive element is important in manufacturing the positive electrode active material 100 having the distribution of the additive element, the composition, and/or the crystal structure described in the above embodiment. Favorable crystallinity of the inner portion 100b is important as well.

In the manufacturing process of the positive electrode active material 100 using one method, lithium cobalt oxide is synthesized first, an additive element source is then mixed, and heat treatment is performed. A method in which an additive element source is mixed in the same step as a cobalt source and a lithium source to synthesize lithium cobalt oxide including the additive element may alternatively be employed. It is preferable that heating be performed in addition to mixing of lithium cobalt oxide and the additive element source to make the additive element be formed a solid solution with lithium cobalt oxide. Sufficient heating is preferably performed to enable favorable distribution of the additive element. The heat treatment after the mixing of the additive element source is thus important. The heat treatment after the mixing of the additive element source may be referred to as baking or annealing.

However, heat treatment at an excessively high temperature may cause cation mixing, which increases the possibility of entry of the additive element such as magnesium into the cobalt sites. Magnesium that exists at the cobalt sites does not have an effect of maintaining a layered rock-salt crystal structure belonging to R-3m when x in LiₓCoO₂ is small. Furthermore, heat treatment at an excessively high temperature might have an adverse effect; for example, cobalt might be reduced to have a valence of two or lithium might be evaporated.

Here, a material functioning as a fusing agent is preferably mixed together with the additive element source or is preferably mixed as an additive element source. As the material functioning as a fusing agent, a substance having a lower melting point than lithium cobalt oxide can be used. As the fusing agent, for example, a fluorine compound such as lithium fluoride is preferably used. Addition of a fusing agent lowers the melting points of the additive element source and lithium cobalt oxide. Lowering the melting points makes it easier to favorably distribute the additive element at a temperature at which cation mixing is unlikely to occur.

It is further preferable that heat treatment be performed after the synthesis of the lithium cobalt oxide before the mixing of the additive element, as well. This heating is referred to as initial heating in some cases.

Owing to influence of lithium extraction from part of the surface portion 100a of the lithium cobalt oxide by the initial heating, the distribution of the additive element becomes more favorable.

Specifically, the distributions of the additive elements can be easily made different from each other by the initial heating in the following mechanism. First, lithium is extracted from part of the surface portion 100a by the initial heating. Next, the additive element sources such as a nickel source, an aluminum source, and a magnesium source and lithium cobalt oxide including the surface portion 100a that is deficient in lithium are mixed and heated. Among the additive elements, magnesium is a divalent representative element, and nickel is a transition metal but is likely to be a divalent ion. Therefore, in part of the surface portion 100a, a rock-salt phase including Co²⁺, which is obtained by reduction due to lithium deficiency, Mg²⁺, and Ni²⁺ is formed. However, this phase is formed in part of the surface portion 100a, and thus is sometimes not clearly observed in an image obtained with an electron microscope, such as a STEM, and an electron diffraction pattern.

Among the additive elements, nickel is likely to be formed a solid solution and is diffused to the inner portion 100b in the case where the surface portion 100a is lithium cobalt oxide that has a layered rock-salt crystal structure, but nickel is likely to remain in the surface portion 100a in the case where part of the surface portion 100a has a rock-salt crystal structure. Thus, the initial heating can make it easy for a divalent additive element such as nickel to remain in the surface portion 100a. The effect of this initial heating is large particularly at the surface having an orientation other than the (001) orientation of the positive electrode active material 100 and the surface portion 100a thereof.

Furthermore, in such a rock-salt crystal structure, the bond distance between a metal Me and oxygen (Me-O distance) tends to be longer than that in a layered rock-salt crystal structure.

For example, the Me-O distance is 2.09×10⁻¹⁰ m and 2.11×10⁻¹⁰ m in Ni_{0.5}Mg_{0.5}O having a rock-salt crystal structure and MgO having a rock-salt crystal structure, respectively. Even when a spinel phase is formed in part of the surface portion 100a, the Me-O distance is 2.0125×10⁻¹⁰ m and 2.02×10⁻¹⁰ m in NiAl₂O₄ having a spinel structure and MgAl₂O₄ having a spinel structure, respectively. In each case, the Me-O distance is longer than 2×10⁻¹⁰ m. Meanwhile, in a layered rock-salt crystal structure, the bond distance between oxygen and a metal other than lithium is shorter than the above-described distance. For example, the Al—O distance is 1.905×10⁻¹⁰ m (Li—O distance is 2.11×10⁻¹⁰ m) in LiAlO₂ having a layered rock-salt crystal structure. In addition, the Co—O distance is 1.9224×10⁻¹⁰ m (Li—O distance is 2.0916×10⁻¹⁰ m) in LiCoO₂ having a layered rock-salt crystal structure.

According to Shannon's ionic radius, the ion radius of hexacoordinated aluminum is 0.535×10⁻¹⁰ m and the ion radius of hexacoordinated oxygen is 1.4×10⁻¹⁰ m and the sum of these values is 1.935×10⁻¹⁰ m.

From the above, aluminum is considered to be present at sites other than lithium sites more stably in a layered rock-salt crystal structure than in a rock-salt crystal structure. Thus, in the surface portion 100a, aluminum is more likely to be distributed in a region having a layered rock-salt phase at a larger depth and/or the inner portion 100b than in a region having a rock-salt phase and being close to the surface.

Moreover, the initial heating can potentially have an effect of increasing the crystallinity of the layered rock-salt crystal structure of the inner portion 100b.

For this reason, the initial heating is preferably performed in forming the positive electrode active material 100 that has the monoclinic O1 (15) type crystal structure when x in LiₓCoO₂ is, for example, greater than or equal to 0.15 and less than or equal to 0.17.

However, the initial heating is not necessarily performed. In some cases, by controlling atmosphere, temperature, time, or the like in another heating step, the positive electrode active material 100 that has the O3′ type structure and/or the monoclinic O1 (15) type structure when x in LiₓCoO₂ is small can be formed.

### <Eutectic Point>

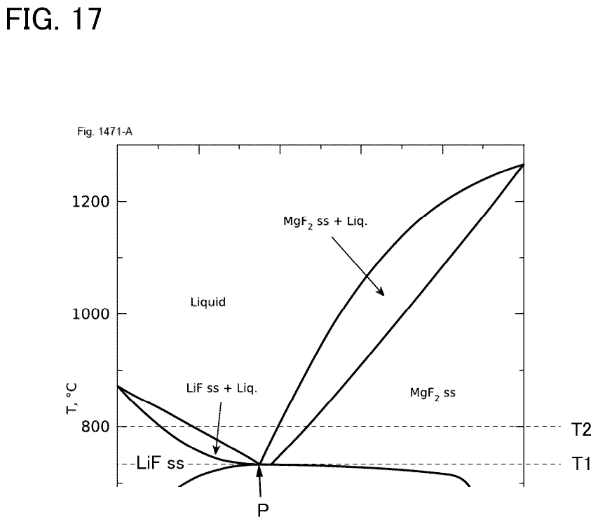

In the case where a fluorine compound (also referred to as a fluoride in some cases) such as lithium fluoride has a lower melting point than another additive element source, the fluorine compound or the like can serve as a fusing agent (also referred to as a flux agent) for lowering the melting point of the another additive element source. In the case of a fluorine compound including LiF and MgF₂, the eutectic point P of LiF and MgF₂ is around 742° C. (T1) as shown in FIG. 17 (which is cited from FIG. 6 of Non-Patent Document 12 and retouched); thus, the heating temperature in the heating step following the mixing of the additive element is preferably set higher than or equal to 742° C.

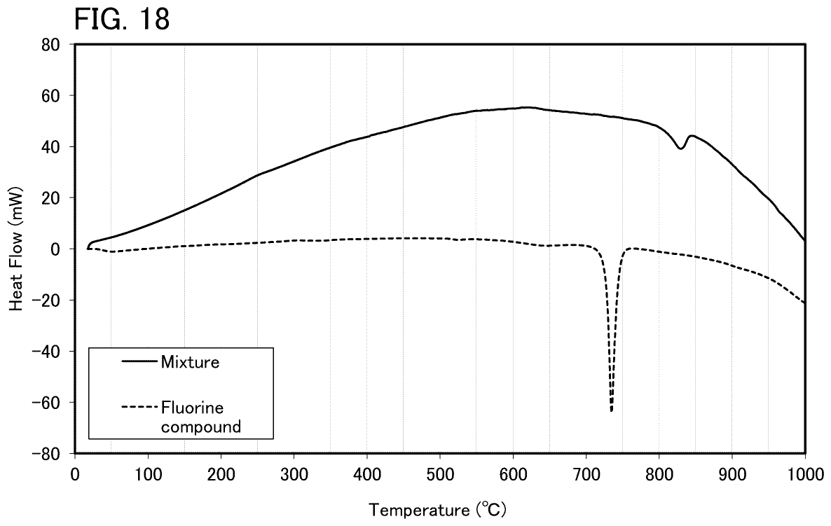

Here, DSC measurement of a fluorine compound and a mixture is described with reference to FIG. 18. The mixture in FIG. 18 is obtained by mixing lithium cobalt oxide as the lithium oxide and LiF and MgF₂ as the fluorine compound. Specifically, the mixture is obtained by performing mixing at LiCoO₂:LiF:MgF₂=100:0.33:1 (molar ratio). The fluorine compound in FIG. 18 is a mixture of LiF and MgF₂. Specifically, the fluorine compound is obtained by performing mixing at LiF:MgF₂=1:3 (molar ratio).

As shown in FIG. 18, the endothermic peak of the fluorine compound is observed around 735° C. The endothermic peak of the mixture of lithium cobalt oxide, LiF, and MgF₂ is observed at around 830° C. Thus, the temperature of the heating following the mixing of the additive element is preferably higher than or equal to 742° C., further preferably higher than or equal to 830° C. Alternatively, 800° C. (T2 in FIG. 17) or higher between the temperatures is preferably employed.

### <<Manufacturing Method 1 of Positive Electrode Active Material>>

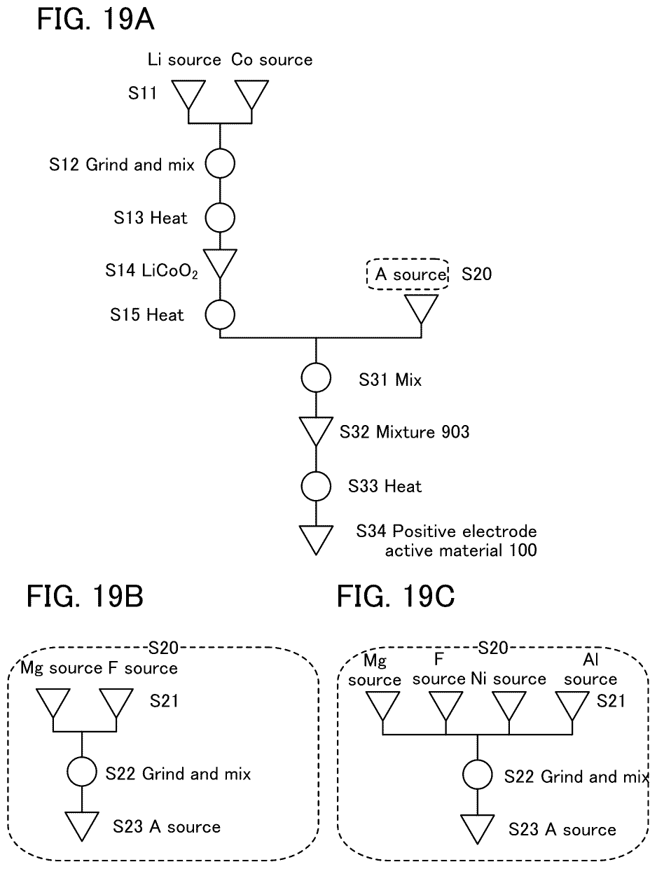

A manufacturing method 1 of the positive electrode active material 100, in which initial heating is performed, will be described with reference to FIG. 19A to FIG. 19C.

### <Step S11>

In Step S11 shown in FIG. 19A, a lithium source (Li source) and a cobalt source (Co source) are prepared as materials for lithium and a transition metal which are starting materials.

As the lithium source, a lithium-including compound is preferably used and for example, lithium carbonate, lithium hydroxide, lithium nitrate, lithium fluoride, or the like can be used. The lithium source preferably has a high purity and is preferably a material having a purity higher than or equal to 99.99%, for example.

As the cobalt source, a cobalt-including compound is preferably used, and for example, cobalt oxide such as tricobalt tetraoxide or cobalt hydroxide can be used.

The cobalt source preferably has a high purity and is preferably a material having a purity of higher than or equal to 3N (99.9%), further preferably higher than or equal to 4N (99.99%), still further preferably higher than or equal to 4N5 (99.995%), yet further preferably higher than or equal to 5N (99.999%), for example. Impurities of the positive electrode active material can be controlled by using such a high-purity material. As a result, a secondary battery with an increased capacity and/or increased reliability can be obtained.

Furthermore, the cobalt source preferably has high crystallinity, and preferably includes single crystal particles, for example. The crystallinity of the cobalt source can be evaluated with a TEM image, an STEM image, a HAADF-STEM image, or an ABF-STEM image or by XRD, electron diffraction, neutron diffraction, or the like. Note that the above methods for evaluating crystallinity can also be employed to evaluate the crystallinity of materials other than the cobalt source.

### <Step S12>

Next, in Step S12 shown in FIG. 19A, the lithium source and the cobalt source are ground and mixed to form a mixed material. The grinding and mixing can be performed by a dry method or a wet method. A wet method is preferable because it can crush a material into a smaller size. When the grinding and mixing are performed by a wet method, a solvent is prepared. As the solvent, a ketone such as acetone, an alcohol such as ethanol or isopropanol, an ether, dioxane, acetonitrile, N-methyl-2-pyrrolidone (NMP), or the like can be used. An aprotic solvent, which is unlikely to react with lithium, is preferably used. In this embodiment, dehydrated acetone with a purity higher than or equal to 99.5% is used. It is preferable that the lithium source and the cobalt source be mixed into dehydrated acetone whose moisture content is less than or equal to 10 ppm and which has a purity higher than or equal to 99.5% in the grinding and mixing. With the use of dehydrated acetone with the above-described purity, impurities that might be mixed can be reduced.

A ball mill, a bead mill, or the like can be used for the grinding and mixing. When a ball mill is used, aluminum oxide balls or zirconium oxide balls are preferably used as a medium. Zirconium oxide balls are preferable because they release fewer impurities. When a ball mill, a bead mill, or the like is used, the peripheral speed is preferably higher than or equal to 100 mm/s and lower than or equal to 2000 mm/s in order to inhibit contamination from the medium. In this embodiment, the peripheral speed is set to 838 mm/s (the rotational frequency is 400 rpm, and the diameter of the ball mill is 40 mm).

### <Step S13>

Next, in Step S13 shown in FIG. 19A, the above mixed material is heated. The heating is preferably performed at higher than or equal to 800° C. and lower than or equal to 1100° C., further preferably at higher than or equal to 900° C. and lower than or equal to 1000° C., still further preferably at approximately 950° C. An excessively low temperature might lead to insufficient decomposition and melting of the lithium source and the cobalt source. An excessively high temperature might lead to a defect due to evaporation of lithium from the lithium source and/or excessive reduction of cobalt, for example. An oxygen vacancy or the like might be induced by a change of trivalent cobalt into divalent cobalt, for example.

When the heating time is too short, lithium cobalt oxide is not synthesized, but when the heating time is too long, the productivity is lowered. For example, the heating time is preferably longer than or equal to 1 hour and shorter than or equal to 100 hours, further preferably longer than or equal to 2 hours and shorter than or equal to 20 hours.

A temperature rising rate is preferably higher than or equal to 80° C./h and lower than or equal to 250° C./h, although depending on the end-point temperature of the heating. For example, in the case of heating at 1000° C. for 10 hours, the temperature raising rate is preferably 200° C./h.

The heating is preferably performed in an atmosphere with little water such as a dry-air atmosphere and for example, the dew point of the atmosphere is preferably lower than or equal to −50° C., further preferably lower than or equal to −80° C. In this embodiment, the heating is performed in an atmosphere with a dew point of −93° C. To reduce impurities that might enter the material, the concentrations of impurities such as CH₄, CO, CO₂, and H₂ in the heating atmosphere are each preferably lower than or equal to 5 ppb (parts per billion).

The heating atmosphere is preferably an oxygen-containing atmosphere. In a method, a dry air is continuously introduced into a reaction chamber. The flow rate of a dry air in this case is preferably 10 L/min. A method of continuously introducing oxygen into a reaction chamber to make oxygen flow therein is referred to as flowing.

In the case where the heating atmosphere is an oxygen-containing atmosphere, it is preferable that flowing not be performed. As a method that does not allow flowing, for example, there is a method in which the pressure in the reaction chamber is reduced, the reaction chamber is filled (which may also be referred to as purged) with oxygen, and the oxygen is prevented from exiting from the reaction chamber. For example, it is preferable that the pressure be reduced until a differential pressure gauge in the reaction chamber reads −970 hPa, and then the reaction chamber be filled with oxygen until the pressure becomes 50 hPa.

Cooling after the heating can be performed by natural cooling, and the time it takes for the temperature to decrease to room temperature from a predetermined temperature is preferably longer than or equal to 10 hours and shorter than or equal to 50 hours; for example, the temperature falling rate (hereinafter also referred to as cooling rate) is preferably higher than or equal to 80° C./h and lower than or equal to 250° C./h, further preferably higher than or equal to 180° C./h and lower than or equal to 210° C./h. Note that the temperature does not necessarily need to decrease to room temperature as long as it decreases to a temperature acceptable to the next step.

The heating in this step may be performed with a rotary kiln or a roller hearth kiln. Heating with stirring can be performed in either case of a sequential rotary kiln or a batch-type rotary kiln.

As a crucible used at the time of the heating, a crucible made of aluminum oxide is preferable. A crucible made of aluminum oxide has a material property that hardly releases impurities. In this embodiment, a crucible made of aluminum oxide with a purity of 99.9% is used. The heating is preferably performed with the crucible covered with a lid. This can prevent volatilization or sublimation of a material. A lid at least prevents volatilization or sublimation of a material at the time when the temperature is increased and decreased in this step, and does not necessarily seal off a crucible. For example, this step can be performed without sealing off the crucible in the case where the reaction chamber is filled with oxygen as described above.

A used crucible is preferred to a new crucible. In this specification and the like, a new crucible refers to a crucible that is subjected to heating two or less times while a material including lithium, the transition metal M, and/or the additive element is included therein. A used crucible refers to a crucible that is subjected to heating three or more times while a material including lithium, the transition metal M, and/or the additive element is included therein. In the case where a new crucible is used, some materials such as lithium fluoride might be absorbed by, diffused in, transferred to, and/or attached to a sagger. Loss of some materials due to such phenomena increases a concern that an element is not distributed in a preferred range particularly in the surface portion of the positive electrode active material. In contrast, such a risk is low in the case of a used crucible.

After the heating, the heated material is ground as needed and may be made to pass through a sieve. Before collection of the heated material, the material may be moved from the crucible to a mortar. As the mortar, an aluminum oxide mortar or a zirconium oxide mortar is suitably used. An aluminum oxide mortar is made of a material that hardly releases impurities. Specifically, a mortar made of aluminum oxide with a purity higher than or equal to 90%, preferably higher than or equal to 99% is used. Note that heating conditions equivalent to those in Step S13 can be employed in a later-described heating step other than Step S13.

### <Step S14>

Through the above process, lithium cobalt oxide (LiCoO₂) can be synthesized in Step S14 in FIG. 19A. In the case where a median diameter (D50) is employed as the particle diameter of lithium cobalt oxide, lithium cobalt oxide is preferably ground in order to obtain the positive electrode active material 100 with a relatively small median diameter (D50).

Although the example is described in which the composite oxide is formed by a solid phase method as in Step S11 to Step S14, the composite oxide may be formed by a coprecipitation method. Alternatively, the composite oxide may be formed by a hydrothermal method.

### <Step S15>

Next, as Step S15 shown in FIG. 19A, the lithium cobalt oxide is heated. The heating in Step S15 is the first heating performed on the lithium cobalt oxide and thus, this heating is sometimes referred to as the initial heating. The heating is performed before Step S20 described below, and thus is sometimes referred to as preheating or pretreatment. The crucible, lid, and/or the like used in this step are/is similar to those used in Step S13. Although the initial heating is expected to have the following effects, the initial heating is not essential in obtaining the positive electrode active material of one embodiment of the present invention.

By the initial heating, lithium is extracted from part of the surface portion 100a of the lithium cobalt oxide as described above. In addition, an effect of increasing the crystallinity of the inner portion 100b can be expected. The lithium source and/or the cobalt source prepared in Step S11 and the like might include impurities. The initial heating can reduce impurities in the lithium cobalt oxide completed in Step S14.

Through the initial heating, an effect of smoothing the surface of the lithium cobalt oxide is obtained. The composite oxide having a smooth surface refers to the composite oxide that has little unevenness and is rounded as a whole with its corner portion rounded. A smooth surface also refers to a surface to which few foreign matters are attached. Foreign matters are deemed to cause unevenness and are preferably not attached to a surface.

For the initial heating, there is no need to prepare a lithium source. For the initial heating, there is no need to prepare the additive element source. Alternatively, there is no need to prepare a material functioning as a fusing agent.

When the heating time in this step is too short, a sufficient effect is not obtained, but when the heating time in this step is too long, the productivity is lowered. For example, any of the heating conditions described for Step S13 can be selected to perform the heating. Additionally, the heating temperature in this step is preferably lower than that in Step S13 so that the crystal structure of the composite oxide is maintained. The heating time in this step is preferably shorter than that in Step S13 so that the crystal structure of the composite oxide is maintained. For example, the heating is preferably performed at a temperature of higher than or equal to 700° C. and lower than or equal to 1000° C. for longer than or equal to 2 hours and shorter than or equal to 20 hours.

The effect of increasing the crystallinity of the inner portion 100b is, for example, an effect of reducing distortion, a shift, or the like derived from differential shrinkage or the like of the lithium cobalt oxide formed in Step S13.

The heating in Step S13 might cause a temperature difference between the surface and an inner portion of the lithium cobalt oxide. The temperature difference sometimes induces differential shrinkage. It can also be deemed that the temperature difference leads to a fluidity difference between the surface and the inner portion, thereby causing differential shrinkage. The energy involved in differential shrinkage causes a difference in internal stress in the lithium cobalt oxide. The difference in internal stress is also called distortion, and the above energy is sometimes referred to as distortion energy. The internal stress is eliminated by the initial heating in Step S15 and in other words, the distortion energy is probably equalized by the initial heating in Step S15. When the distortion energy is equalized, the distortion in the lithium cobalt oxide is relieved. Accordingly, the surface of the lithium cobalt oxide may become smooth. This is also rephrased as modification of the surface. In other words, it is deemed that Step S15 reduces the differential shrinkage caused in the lithium cobalt oxide to make the surface of the composite oxide smooth.

Such differential shrinkage might cause a micro shift in the lithium cobalt oxide such as a shift in a crystal. To reduce the shift, this step is preferably performed. Performing this step can distribute a shift uniformly in the composite oxide. When the shift is distributed uniformly, the surface of the composite oxide might become smooth. This is also referred to as alignment of crystal grains. In other words, it can be deemed that Step S15 reduces the shift in a crystal or the like which is caused in the composite oxide and makes the surface of the composite oxide smooth.

In a secondary battery including lithium cobalt oxide with a smooth surface as a positive electrode active material, deterioration by charge and discharge is suppressed and cracking in the positive electrode active material can be prevented.

Note that pre-synthesized lithium cobalt oxide may be used in Step S14. In this case, Step S11 to Step S13 can be omitted. When Step S15 is performed on the pre-synthesized lithium cobalt oxide, lithium cobalt oxide with a smooth surface can be obtained.

### <Step S20>

Next, as shown in Step S20, the additive element A is preferably added to the lithium cobalt oxide that has been subjected to the initial heating. When the additive element A is added to the lithium cobalt oxide that has been subjected to the initial heating, the additive element A can be uniformly added. It is thus preferable that the initial heating precede the addition of the additive element A. The step of adding the additive element A is described with reference to FIG. 19B and FIG. 19C.

### <Steps S21 to S23>

The steps of preparing an additive element A source (A source) are described with reference to FIGS. 19B and 19C. A lithium source may be prepared in addition to the additive element A source.

As the additive element A, the additive element described in the above embodiment, e.g., one or more selected from magnesium, fluorine, nickel, aluminum, titanium, zirconium, vanadium, iron, manganese, chromium, niobium, arsenic, zinc, silicon, sulfur, phosphorus, and boron can be used. Furthermore, one or both of bromine and beryllium can be used.

### <Step S21>

Step S21 shown in FIG. 19B is described. When magnesium is selected as the additive element, the additive element source can be referred to as a magnesium source (Mg source). As the magnesium source, magnesium fluoride, magnesium oxide, magnesium hydroxide, magnesium carbonate, or the like can be used. Two or more of these magnesium sources may be used.

When fluorine is selected as the additive element, the additive element source can be referred to as a fluorine source (F source). As the fluorine source, for example, lithium fluoride (LiF), magnesium fluoride (MgF₂), aluminum fluoride (AlF₃), titanium fluoride (TiF₄), cobalt fluoride (CoF₂ and CoF₃), nickel fluoride (NiF₂), zirconium fluoride (ZrF₄), vanadium fluoride (VF₅), manganese fluoride, iron fluoride, chromium fluoride, niobium fluoride, zinc fluoride (ZnF₂), calcium fluoride (CaF₂), sodium fluoride (NaF), potassium fluoride (KF), barium fluoride (BaF₂), cerium fluoride (CeF₃ and CeF₄), lanthanum fluoride (LaF₃), sodium aluminum hexafluoride (Na₃AlF₆), or the like can be used. In particular, lithium fluoride is preferable because it is easily melted in a heating step described later owing to its relatively low melting point of 848° C.

Magnesium fluoride can be used as both the fluorine source and the magnesium source. Lithium fluoride can also be used as both the fluorine source and the lithium source. Another example of the lithium source that can be used in Step S21 is lithium carbonate.

The fluorine source may preferably be a gas; for example, fluorine (F₂), carbon fluoride, sulfur fluoride, oxygen fluoride (OF₂, O₂F₂, O₃F₂, O₄F₂, O₅F₂, O₆F₂, and O₂F), or the like may be used and mixed in the atmosphere in a heating step described later. Two or more of these fluorine sources may be used.

In this embodiment, lithium fluoride (LiF) is prepared as the fluorine source, and magnesium fluoride (MgF₂) is prepared as the fluorine source and the magnesium source. When lithium fluoride and magnesium fluoride are mixed at approximately LiF:MgF₂=65:35 (molar ratio), the effect of lowering the melting point is maximized. Meanwhile, when the proportion of lithium fluoride increases, cycle performance might be degraded because of an excessive amount of lithium. Therefore, the molar ratio of lithium fluoride to magnesium fluoride is preferably LiF:MgF₂=x:1 (0≤x≤1.9), further preferably LiF:MgF₂=x:1 (0.1≤x≤0.5), still further preferably LiF:MgF₂=x:1 (x is 0.33 or a value in the vicinity thereof). Note that here, the vicinity means a value greater than 0.9 times and less than 1.1 times a given value.

### <Step S22>

Next, in Step S22 shown in FIG. 19B, the magnesium source and the fluorine source are ground and mixed. Any of the conditions for grinding and mixing that are described for Step S12 can be selected to perform this step.

### <Step S23>

Next, in Step S23 shown in FIG. 19B, the materials ground and mixed in the above step are collected to give the additive element A source (A source). Note that the additive element A source shown in Step S23 includes a plurality of starting materials and can be referred to as a mixture.

As for the particle diameter of the mixture, the median diameter (D50) is preferably greater than or equal to 600 nm and less than or equal to 10 μm, further preferably greater than or equal to 1 μm and less than or equal to 5 μm. When one kind of material is used as the additive element source, the median diameter (D50) is preferably greater than or equal to 600 nm and less than or equal to 10 μm, further preferably greater than or equal to 1 μm and less than or equal to 5 μm.

Such a pulverized mixture (which may include only one kind of the additive element) is easily attached to the surface of lithium cobalt oxide particles uniformly in a later step of mixing with the lithium cobalt oxide. The mixture is preferably attached uniformly to the surface of the lithium cobalt oxide particles, in which case the additive element is easily distributed or dispersed uniformly in the surface portion 100a of the composite oxide after heating.

### <Step S21>

A process different from that in FIG. 19B is described with reference to FIG. 19C. In Step S21 shown in FIG. 19C, four kinds of additive element sources to be added to the lithium cobalt oxide are prepared. In other words, FIG. 19C is different from FIG. 19B in the kinds of the additive element sources. A lithium source may be prepared together with the additive element sources.

As the four kinds of additive element sources, a magnesium source (Mg source), a fluorine source (F source), a nickel source (Ni source), and an aluminum source (A1 source) are prepared. Note that the magnesium source and the fluorine source can be selected from the compounds and the like described with reference to FIG. 19B. As the nickel source, nickel oxide, nickel hydroxide, or the like can be used. As the aluminum source, aluminum oxide, aluminum hydroxide, or the like can be used.

### <Step S22 and Step S23>

Step S22 and Step S23 shown in FIG. 19C are similar to the steps described with reference to FIG. 19B.

### <Step S31>

Next, in Step S31 shown in FIG. 19A, the lithium cobalt oxide and the additive element A source (A source) are mixed. The atomic ratio of cobalt Co in the lithium cobalt oxide to magnesium Mg included in the additive element A source is preferably Co: Mg=100:y (0.1≤y≤6), further preferably Co:Mg=100:y (0.3≤y≤3).

The condition of the mixing in Step S31 is preferably milder than that of the mixing in Step S12 not to damage the lithium cobalt oxide particle shape. For example, conditions with a lower rotational frequency or a shorter time than those for the mixing in Step S12 are preferable. In addition, it can be said that a dry method has a milder condition than a wet method. For example, a ball mill or a bead mill can be used for the mixing. When a ball mill is used, zirconium oxide balls are preferably used as a medium, for example.

In this embodiment, the mixing is performed with a ball mill using zirconium oxide balls with a diameter of 1 mm by a dry method at 150 rpm for 1 hour. The mixing is performed in a dry room the dew point of which is higher than or equal to −100° C. and lower than or equal to −10° C.

### <Step S32>

Next, in Step S32 in FIG. 19A, the materials mixed in the above step are collected to give a mixture 903. At the time of the collection, the materials may be crushed as needed and made to pass through a sieve.

Note that although FIG. 19A to FIG. 19C show the formation method in which addition of the additive element is performed after the initial heating, the present invention is not limited to the above-described method. The addition of the additive element may be performed at another timing or may be performed a plurality of times. The timing of the addition may be different between the additive elements.

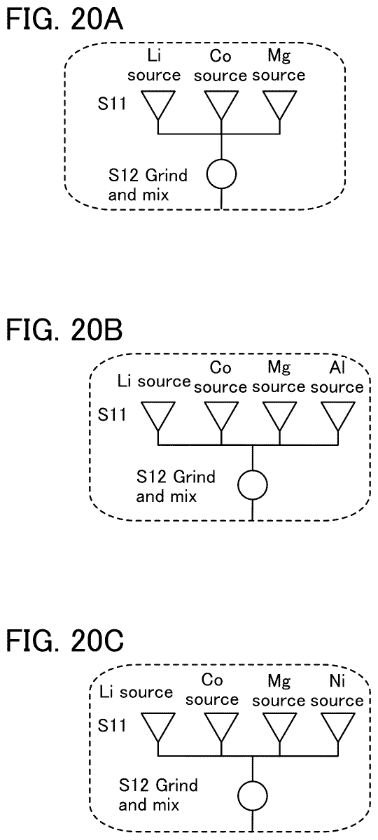

As shown in FIG. 20A to FIG. 20C, for example, the additive element may be added to the lithium source and the cobalt source in Step S11, i.e., at the stage of the starting materials of the composite oxide. FIG. 20A shows a flowchart for adding the magnesium source to the lithium source and the cobalt source. FIG. 20B shows a flowchart for adding the magnesium source and the aluminum source to the lithium source and the cobalt source. FIG. 20C shows a flowchart for adding the magnesium source and the nickel source to the lithium source and the cobalt source. The additive element sources shown in FIG. 20A to FIG. 20C are examples.

The process is followed by Steps S12 and S13, and the lithium cobalt oxide including the additive element can be obtained in Step S14. The distribution of the additive element can be controlled by changing the timing of the addition of the additive element. The additive element added as shown in any of FIG. 20A to FIG. 20C is expected to be located in the inner portion of the positive electrode active material 100. Steps S21 to S23 described above do not need to be performed separately from Steps S11 to S14 described above in the case where any of the processes shown in FIG. 20A to FIG. 20C is employed, so that the method is simplified and enables increased productivity. Needless to say, another additive element may be added in Step S20 also in the case where any of the processes shown in FIG. 20A to FIG. 20C is employed.

Alternatively, lithium cobalt oxide that includes some of the additive elements in advance may be used. When lithium cobalt oxide to which magnesium and fluorine are added is used, for example, Step S11 to Step S14 and part of Step S20 can be skipped. This method can be regarded as being simple and highly productive.

Alternatively, after the heating in Step S15 is performed, to lithium cobalt oxide to which magnesium and fluorine are added in advance, a magnesium source and a fluorine source, or a magnesium source, a fluorine source, a nickel source, and an aluminum source may be further added as in Step S20.

### <Step S33>

Then, in Step S33 illustrated in FIG. 19A, the mixture 903 is heated. Any of the heating conditions described for Step S13 can be selected to perform the heating. The heating time is preferably longer than or equal to 2 hours. Here, the pressure in a furnace may be higher than atmospheric pressure to make the oxygen partial pressure of the heating atmosphere high. An insufficient oxygen partial pressure of the heating atmosphere might cause reduction of cobalt or the like and hinder the lithium cobalt oxide or the like from maintaining a layered rock-salt crystal structure.

Here, a supplementary explanation of the heating temperature is given. The lower limit of the heating temperature in Step S33 needs to be higher than or equal to the temperature at which a reaction between the lithium cobalt oxide and the additive element source proceeds. The temperature at which the reaction proceeds is preferably the temperature at which interdiffusion of the elements included in lithium cobalt oxide and the additive element source occurs, and may be lower than the melting temperatures of these materials. It is known that in the case of an oxide as an example, solid phase diffusion occurs at the temperature 0.757 times the melting temperature Tₘ (the Tamman temperature T_{d}). Accordingly, the heating temperature in Step S33 is preferably higher than or equal to 650° C.

Needless to say, the reaction more easily proceeds at a temperature higher than or equal to the temperature at which one or two or more selected from the materials included in the mixture 903 are melted. For example, in the case where LiF and MgF₂ are included in the additive element source, the lower limit of the heating temperature in Step S33 is preferably higher than or equal to 742° C. (refer to eutectic point in FIG. 17) because the eutectic point of LiF and MgF₂ is around 742° C.

The mixture 903 obtained by mixing such that LiCoO₂:LiF:MgF₂=100:0.33:1 (molar ratio) exhibits an endothermic peak at around 830° C. in DSC. Therefore, the lower limit of the heating temperature is further preferably higher than or equal to 830° C.

A higher heating temperature is preferable because it facilitates the reaction, shortens the heating time, and enables high productivity.

The upper limit of the heating temperature is lower than the decomposition temperature (the melting point: 1130° C.) of the lithium cobalt oxide. At around the decomposition temperature, a slight amount of lithium cobalt oxide might be decomposed. Thus, the upper limit of the heating temperature is preferably lower than or equal to 1000° C., further preferably lower than or equal to 950° C., still further preferably lower than or equal to 900° C.

In view of the above, the heating temperature in Step S33 is preferably higher than or equal to 650° C. and lower than or equal to 1130° C., further preferably higher than or equal to 650° C. and lower than or equal to 1000° C., still further preferably higher than or equal to 650° C. and lower than or equal to 950° C., yet still further preferably higher than or equal to 650° C. and lower than or equal to 900° C. Furthermore, the heating temperature is preferably higher than or equal to 742° C. and lower than or equal to 1130° C., further preferably higher than or equal to 742° C. and lower than or equal to 1000° C., still further preferably higher than or equal to 742° C. and lower than or equal to 950° C., yet still further preferably higher than or equal to 742° C. and lower than or equal to 900° C. Furthermore, the temperature is preferably higher than or equal to 830° C. and lower than or equal to 1130° C., further preferably higher than or equal to 830° C. and lower than or equal to 1000° C., still further preferably higher than or equal to 830° C. and lower than or equal to 950° C., yet still further preferably higher than or equal to 830° C. and lower than or equal to 900° C. Note that the heating temperature in Step S33 is preferably lower than the heating temperature in Step S13.

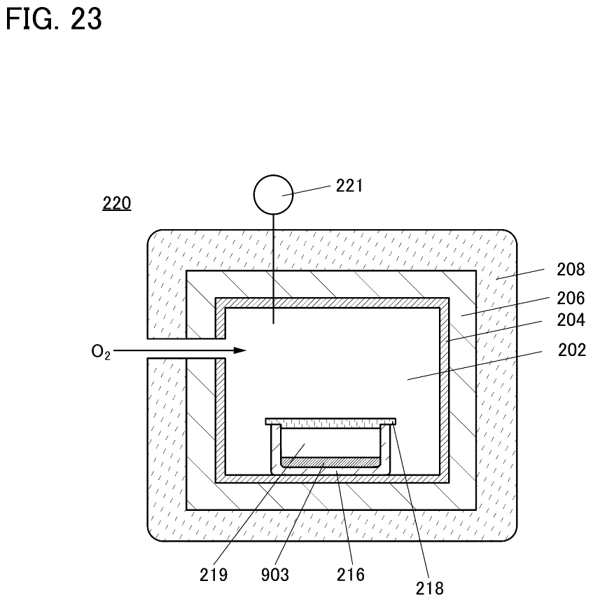

An example of the heating furnace used in Step S33 is described with reference to FIG. 23.

A heating furnace 220 illustrated in FIG. 23 includes a space 202 in the heating furnace, a hot plate 204, a pressure gauge 221, a heater unit 206, and a heat insulator 208. The heating is preferably performed with a container 216, which corresponds to a crucible or a sagger, covered with a lid 218. With this structure, an atmosphere including a fluoride can be obtained in a space 219 enclosed by the container 216 and the lid 218. In the heating, the state of the space 219 is maintained with the lid put on so that the concentration of the gasified fluoride inside the space 219 can be constant or cannot be reduced, in which case fluorine and magnesium can be included in the vicinity of the particle surface of the mixture 903. The atmosphere including a fluoride can be provided in the space 219, which is smaller in capacity than the space 202 in the heating furnace, by volatilization of a smaller amount of a fluoride. This means that an atmosphere including a fluoride can be provided in the atmosphere of the reaction system without a significant reduction in the amount of a fluoride included in the mixture 903. In addition, the use of the lid 218 allows the heating of the mixture 903 in an atmosphere including a fluoride to be simply and inexpensively performed.

Before heating in the space 202 in the heating furnace is performed, the step of providing an atmosphere including oxygen in the space 202 in the heating furnace and the step of placing the container 216 in which the mixture 903 is placed in the space 202 in the heating furnace are performed. The steps in this order enable the mixture 903 to be heated in an atmosphere including oxygen and a fluoride. For example, flowing of a gas is performed during the heating (flowing). The gas can be introduced from below the space 202 in the heating furnace and exhausted to above the space 202 in the heating furnace. During the heating, the space 202 in the heating furnace may be sealed off to be a closed space so that the gas is not transferred to the outside (purging).

Although there is no particular limitation on the method of providing an atmosphere including oxygen in the space 202 in the heating furnace, examples are a method of introducing an oxygen gas or a gas including oxygen such as dry air after exhausting air from the space 202 in the heating furnace and a method of flowing an oxygen gas or a gas including oxygen such as dry air into the space 202 for a certain period of time. In particular, introducing an oxygen gas after exhausting air from the space 202 in the heating furnace (displacement by oxygen) is preferably performed. Note that the atmosphere of the space 202 in the heating furnace may be regarded as an atmosphere including oxygen.

Furthermore, the fluoride or the like attached to inner walls of the container 216 and the lid 218 is fluttered again by the heating and can also be attached to the mixture 903.

There is no particular limitation on the step of heating the heating furnace 220. The heating is preferably performed using a heating mechanism included in the heating furnace 220. Although there is no particular limitation on the way of placing the mixture 903 in the container 216, as illustrated in FIG. 23, the mixture 903 is preferably placed such that the top surface of the mixture 903 is flat with respect to the bottom surface of the container 216, in other words, the level of the top surface of the mixture 903 is uniform.

The heating in Step S33 described above is preferably performed with the pressure in the furnace controlled using the pressure gauge 221. The furnace is preferably in an atmospheric pressure state or a pressurized state. Exposed to pressure, for example, the surface of lithium cobalt oxide is probably melted. Thus, the surface of lithium cobalt oxide heated together with LiF and MgF₂ may be melted under pressure.

Cooling after the heating in the Step S33 above can be performed by natural cooling, and the time it takes for the temperature to decrease to room temperature from a predetermined temperature is preferably longer than or equal to 10 hours and shorter than or equal to 50 hours; for example, the temperature falling rate is preferably higher than or equal to 80° C./h and lower than or equal to 250° C./h, further preferably higher than or equal to 180° C./h and lower than or equal to 210° C./h. The cooling rate in Step S33 is preferably higher than that in Step S13. Cooling at a high cooling rate is referred to as rapid cooling. Performing rapid cooling after the above-described melting makes it possible to form a shell adequately. Specifically, it is possible to form a thin shell. Note that as long as the temperature becomes acceptable to the next step, the cooling is not necessarily continued until room temperature is reached.

In addition, at the time of heating the mixture 903, the partial pressure of fluorine or a fluorine compound originating from the fluorine source or the like is preferably controlled to be within an appropriate range. The partial pressure may be controlled by performing the heating in this step with the crucible covered with the lid. As described above, the lid can prevent volatilization or sublimation of a material. That is, at the time when the temperature is increased and decreased in this step, the crucible is not necessarily sealed off with the lid as long as volatilization or sublimation of a material is prevented. For example, this step can be performed without sealing off the crucible in the case where the reaction chamber in which the crucible is put is filled with oxygen. A positive electrode active material including fluorine or a fluorine compound in an appropriate manner is preferable because such positive electrode active material would inhibit ignition and smoking if an internal short circuit occurs.

In the formation method described in this embodiment, some of the materials, e.g., LiF as the fluorine source, function as a fusing agent in some cases. Owing to this function, the heating temperature can be lower than the decomposition temperature of the lithium cobalt oxide, e.g., a temperature higher than or equal to 742° C. and lower than or equal to 950° C., which allows distribution of the additive element such as magnesium in the surface portion and formation of the positive electrode active material having favorable characteristics.

However, since LiF in a gas phase has a specific gravity less than that of oxygen, heating might volatilize or sublimate LiF and in that case, LiF in the mixture 903 decreases. As a result, the function of a fusing agent deteriorates. Therefore, heating needs to be performed while volatilization of LiF is inhibited. Note that even when LiF is not used as the fluorine source or the like, Li at the surface of LiCoO₂ and F of the fluorine source might react to produce LiF, which might be volatilized. Thus, such inhibition of volatilization is needed even when a fluorine compound having a higher melting point than LiF is used.

In view of this, the mixture 903 is preferably heated in an atmosphere including LiF, i.e., the mixture 903 is preferably heated in a state where the partial pressure of LiF in the heating furnace is high. Such heating can inhibit volatilization of LiF in the mixture 903. The crucible is preferably covered with the lid so that volatilization of LiF is inhibited.

The heating in this step is preferably performed such that the particles of the mixture 903 are not adhered to each other. Adhesion of the particles of the mixture 903 during the heating might decrease the area of contact with oxygen in the atmosphere and inhibit a path of diffusion of the additive element (e.g., fluorine), thereby hindering distribution of the additive element (e.g., magnesium and fluorine) in the surface portion. In order to promote a reaction with oxygen in the atmosphere, the crucible is not necessarily sealed off with the lid.

It is considered that uniform distribution of the additive element (e.g., fluorine) in the surface portion leads to a smooth positive electrode active material with little unevenness. Thus, it is preferable that the particles of the mixture 903 not be adhered to each other in order to allow the smooth surface obtained through the heating in Step S15 to be maintained or to be smoother in this step.

In the case of using a rotary kiln for the heating, the heating is preferably performed while the flow rate of an oxygen-containing atmosphere in the kiln is controlled. For example, the flow rate of an oxygen-containing atmosphere is preferably set low, or no flowing of an atmosphere is preferably performed after an atmosphere is purged first and an oxygen atmosphere is introduced into the kiln. Flowing of oxygen is not preferable because it might cause evaporation of the fluorine source, which prevents maintaining the smoothness of the surface.

In the case of using a roller hearth kiln for the heating, the mixture 903 can be heated in an atmosphere including LiF with the container including the mixture 903 covered with a lid, for example. This is the same as the lid which covers the crucible.

A supplementary explanation of the heating time is given. The heating time depends on conditions such as the heating temperature and the size and composition of the lithium cobalt oxide obtained in Step S14. In the case where the lithium cobalt oxide is small, the heating is preferably performed at a lower temperature or for a shorter time than heating in the case where the lithium cobalt oxide is large, in some cases.

When the median diameter (D50) of the lithium cobalt oxide obtained in Step S14 in FIG. 19A is approximately 12 μm, the heating temperature is preferably higher than or equal to 650° C. and lower than or equal to 950° C., for example. The heating time is preferably longer than or equal to 3 hours and shorter than or equal to 60 hours, further preferably longer than or equal to hours and shorter than or equal to 30 hours, still further preferably approximately 20 hours, for example. Note that the temperature decreasing time after the heating is, for example, preferably longer than or equal to 10 hours and shorter than or equal to 50 hours.

When the median diameter (D50) of the lithium cobalt oxide obtained in Step S14 is approximately 5 μm, the heating temperature is preferably higher than or equal to 650° C. and lower than or equal to 950° C., for example. The heating time is preferably longer than or equal to 1 hour and shorter than or equal to 10 hours, further preferably approximately 5 hours, for example. Note that the temperature decreasing time after the heating is, for example, preferably longer than or equal to 10 hours and shorter than or equal to 50 hours.

### <Step S34>

Next, the heated material is collected in Step S34 shown in FIG. 19A; thus, the positive electrode active material 100 is obtained. The collected particles may be made to pass through a sieve. Through the above process, the positive electrode active material 100 of one embodiment of the present invention can be formed. The positive electrode active material of one embodiment of the present invention has a smooth surface.

### <<Manufacturing Method 2 of Positive Electrode Active Material>>

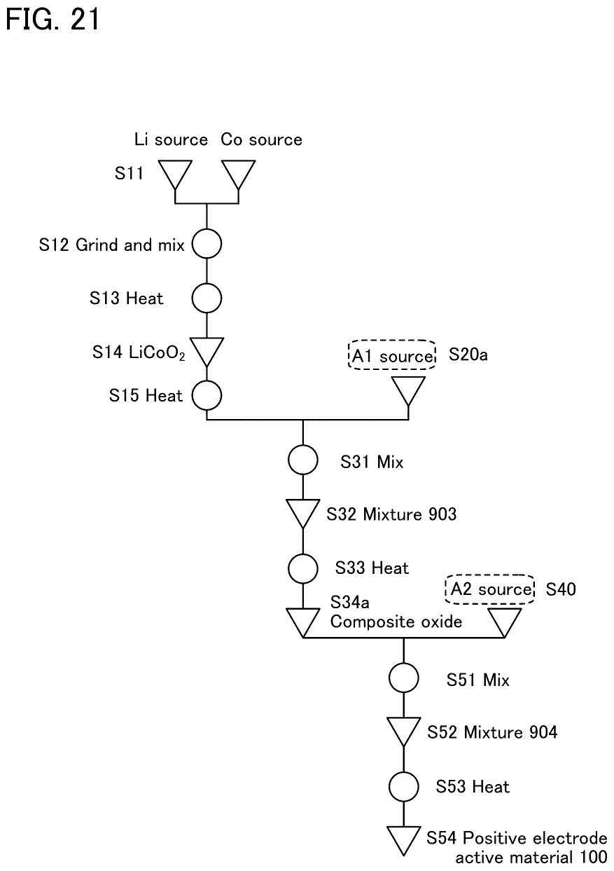

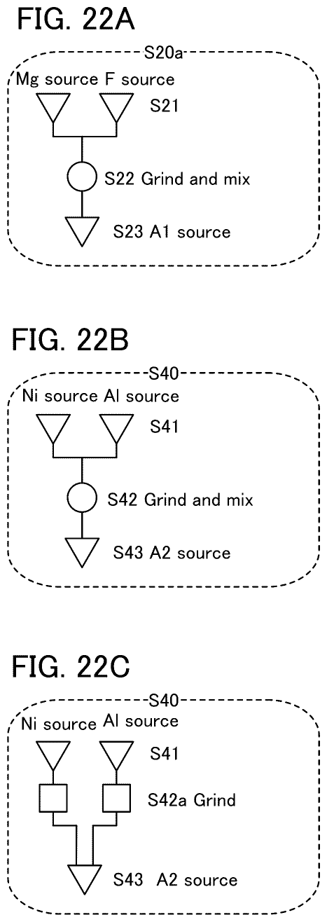

Next, as one embodiment of the present invention, a manufacturing method 2 of a positive electrode active material, which is different from the manufacturing method 1 of a positive electrode active material, will be described with reference to FIG. 21 to FIG. 22C. The manufacturing method 2 of a positive electrode active material is different from the formation method 1 mainly in the number of times of adding additive elements and a mixing method. For the description except for the above, the description of the formation method 1 can be referred to.

Steps S11 to Step S15 in FIG. 21 are performed as in FIG. 19A to prepare lithium cobalt oxide that has been subjected to the initial heating.

### <Step S20a>

Next, in Step S20a, an additive element A1 source used to add an additive element A1 to the lithium cobalt oxide that has been subjected to the initial heating is prepared. The steps of preparing the additive element A1 source are described with reference to FIG. 22A.

### <Step S21>

Step S21 shown in FIG. 22A is described. The additive element A1 can be selected from the elements that are given as the examples of the additive element A described for Step S21 with reference to FIG. 19B. For example, one or more elements selected from magnesium, fluorine, and calcium can be suitably used as the additive element A1. FIG. 22A shows an example in which magnesium and fluorine are selected as the additive elements Al and a magnesium source (Mg source) and a fluorine source (F source) are prepared in Step S21.

Steps S21 to S23 shown in FIG. 19B can be performed under conditions similar to those of Steps S21 to S23 shown in FIG. 21B, whereby the additive element A1 source (A1 source) can be obtained in Step S23.

Steps S31 to S33 shown in FIG. 21 can be performed in a manner similar to that of Steps S31 to S33 shown in FIG. 19A.

### <Step S34a>

Next, the material heated in Step S33 is collected to give lithium cobalt oxide including the additive element A1. This composite oxide is called a second composite oxide to be distinguished from the composite oxide in Step S14.

### <Step S40>

In Step S40 shown in FIG. 21, an additive element A2 source used to add an additive element A2 to the second composite oxide is prepared. The steps of preparing the additive element A2 source are described with reference to FIGS. 22B and 22C.

### <Step S41>

Step S41 shown in FIG. 22B is described. The additive element A2 can be selected from the elements that are given as the examples of the additive element A described for Step S21 with reference to FIG. 19C. For example, one or more elements selected from nickel, titanium, boron, zirconium, and aluminum can be suitably used as the additive element A2. FIG. 22B shows an example in which nickel and aluminum are selected as the additive elements A2 and a nickel source (Ni source) and an aluminum source (A1 source) are prepared.

Steps S41 to S43 shown in FIG. 22B can be performed under conditions similar to those of Steps S21 to S23 shown in FIG. 19B, whereby the additive element A2 source (A2 source) can be obtained in Step S43.

FIG. 22C shows a modification example of the steps of preparing the additive element A2 source which are described with reference to FIG. 22B. A nickel source (Ni source) and an aluminum source (A1 source) are prepared in Step S41 shown in FIG. 22C and are separately ground in Step S42a. Accordingly, a plurality of the additive element A2 sources (42 sources) are prepared in Step S43. FIG. 22C is different from FIG. 22B in separately grinding the additive elements in Step S42a.

### <Steps S51 to S54>

Next, Steps S51 to S54 shown in FIG. 21 can be performed under conditions similar to those of Steps S31 to S34 shown in FIG. 19A. In Step S52, a mixture 904 is obtained. The heating in Step S53 can be performed at a lower temperature and for a shorter time than the heating in Step S33. Through the above process, the positive electrode active material 100 of one embodiment of the present invention can be formed in Step S54. The positive electrode active material of one embodiment of the present invention has a smooth surface.

As shown in FIG. 21 and FIG. 22C, in the manufacturing method 2, introduction of the additive elements to the lithium cobalt oxide is separated into introduction of the additive element A1 and that of the additive element A2. When the additive elements are separately introduced, the additive elements can be at different positions in the depth direction, for example. The additive element A1 can be positioned such that its concentration is higher in the surface portion than in the inner portion, and the additive element A2 can be positioned such that its concentration is higher in the inner portion than in the surface portion, for example.

The initial heating described in this embodiment makes it possible to obtain a positive electrode active material having a smooth surface.

The initial heating described in this embodiment is performed on lithium cobalt oxide. Thus, the initial heating is preferably performed at a temperature lower than the heating temperature for forming the lithium cobalt oxide and for a time shorter than the heating time for forming the lithium cobalt oxide. The additive element is preferably added to the lithium cobalt oxide after the initial heating. The adding step may be separated into two or more steps. Such an order of steps is preferred in order to maintain the smoothness of the surface achieved by the initial heating.

The positive electrode active material 100 with a smooth surface may be less likely to be physically broken by pressure application or the like than a positive electrode active material without a smooth surface. For example, the positive electrode active material 100 is unlikely to be broken in a test involving pressure application such as a nail penetration test, meaning that the positive electrode active material 100 has high safety.

This embodiment can be used in combination with the other embodiments.

### Embodiment 3

In this embodiment, a positive electrode, a negative electrode, and the like of a secondary battery of one embodiment of the present invention are described.

### [Positive Electrode]

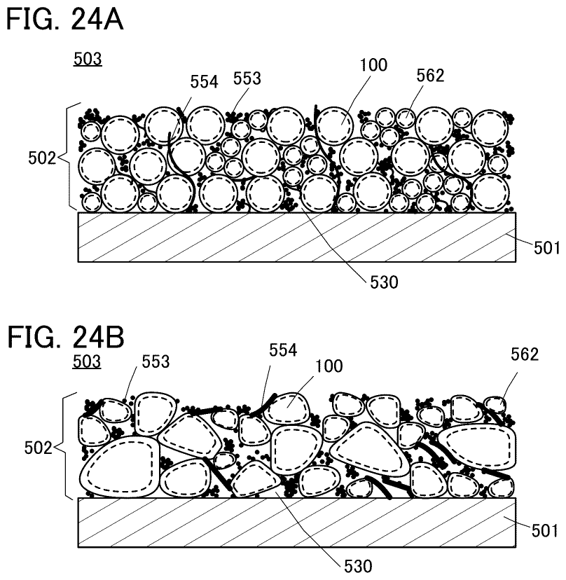

FIG. 24A illustrates an example of a cross-sectional view of the positive electrode 503 used for the secondary battery 1004 and the like. The positive electrode 503 includes the positive electrode active material layer 502 over the positive electrode current collector 501. The positive electrode active material layer 502 includes the positive electrode active material 100, a positive electrode active material 562, the conductive material 553, a conductive material 554, and the electrolyte solution 530. The positive electrode active material layer 502 also includes a binder (not illustrated). The secondary battery preferably includes either the conductive material 553 or the conductive material 554.

A median diameter (D50) of the positive electrode active material 100 is preferably greater than or equal to 1 μm and less than or equal to 50 μm, preferably greater than or equal to 5 μm and less than or equal to 30 μm. To increase the filling density, the positive electrode active material 562 with a different median diameter (D50) is preferably added. The median diameter (D50) of the positive electrode active material 562 is preferably 1/10 to ⅙ of the median diameter (D50) of the positive electrode active material 100. When particle size distribution measurement is performed on an active material in which the positive electrode active material 100 and the positive electrode active material 562 are mixed, two peaks with different local maximum values are observed. Needless to say, two or more peaks may be observed. Note that the filling density can be increased without the positive electrode active material 562.

Each of the positive electrode active material 100 and the positive electrode active material 562 preferably includes a shell. A positive electrode active material that includes a shell can have a good insulating property and inhibits thermal runaway. Although the boundary between a surface portion and an inner portion is indicated by a dotted line in FIG. 24A, the boundary is not always as clear as that in FIG. 24A. The shell can have the structure shown in FIG. 5B or the like. The positive electrode active materials are not limited to those in FIG. 24A and for example, any one of the positive electrode active material 100 and the positive electrode active material 562 includes the shell.

The positive electrode active material 100 and the positive electrode active material 562 may have the same composition or different compositions. In the case where the above positive electrode active materials have the same composition, they have common main components but may be different from each other in the presence or absence of an additive element or the like. In the case where the above positive electrode active materials have different compositions, the positive electrode active materials may be different from each other in their main components.

As already described above, it is preferable that the positive electrode active material 100 and the positive electrode active material 562 include an additive element, and it is particularly preferable that their shells include an additive element. The additive element may be unevenly distributed in the shell or distributed in the inner portion to have a low concentration. The uneven distribution means uneven or localized presence of the additive element. A state where the concentration of the additive element increases from an inner portion toward a shell is sometimes described as uneven distribution of the additive element in the shell.

The additive element may be in the surface portion. The concentration of the additive element in the surface portion is preferably different from the concentration of the additive element in the inner portion. The concentration of the additive element in the surface portion is preferably higher than the concentration of the additive element in the inner portion. This state is sometimes described as uneven distribution of the additive element in the surface portion.

Although sometimes referred to as positive electrode active material particles, the positive electrode active material 100 and the positive electrode active material 562 are in any of a variety of forms other than a particle form. Unlike FIG. 24A, FIG. 24B illustrates the positive electrode 503 including a positive electrode active material in a form other than a particle form. The positive electrode active material in FIG. 24B is the same as that in FIG. 24A except for its form and thus is not described. Although the positive electrode active material 100 and the positive electrode active material 562 are illustrated as primary particles in FIG. 24A and FIG. 24B, they may be secondary particles.

A positive electrode includes a positive electrode active material layer and a positive electrode current collector. The positive electrode active material layer includes a positive electrode active material, and may include a conductive material (can be rephrased as a conductive additive) and a binder. As the positive electrode active material, the positive electrode active material manufactured by the manufacturing method described in the above embodiment can be used, and for example, a mixture of a positive electrode active material having a relatively small median diameter (D50) and a positive electrode active material having a relatively large median diameter (D50) may be used.

The positive electrode active material described in the above embodiments and another positive electrode active material may be mixed to be used.

Examples of the another positive electrode active material include a composite oxide with an olivine crystal structure, a composite oxide with a layered rock-salt crystal structure, and a composite oxide with a spinel crystal structure. For example, a compound such as LiFePO₄, LiFeO₂, LiNiO₂, LiMn₂O₄, V₂O₅, Cr₂O₅, or MnO₂ can be used.

As the another positive electrode active material, a mixture of lithium nickel oxide (LiNiO₂ or LiN₁₋ₓMₓO₂ (0<x<1) (M=Co, Al, or the like) and a lithium-including material with a spinel crystal structure which includes manganese such as LiMn₂O₄ is preferably used. This composition can improve the characteristics of the secondary battery.

As the another positive electrode active material, a lithium-manganese composite oxide that can be represented by a compositional formula LiₐMn_{b}M_{c}O_{d} can be used. Here, the element M is preferably silicon, phosphorus, or a metal element other than lithium and manganese, further preferably nickel. In the case where the whole particles of a lithium-manganese composite oxide are measured, it is preferable to satisfy the following at the time of discharging: 0<a/(b+c)<2; c>0; and 0.26≤(b+c)/d<0.5. Note that the proportions of metals, silicon, phosphorus, and other elements in the whole particles of a lithium-manganese composite oxide can be measured with, for example, an ICP-MS. The proportion of oxygen in the whole lithium-manganese composite oxide particle can be measured by, for example, EDX. Alternatively, the proportion of oxygen can be measured by ICP-MS analysis combined with fusion gas analysis and valence evaluation of XAFS (X-ray absorption fine structure) analysis. Note that the lithium-manganese composite oxide is an oxide including at least lithium and manganese, and may include one or two or more selected from a group consisting of chromium, cobalt, aluminum, nickel, iron, magnesium, molybdenum, zinc, indium, gallium, copper, titanium, niobium, silicon, phosphorus, and the like.

### [Conductive Material]

The conductive material has a function of giving aid to, for example, a current path between the active material and the current collector or a current path between a plurality of the active materials. In order to have such a function, the conductive material preferably includes a material having lower resistance than the active material. The conductive material is also referred to as a conductive additive or a conductivity-imparting agent because of its function.

As the conductive material, a carbon material or a metal material is typically used. The conductive material is in a particle form; examples of the particulate conductive material include carbon black (e.g., furnace black, acetylene black, or graphite). Carbon black mostly has a smaller particle diameter than the positive electrode active material. Some conductive materials are in a fibrous form; examples of the fibrous conductive material include carbon nanotube (CNT) and VGCF (registered trademark). Other conductive materials are in a sheet form; examples of the sheet-shaped conductive material include multilayer graphene. The sheet-shaped conductive material sometimes looks like a thread in observation of a cross section of a positive electrode.

The particulate conductive material can enter a gap of the positive electrode active material or the like and easily aggregates. Thus, the particulate conductive material can give aid to a conductive path between positive electrode active materials provided close to each other. Although having a bent region, the fibrous conductive material is larger than the positive electrode active material. The fibrous conductive material can thus give aid not only to a conductive path between adjacent positive electrode active materials but also to a conductive path between positive electrode active materials located apart from each other. Conductive additives in two or more forms as described above are preferably mixed.

In the case of using multilayer graphene as the sheet-shaped conductive material and carbon black as a particulate conductive material, the weight of the carbon black is preferably 1.5 times to 20 times, further preferably 2 times to 9.5 times the weight of the multilayer graphene in the state of slurry where these are mixed.

When the mixing ratio between multilayer graphene and carbon black is in the above-described range, carbon black does not aggregate and is easily dispersed. When the mixing ratio between multilayer graphene and carbon black is in the above range, the electrode density can be higher than when only carbon black is used as a conductive additive. As the electrode density becomes higher, the capacity per unit weight can become higher.

Moreover, when the mixing ratio between multilayer graphene and carbon black is in the above-described range, fast charging is possible.

Graphene in this specification and the like refers to multilayer graphene and multi graphene. In other words, graphene includes carbon, has a plate-like shape, a sheet-like shape, or the like, and has a two-dimensional structure formed of a six-membered ring composed of carbon atoms. The two-dimensional structure formed of the six-membered ring composed of carbon atoms may be referred to as a carbon sheet. A graphene compound also refers to graphene oxide, multilayer graphene oxide, multi graphene oxide, reduced graphene oxide, reduced multilayer graphene oxide, reduced multi graphene oxide, graphene quantum dots, and the like. That is, a graphene compound may include a functional group. Graphene or a graphene compound is preferably bent. Graphene or a graphene compound may be rolled, and rolled graphene is referred to as a carbon nanofiber in some cases.

In this specification and the like, graphene oxide includes carbon and oxygen, has a sheet-like shape, and includes a functional group, in particular, an epoxy group, a carboxy group, or a hydroxy group.

In this specification and the like, reduced graphene oxide includes carbon and oxygen, has a sheet-like shape, and has a two-dimensional structure formed of a six-membered ring composed of carbon atoms. The reduced graphene oxide functions by itself but may have a stacked-layer structure. The reduced graphene oxide preferably includes a portion where the carbon concentration is higher than 80 atomic % and the oxygen concentration is higher than or equal to 2 atomic % and lower than or equal to 15 atomic %. With such a carbon concentration and such an oxygen concentration, the reduced graphene oxide can function as a conductive material with high conductivity even with a small amount. In addition, the intensity ratio G/D of a G band to a D band of the Raman spectrum of the reduced graphene oxide is preferably 1 or more. The reduced graphene oxide with such an intensity ratio can function as a conductive material with high conductivity even with a small amount.

As a graphene compound, fluorine-including graphene may be used. Fluorine in the graphene compound is preferably adsorbed on a surface. Fluorine-including graphene can be formed by making graphene and a fluorine compound contact with each other (which is called fluorination treatment). For the fluorination treatment, fluorine (F₂) or a fluorine compound is preferably used. The fluorine compound is preferably hydrogen fluoride, halogen fluoride (e.g., ClF₃ or IF₅), a gaseous fluoride (e.g., BF₃, NF₃, PF₅, SiF₄, or SF₆), a metal fluoride (e.g., LiF, NiF₂, AlF₃, or MgF₂), or the like. For the fluorination treatment, a gaseous fluoride is preferably used, and the gaseous fluoride may be diluted with an inert gas. The fluorination treatment is preferably performed at room temperature or in a temperature range higher than or equal to 0° C. and lower than or equal to 250° C., which includes the room temperature. Performing the fluorination treatment at higher than or equal to 0° C. enables adsorption of fluorine onto a surface of graphene.

A graphene compound sometimes has excellent electrical characteristics of high conductivity and excellent physical properties of high flexibility and high mechanical strength. The graphene compound has a sheet-like shape. The graphene compound has a curved surface in some cases, thereby enabling low-resistant surface contact. Furthermore, the graphene compound has extremely high conductivity even with a small thickness in some cases and thus allows a conductive path to be formed in an active material layer efficiently even with a small amount. Hence, when the graphene compound is used as the conductive material, the area where the active material and the conductive material are in contact with each other can be increased. The graphene compound preferably covers 80% or more of the area of the active material. Note that a graphene compound preferably clings to at least part of an active material. Alternatively, a graphene compound preferably overlays at least part of an active material. Alternatively, the shape of a graphene compound preferably conforms to at least part of the shape of an active material. The shape of an active material indicates, for example, an uneven surface formed by a plurality of active material. A graphene compound preferably surrounds at least part of an active material. The graphene compound may have a hole.

In the case where an active material with a small particle diameter (e.g., 1 μm or less) is used, the specific surface area of the active material is large and thus more conductive paths for the active materials are needed. In such a case, a graphene compound that can efficiently form a conductive path even with a small amount is preferably used.

It is particularly effective to use a graphene compound, which has the above-described properties, as a conductive material of a secondary battery that needs to be rapidly charged and rapidly discharged. For example, a secondary battery for a two-wheeled or four-wheeled vehicle, a secondary battery for a drone, or the like is required to be rapidly charged and rapidly discharged in some cases. In addition, a mobile electronic device or the like is required to have rapid charge characteristics in some cases. Fast charging and discharging are referred to as charging and discharging at, for example, 200 mA/g, 400 mA/g, or 1000 mA/g or more.

The longitudinal cross section of the positive electrode active material layer 502 in FIG. 24B shows substantially uniform dispersion of the sheet-like graphene or the sheet-like graphene compound in the positive electrode active material layer 502. The graphene or the graphene compound is schematically shown by the thick line in FIG. 24B but is actually a thin film having a thickness corresponding to the thickness of a single layer or a multi-layer of carbon molecules. A plurality of sheets of graphene or the plurality of graphene compounds are formed to partly cover or adhere to the surfaces of the plurality of particles of the positive electrode active material 100, so that the plurality of sheets of graphene or the plurality of graphene compounds make surface contact with the particles of the positive electrode active material 100.

Here, the plurality of sheets of graphene or the plurality of graphene compounds can be bonded to each other to form a net-shaped graphene compound sheet (hereinafter, referred to as a graphene compound net or a graphene net). A graphene net that covers the active material can function also as a binder for bonding the active materials. This can increase the proportion of the active material in the electrode volume and the electrode weight. That is, the discharge capacity of the secondary battery can be increased.

Here, it is preferable to perform reduction after a layer to be the positive electrode active material layer 502 is formed by using graphene oxide as the graphene or the graphene compound and mixing the graphene oxide with an active material. That is, the formed active material layer preferably includes reduced graphene oxide. When graphene oxide with extremely high dispersibility in a polar solvent is used for the formation of the graphene or the graphene compound, the graphene or the graphene compound can be substantially uniformly dispersed in the positive electrode active material layer 502. The solvent is removed by volatilization from a dispersion medium including the uniformly dispersed graphene oxide to reduce the graphene oxide; hence, the graphene compounds remaining in the positive electrode active material layer 502 partly overlap with each other and are dispersed such that surface contact is made, thereby forming a three-dimensional conductive path. Note that graphene oxide can be reduced by heat treatment or with the use of a reducing agent, for example.

Unlike a conductive material in the form of particles, such as acetylene black, which makes point contact with an active material, graphene or a graphene compound is capable of making low-resistance surface contact; accordingly, the electrical conduction between the particulate positive electrode active material 100 and graphene or a graphene compound can be improved with a smaller amount of graphene than that of a normal conductive material. This can increase the proportion of the positive electrode active material 100 in the positive electrode active material layer 502. Thus, discharge capacity of the secondary battery can be increased.

It is possible to form, with a spray dry apparatus, a graphene compound serving as a conductive material as a coating portion to cover the entire surface of the active material in advance and to form a conductive path between the active materials using the graphene compound.

A material used in formation of the graphene compound may be mixed with the graphene compound to be used for the positive electrode active material layer 502. For example, particles used as a catalyst in formation of the graphene compound may be mixed with the graphene compound. As an example of the catalyst in formation of the graphene compound, particles including any of silicon oxide (SiO₂ or SiOₓ (x<2)), aluminum oxide, iron, nickel, ruthenium, iridium, platinum, copper, germanium, and the like can be given. The median diameter (D50) of the particles is preferably less than or equal to 1 μm, further preferably less than or equal to 100 nm.

As the conductive material, acetylene black (referred to as AB) can be used instead of graphene. Fluorine-including acetylene black may be used. Fluorine in the fluorine-including acetylene black is preferably adsorbed on a surface. Fluorine-including acetylene black can be formed by making acetylene black and a fluorine compound contact with each other (which is called fluorination treatment). For the fluorination treatment, the contents of the description on graphene can be referred to for acetylene black.

As the conductive material, a carbon fiber material (referred to as carbon nanotube or CNT) can be used instead of graphene and acetylene black. A fluorine-including carbon nanotube may be used. Fluorine in the fluorine-including carbon nanotube is preferably adsorbed on a surface. A fluorine-including carbon nanotube can be manufactured by making a carbon nanotube and a fluorine compound contact with each other (which is called fluorination treatment). For the fluorination treatment, the contents of the description on graphene can be referred to for carbon nanotube.

### [Binder]

The binder, which does not cover the entire surface of the active material, is necessary for enhancing adhesion of the active material in powder form. Furthermore, the binder need to have a property of adhering to the current collector. In other words, the binder is preferably a material including an adhering component. Furthermore, it is preferable that the binder be sufficiently flexible and resilient to a change in the state of the active material, in view of expansion of the active material. The binder also needs to be compatible with the electrolyte solution. Moreover, since a secondary battery involves an extremely strong oxidation reaction and an extremely strong reduction reaction, it is desirable that the binder do not deteriorate due to the reactions or be less reactive to the reactions.

As the binder, a rubber material such as styrene-butadiene rubber (SBR), styrene-isoprene-styrene rubber, acrylonitrile-butadiene rubber, butadiene rubber, or ethylene-propylene-diene copolymer is preferably used, for example. Fluororubber can also be used as the binder.

As the binder, water-soluble polymers are preferably used, for example. As the water-soluble polymers, a polysaccharide can be used, for example. As the polysaccharide, one or more of starch, cellulose derivatives such as carboxymethyl cellulose (CMC), methyl cellulose, ethyl cellulose, hydroxypropyl cellulose, diacetyl cellulose, and regenerated cellulose, and the like can be used. It is further preferable that such water-soluble polymers be used in combination with any of the above rubber materials.

Alternatively, as the binder, a material such as polystyrene, poly(methyl acrylate), poly(methyl methacrylate) (PMMA), sodium polyacrylate, polyvinyl alcohol (PVA), polyethylene oxide (PEO), polypropylene oxide, polyimide, polyvinyl chloride, polytetrafluoroethylene, polyethylene, polypropylene, polyisobutylene, polyethylene terephthalate, nylon, poly(vinylidene fluoride) (PVDF), polyacrylonitrile (PAN), ethylene-propylene-diene polymer, polyvinyl acetate, or nitrocellulose is preferably used.

As the binder, two or more of the above materials may be used in combination.

For example, a material having a significant viscosity modifying effect and another material may be used in combination. For example, a rubber material or the like has high adhesion and/or high elasticity but may have difficulty in viscosity modification when mixed in a solvent. In such a case, a rubber material or the like is preferably mixed with a material having a significant viscosity modifying effect, for example. As a material having a significant viscosity modifying effect, for instance, a water-soluble polymer is preferably used. As a water-soluble polymer having a significant viscosity modifying effect, the above-mentioned polysaccharide, for instance, a cellulose derivative such as carboxymethyl cellulose (CMC), methyl cellulose, ethyl cellulose, hydroxypropyl cellulose, diacetyl cellulose, or regenerated cellulose or starch can be used.

Note that a cellulose derivative such as carboxymethyl cellulose obtains a higher solubility when converted into a salt such as a sodium salt or an ammonium salt of carboxymethyl cellulose, and thus easily exerts an effect as a viscosity modifier. A high solubility can also increase the dispersibility of an active material and other components in the formation of a slurry for an electrode. In this specification, cellulose and a cellulose derivative used as a binder of an electrode include salts thereof.

A water-soluble polymer stabilizes the viscosity by being dissolved in water and allows stable dispersion of the active material and another material combined as a binder, such as styrene-butadiene rubber, in an aqueous solution. Furthermore, a water-soluble polymer is expected to be easily and stably adsorbed on an active material surface because it has a functional group. Many cellulose derivatives, such as carboxymethyl cellulose, have a functional group such as a hydroxyl group or a carboxyl group. Because of functional groups, polymers are expected to interact with each other and cover an active material surface in a large area.

In the case where the binder that covers or is in contact with the active material surface forms a film, the film is expected to serve also as a passivation film to suppress the decomposition of the electrolyte solution. Here, a passivation film refers to a film without electric conductivity or a film with extremely low electric conductivity, and can inhibit the decomposition of the electrolyte solution at a potential at which a battery reaction occurs when the passivation film is formed on the active material surface, for example. It is desirable that the passivation film can conduct lithium ions while inhibiting electrical conduction.

### [Current Collector]

For the current collector, a material that has high conductivity, such as a metal like stainless steel, gold, platinum, aluminum, or titanium, or an alloy thereof can be used. It is preferable that a material used for the positive electrode current collector not be dissolved at the potential of the positive electrode. Alternatively, it is possible to use an aluminum alloy to which an element that improves heat resistance, such as silicon, titanium, neodymium, scandium, or molybdenum, is added. A metal element that forms silicide by reacting with silicon may be used. Examples of the metal element that forms silicide by reacting with silicon include zirconium, titanium, hafnium, vanadium, niobium, tantalum, chromium, molybdenum, tungsten, cobalt, and nickel. The current collector can have a foil-like shape, a plate-like shape, a sheet-like shape, a net-like shape, a punching-metal shape, an expanded-metal shape, or the like as appropriate. The current collector preferably has a thickness greater than or equal to 5 μm and less than or equal to 30 μm.

### [Negative Electrode]

The negative electrode includes a negative electrode active material layer and a negative electrode current collector. The negative electrode active material layer may include a conductive material and a binder.

### [Negative Electrode Active Material]

As the negative electrode active material, for example, an alloy-based material and/or a carbon-based material can be used.

For the negative electrode active material, an element that enables charge and discharge reactions by an alloying reaction and a dealloying reaction with lithium can be used. For example, a material including one or two or more selected from silicon, tin, gallium, aluminum, germanium, lead, antimony, bismuth, silver, zinc, cadmium, indium, and the like can be used. Such elements have higher charge and discharge capacity than carbon; in particular, silicon has a high theoretical capacity of 4200 mAh/g. For this reason, silicon is preferably used as the negative electrode active material. Alternatively, a compound including any of the above elements may be used. Examples of the compound include SiO, Mg₂Si, Mg₂Ge, SnO, SnO₂, Mg₂Sn, SnS₂, V₂Sn₃, FeSn₂, CoSn₂, Ni₃Sn₂, Cu₆Sns, Ag₃Sn, Ag₃Sb, Ni₂MnSb, CeSb₃, LaSn₃, La₃Co₂Sn₇, CoSb₃, InSb, and SbSn. Here, an element that enables charge and discharge reactions by alloying and dealloying reactions with lithium and a compound including the element, for example, are referred to as alloy-based materials in some cases.

In this specification and the like, SiO refers, for example, to silicon monoxide. SiO can alternatively be expressed as SiOₓ. For example, x is preferably greater than or equal to 0.2 and less than or equal to 1.5, further preferably greater than or equal to 0.3 and less than or equal to 1.2. Alternatively, x is preferably greater than or equal to 0.2 and less than or equal to 1.2. Alternatively, x is preferably greater than or equal to 0.3 and less than or equal to 1.5.

As the carbon-based material, graphite, graphitizing carbon (soft carbon), non-graphitizing carbon (hard carbon), carbon nanotube, graphene, carbon black, or the like can be used.

Examples of graphite include artificial graphite and natural graphite. Examples of artificial graphite include mesocarbon microbeads (MCMB), coke-based artificial graphite, and pitch-based artificial graphite. As artificial graphite, spherical graphite having a spherical shape can be used. For example, MCMB is preferable because it may have a spherical shape. Moreover, MCMB may be preferable because it can relatively easily have a small surface area. Examples of natural graphite include flake graphite and spherical natural graphite.

Graphite has a low potential substantially equal to that of a lithium metal (greater than or equal to 0.05 V and less than or equal to 0.3 V vs. Li/Li⁺) when lithium ions are inserted into graphite (while a lithium-graphite intercalation compound is formed). For this reason, a lithium-ion secondary battery can have a high operating voltage. In addition, graphite is preferred because of its advantages such as a relatively high charge and discharge capacity per unit volume, relatively small volume expansion, low cost, and a higher level of safety than that of a lithium metal.

As the negative electrode active material, an oxide such as titanium dioxide (TiO₂), lithium titanium oxide (Li₄Ti₅O₁₂), a lithium-graphite intercalation compound (LiₓC₆), niobium pentoxide (Nb₂O₅), tungsten dioxide (WO₂), or molybdenum dioxide (MoO₂) can be used.

Alternatively, as the negative electrode active material, Li₃₋ₓMₓN (M=Co, Ni, or Cu) with a Li₃N structure, which is a nitride of lithium and a transition metal, can be used. For example, Li_{2.6}Co_{0.4}N is preferable because of its high charge and discharge capacity (900 mAh/g and 1890 mAh/cm³).

A nitride of lithium and a transition metal is preferably used, in which case lithium ions are included in the negative electrode active material and thus the negative electrode active material can be used in combination with a positive electrode active material that does not include lithium ions, such as V₂O₅ or Cr₃O₈. Note that even in the case of using a material including lithium ions as a positive electrode active material, the nitride including lithium and a transition metal can be used as the negative electrode active material by extracting the lithium ions included in the positive electrode active material in advance.

A material that causes a conversion reaction can also be used as the negative electrode active material. For example, a transition metal oxide that does not form an alloy with lithium, such as cobalt oxide (CoO), nickel oxide (NiO), or iron oxide (FeO), may be used as the negative electrode active material. Other examples of the material that causes a conversion reaction include oxides such as Fe₂O₃, CuO, Cu₂O, RuO₂, and Cr₂O₃, sulfides such as CoS_{0.89}, NiS, and CuS, nitrides such as Zn₃N₂, Cu₃N, and Ge₃N₄, phosphides such as NiP₂, FeP₂, and CoP₃, and fluoride compounds such as FeF₃ and BiF₃.

For the conductive material and the binder that can be included in the negative electrode active material layer, materials similar to those for the conductive material and the binder that can be included in the positive electrode active material layer can be used.

### [Negative Electrode Current Collector]

For the negative electrode current collector, a material similar to that of the positive electrode current collector can be used. Note that a material that does not alloy with carrier ions of lithium or the like is preferably used for the negative electrode current collector.

### [Electrolyte Solution]

An electrolyte solution can be used as one embodiment of the electrolyte. The electrolyte solution includes a solvent and a lithium salt. As the above-described solvent (which can also be referred to as a solvent of an electrolyte), an aprotic organic solvent is preferably used. For example, one of ethylene carbonate (EC), propylene carbonate (PC), butylene carbonate, chloroethylene carbonate, vinylene carbonate, g-butyrolactone, g-valerolactone, dimethyl carbonate (DMC), diethyl carbonate (DEC), ethyl methyl carbonate (EMC), methyl formate, methyl acetate, ethyl acetate, methyl propionate, ethyl propionate, propyl propionate, methyl butyrate, 1,3-dioxane, 1,4-dioxane, dimethoxyethane (DME), dimethyl sulfoxide, diethyl ether, methyl diglyme, acetonitrile, benzonitrile, tetrahydrofuran, sulfolane, and sultone can be used, or two or more of these solvents can be used in an appropriate combination in an appropriate ratio. A combination of two or more kinds of solvents is referred to as a mixed organic solvent.

As an organic solvent including ethylene carbonate (EC) and diethyl carbonate (DEC) in the electrolyte solution, it is possible to use a mixed organic solvent in which the volume ratio between EC and DEC is x:100-x (where 20≤x≤40) on the assumption that EC and DEC account for 100 vol %. More specifically, a mixed organic solvent including EC and DEC at EC:DEC=30:70 (volume ratio) can be used.

As an organic solvent including ethylene carbonate (EC), ethyl methyl carbonate (EMC), and dimethyl carbonate (DMC) in the electrolyte solution, it is possible to use a mixed organic solvent in which the volume ratio between EC, EMC, and DMC is x:y:100-x-y (where 5<x<35 and 0<y<65) on the assumption that EC, EMC, and DMC account for 100 vol %. More specifically, a mixed solvent including EC, EMC, and DMC at EC: EMC: DMC=30:35:35 (volume ratio) can be used.

As the organic solvent included in the electrolyte solution, a mixed organic solvent including a fluorinated cyclic carbonate or a fluorinated linear carbonate can be used. The above mixed organic solvent further preferably includes both a fluorinated cyclic carbonate and a fluorinated chain carbonate. A fluorinated cyclic carbonate and a fluorinated chain carbonate are preferable because they each include a substituent with an electron-withdrawing property and have a low solvation energy of a lithium ion. Accordingly, a fluorinated cyclic carbonate and a fluorinated chain carbonate are each suitable for the electrolyte solution, and a mixed organic solvent including either of them is suitable.

As a fluorinated cyclic carbonate, for example, fluoroethylene carbonate (fluorinated ethylene carbonate, FEC, or FIEC), difluoroethylene carbonate (DFEC or F2EC), trifluoroethylene carbonate (F3EC), tetrafluoroethylene carbonate (F4EC), or the like can be used. Note that DFEC has isomers such as a cis-4,5 isomer and a trans-4,5 isomer. Each of these fluorinated cyclic carbonates includes a substituent with an electron-withdrawing property and thus is presumed to have a low solvation energy of a lithium ion.

Structural Formula (H10) below is a structure formula of FEC. The substituent with an electron-withdrawing property in FEC is an F group.

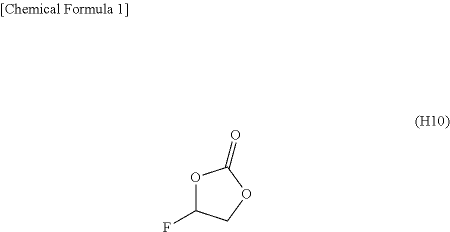

An example of the fluorinated chain carbonate is methyl 3,3,3-trifluoropropionate. Structural Formula (H22) below is a structure formula of methyl 3,3,3-trifluoropropionate. An abbreviation of methyl 3,3,3-trifluoropropionate is “MTFP”. The substituent with an electron-withdrawing property in MTFP is a CF₃ group.

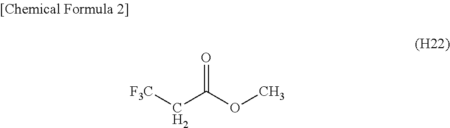

FEC, which is a cyclic carbonate, has a high dielectric constant and thus has an effect of promoting dissociation of a lithium salt when used in an organic solvent. Meanwhile, it can be said that since FEC includes a substituent having an electron-withdrawing property, a lithium ion is desolvated with FEC more easily than with ethylene carbonate (EC), which does not include a substituent having an electron-withdrawing property. Specifically, the solvation energy of a lithium ion is lower in FEC than in ethylene carbonate (EC), which does not include a substituent with an electron-withdrawing property. Thus, lithium ions are likely to be extracted from surfaces of a positive electrode active material and a negative electrode active material, which can reduce an internal resistance of a secondary battery. In addition, FEC is presumed to have a deep highest occupied molecular orbital (HOMO) level and thus is not easily oxidized, leading to high oxidation resistance. Meanwhile, FEC disadvantageously has high viscosity. In view of this, a mixed organic solvent including not only FEC but also MTFP is preferably used for the electrolyte solution. MTFP, which is a linear carbonate, can have an effect of reducing the viscosity of the electrolyte solution or maintaining the viscosity at room temperature (typically, 25° C.) even at low temperatures (typically, 0° C.). Moreover, MTFP has a lower solvation energy than methyl propionate (abbreviated as “MP”), which does not include a substituent with an electron-withdrawing property, and may solvate a lithium ion when used for the electrolyte solution.

FEC and MTFP having the above-described physical properties are preferably mixed such that the volume ratio between FEC and MTFP is x:100-x (where 5≤x≤30, preferably 10≤x≤20) on the assumption that a mixed organic solvent including FEC and MTFP accounts for 100 vol %. In other words, MTFP and FEC are preferably mixed such that the amount of MTFP is larger than that of FEC in the mixed organic solvent.

The use of one or more kinds of ionic liquids (room temperature molten salts) which have features of non-flammability and non-volatility as the solvent of the electrolyte solution can prevent a secondary battery from exploding and/or igniting, for example, even when the secondary battery internally shorts out or the internal temperature increases owing to overcharging or the like. An ionic liquid includes a cation and an anion, specifically, an organic cation and an anion. Examples of the organic cation used for the electrolyte solution include aliphatic onium cations such as a quaternary ammonium cation, a tertiary sulfonium cation, and a quaternary phosphonium cation, and aromatic cations such as an imidazolium cation and a pyridinium cation. Examples of the anion used for the electrolyte solution include a monovalent amide-based anion, a monovalent methide-based anion, a fluorosulfonate anion, a perfluoroalkylsulfonate anion, a tetrafluoroborate anion, a perfluoroalkylborate anion, a hexafluorophosphate anion, and a perfluoroalkylphosphate anion.

It is preferable that the above-described solvent of the electrolyte solution be highly purified and include a small amount of particulate dust or molecules other than constituent molecules of the organic solvent (hereinafter also simply referred to as “impurities” and include oxygen (O₂), water (H₂O), and moisture). Specifically, the amount of impurities included in the solvent of the electrolyte solution is less than or equal to 100 ppm, preferably less than or equal to 50 ppm, further preferably less than 10 ppm. For example, moisture can be detected by Karl Fischer titration.

Furthermore, it is preferable that peaks attributed to impurities in the above-described organic solvent be hardly observed by NMR measurement or the like. The expression “hardly observed” includes the case where the ratio of the integral area of the peak attributed to impurities to the integral area of the peak attributed to the main component (such a ratio is simply referred to as an integral ratio) is less than or equal to 0.005, preferably less than or equal to 0.002. An apparatus used for the NMR measurement is not particularly limited, and for example, “AVANCE III 400” manufactured by Bruker Corporation can be used. Among the five peaks of acetonitrile derived from acetonitrile-d₃ used in a solvent in the 1H-NMR measurement, the center peak can be 1.94 ppm.

For example, in the case of MTFP, it is known that when 1H-NMR is measured using an acetonitrile-d₃ solvent, four peaks appear at δ of greater than or equal to 3.29 ppm and less than or equal to 3.43 ppm. However, in the case where another peak appears in the vicinity of the above range, for example, another peak appears at δ of greater than or equal to 3.24 ppm and less than or equal to 3.29 ppm, the peak is probably derived from impurities. Accordingly, when the ratio (integral ratio) of a peak area greater than or equal to 3.24 ppm and less than or equal to 3.29 ppm to a peak area greater than or equal to 3.29 ppm and less than or equal to 3.43 ppm is less than or equal to 0.005, preferably less than or equal to 0.002, peaks attributed to impurities are hardly observed.

### [Lithium Salt]

As a lithium salt (also referred to as an electrolyte) dissolved in the above-described solvent, one of lithium salts such as LiPF₆, LiClO₄, LiAsF₆, LiBF₄, LiAlCl₄, LiSCN, LiBr, LiI, Li₂SO₄, Li₂B₁₀Cl₁₀, Li₂B₁₂Cl₁₂, LiCF₃SO₃, LiC₄F₉SO₃, LiC(CF₃SO₂)₃, LiC(C₂F₅SO₂)₃, LiN(CF₃SO₂)₂, LiN(C₄F₉SO₂)(CF₃SO₂), and LiN(C₂F₅SO₂)₂ can be used, or two or more kinds of these can be used in an appropriate combination in an appropriate ratio. The lithium salt is preferably dissolved in the solvent at greater than or equal to 0.5 mol/L and less than or equal to 3.0 mol/L. Using a fluoride such as LiPF₆ or LiBF₄ enables a lithium-ion secondary battery to have improved safety.

### [Additive Agent]

Furthermore, an additive agent such as vinylene carbonate (VC), propane sultone (PS), tert-butylbenzene (TBB), fluoroethylene carbonate (FEC), lithium bis(oxalate) borate (LiBOB), or a dinitrile compound such as succinonitrile or adiponitrile is preferably added to the electrolyte solution. The concentration of the material to be added in the whole solvent is preferably, for example, higher than or equal to 0.1 wt % and lower than or equal to 5 wt %. It is particularly preferable to use VC or LiBOB because it facilitates formation of a favorable coating portion.

### [Gel Electrolyte]

A polymer gel obtained in a manner in which a polymer is swelled with an electrolyte solution may be used as a gel electrolyte. When a polymer gel electrolyte is used, a semisolid electrolyte layer can be provided, so that safety against liquid leakage and the like is improved. Moreover, a secondary battery can be thinner and more lightweight.

As a polymer that undergoes gelation, a silicone gel, an acrylic gel, an acrylonitrile gel, a polyethylene oxide-based gel, a polypropylene oxide-based gel, a fluorine-based polymer gel, or the like can be used.

Examples of the polymer include a polymer having a polyalkylene oxide structure, such as polyethylene oxide (PEO); PVDF; polyacrylonitrile; and a copolymer including any of them.

For example, PVDF-HFP, which is a copolymer of PVDF and hexafluoropropylene (HFP), can be used. The formed polymer may be porous.

### [Solid Electrolyte]

Instead of the electrolyte solution, a solid electrolyte including an inorganic material such as a sulfide-based or oxide-based inorganic material, a solid electrolyte including a polymer material such as a PEO (polyethylene oxide)-based polymer material, or the like can be used. When the solid electrolyte is used, a separator and/or a spacer are/is not necessary. Furthermore, the battery can be entirely solidified; therefore, there is no possibility of liquid leakage and thus the safety of the battery is dramatically improved.

### [Separator]

The secondary battery preferably includes a separator. The separator can be formed using, for example, paper, nonwoven fabric, glass fiber, ceramics, or synthetic fiber including nylon (polyamide), vinylon (polyvinyl alcohol-based fiber), polyester, acrylic, polyolefin, or polyurethane. The separator is preferably formed to have an envelope-like shape to wrap one of the positive electrode and the negative electrode.

The separator may have a multilayer structure. For example, an organic material film of polypropylene, polyethylene, or the like can be coated with a ceramic-based material, a fluorine-based material, a polyamide-based material, a mixture thereof, or the like. Examples of the ceramic-based material include aluminum oxide particles and silicon oxide particles. Examples of the fluorine-based material include PVDF and polytetrafluoroethylene. Examples of the polyamide-based material include nylon and aramid (meta-based aramid and para-based aramid).

When the separator is coated with the ceramics-based material, the oxidation resistance is improved; hence, degradation of the separator during high-voltage charge can be inhibited and thus the reliability of the secondary battery can be improved. When the separator is coated with the fluorine-based material, the separator is easily brought into close contact with an electrode, resulting in high output performance. When the separator is coated with a polyamide-based material, in particular, aramid, the heat resistance is improved; thus, the safety of the secondary battery can be improved.

For example, both surfaces of a polypropylene film may be coated with a mixed material of aluminum oxide and aramid. Alternatively, a surface of a polypropylene film that is in contact with the positive electrode may be coated with a mixed material of aluminum oxide and aramid, and a surface of the polypropylene film that is in contact with the negative electrode may be coated with the fluorine-based material.

The use of a separator having a multilayer structure makes it possible to maintain the safety of the secondary battery even when the total thickness of the separator is small, so that the discharge capacity per volume of the secondary battery can be increased.

### [Exterior Body]

For an exterior body included in the secondary battery, a metal material such as aluminum and/or a resin material can be used, for example. A film-like exterior body can also be used. As the exterior body, it is possible to use, for example, a film having a three-layer structure in which a highly flexible metal thin film of aluminum, stainless steel, copper, nickel, or the like is provided over a film formed of a material such as polyethylene, polypropylene, polycarbonate, ionomer, or polyamide, and a fibrous synthetic resin such as a polyamide resin or a polyester resin is provided over the metal thin film as the outer surface of the exterior body. A fiber made of a polyamide resin is referred to as nylon. An aluminum-including film having such a three-layer structure is sometimes referred to as an aluminum laminate film.

This embodiment can be used in appropriate combination with the other embodiments.

### Embodiment 4

This embodiment specifically describes examples of a secondary battery with a shape different from that of the laminated secondary battery described in the above embodiment.

### <Coin-Type Secondary Battery>

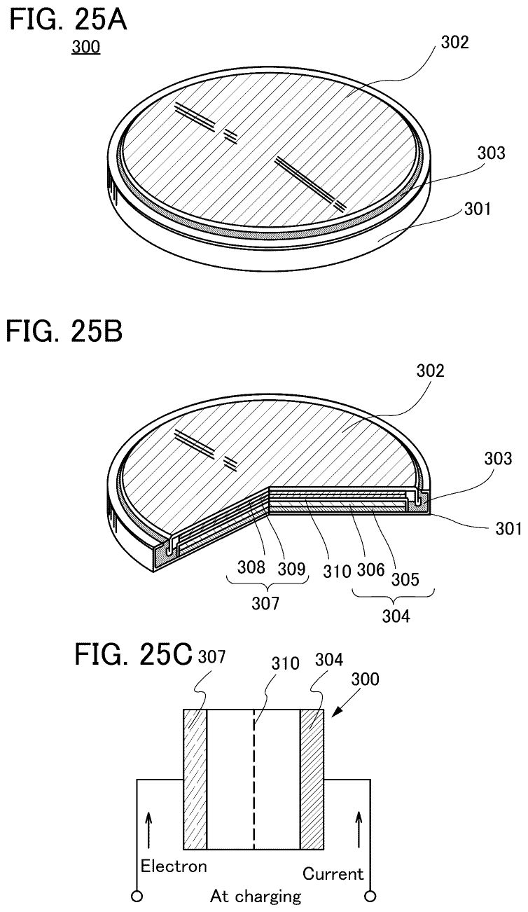

An example of a coin-type secondary battery is described. FIG. 25A is an external view of a coin-type (single-layer flat type) secondary battery, and FIG. 25B is a cross-sectional view thereof. Coin-type secondary batteries are mainly used in small electronic devices. In this specification and the like, coin-type batteries include button-type batteries.

In a coin-type secondary battery 300, the positive electrode can 301 doubling as a positive electrode terminal and the negative electrode can 302 doubling as a negative electrode terminal are insulated from each other and sealed by a gasket 303 made of polypropylene or the like. The positive electrode 304 is formed of the positive electrode current collector 305 and the positive electrode active material layer 306 provided in contact with the positive electrode current collector 305. The negative electrode 307 is formed of a negative electrode current collector 308 and a negative electrode active material layer 309 provided in contact with the negative electrode current collector 308. Between the positive electrode 304 and the negative electrode 307 is provided a separator 310.

Note that only one surface of the current collector of each of the positive electrode 304 and the negative electrode 307 used for the coin-type secondary battery 300 is preferably provided with an active material layer.

For the positive electrode can 301 and the negative electrode can 302, a metal having corrosion resistance to an electrolyte solution, such as nickel, aluminum, or titanium, an alloy of such a metal, or an alloy of such a metal and another metal (e.g., stainless steel) can be used. Alternatively, the positive electrode can 301 and the negative electrode can 302 are preferably covered with nickel, aluminum, and/or the like in order to prevent corrosion due to the electrolyte solution. The positive electrode can 301 and the negative electrode can 302 are electrically connected to the positive electrode 304 and the negative electrode 307, respectively.

The negative electrode 307, the positive electrode 304, and the separator 310 are soaked in the electrolyte solution. Then, as illustrated in FIG. 25B, the positive electrode 304, the separator 310, the negative electrode 307, and the negative electrode can 302 are stacked in this order with the positive electrode can 301 positioned at the bottom, and the positive electrode can 301 and the negative electrode can 302 are subjected to pressure bonding with the gasket 303 located therebetween. In such a manner, the coin-type secondary battery 300 is manufactured.

When the positive electrode active material described in the above embodiment is used in the positive electrode 304, the coin-type secondary battery 300 with high discharge capacity and excellent cycle performance can be obtained.

Here, a current flow in charging the secondary battery is described with reference to FIG. 25C. When a secondary battery using lithium is regarded as one closed circuit, movement of lithium ions and the current flow are in the same direction. Note that in the secondary battery using lithium, the anode and the cathode interchange in charging and discharging, and the oxidation reaction and the reduction reaction interchange; hence, an electrode with a high reaction potential is called a positive electrode and an electrode with a low reaction potential is called a negative electrode. Accordingly, in this specification, the positive electrode is referred to as a “positive electrode” or a “+ electrode (plus electrode)” and the negative electrode is referred to as a “negative electrode” or a “− electrode (minus electrode)” in any of the case where charging is performed, the case where discharging is performed, the case where a reverse pulse current is made to flow, and the case where a charge current is made to flow. The use of the terms “anode” and “cathode” related to an oxidation reaction and a reduction reaction might cause confusion because the anode and the cathode interchange in charging and discharging. Thus, the terms “anode” and “cathode” are not used in this specification. If the term “anode” or “cathode” is used, it should be mentioned that the anode or the cathode is which of the one at the time of charging or the one at the time of discharging and corresponds to which of a positive (plus) electrode or a negative (minus) electrode.

Two terminals illustrated in FIG. 25C are connected to a charger, and the secondary battery 300 is charged. As charging of the secondary battery 300 proceeds, a potential difference between the electrodes increases.

### <Cylindrical Secondary Battery>

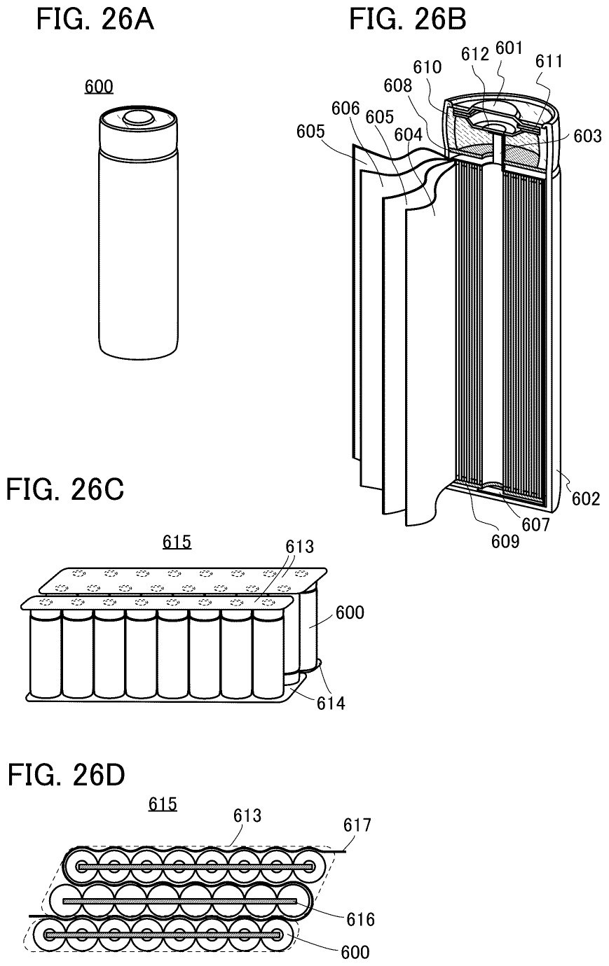

Next, an example of a cylindrical secondary battery is described with reference to FIG. 26. FIG. 26A illustrates an external view of a cylindrical secondary battery 600. FIG. 26B is a schematic cross-sectional view of the cylindrical secondary battery 600. The cylindrical secondary battery 600 includes, as illustrated in FIG. 26B, a positive electrode cap (battery lid) 601 on the top surface and a battery can (outer can) 602 on the side surface and the bottom surface. The positive electrode cap 601 and the battery can (outer can) 602 are insulated from each other by a gasket (insulating gasket) 610.

Inside the battery can 602 having a hollow cylindrical shape, a battery element in which a strip-like positive electrode 604 and a strip-like negative electrode 606 are wound with a separator 605 located therebetween is provided. Although not illustrated, the battery element is wound around a center pin. One end of the battery can 602 is closed and the other end thereof is opened. For the battery can 602, a metal having corrosion resistance to an electrolyte solution, such as nickel, aluminum, or titanium, an alloy of such a metal, and/or an alloy of such a metal and another metal (e.g., stainless steel) can be used. Alternatively, the battery can 602 is preferably covered with nickel, aluminum, and/or the like in order to prevent corrosion due to the electrolyte solution. Inside the battery can 602, the battery element in which the positive electrode, the negative electrode, and the separator are wound is provided between a pair of an insulating plate 608 and an insulating plate 609 that face each other. Furthermore, a nonaqueous electrolyte solution (not illustrated) is injected inside the battery can 602 provided with the battery element. As the nonaqueous electrolyte solution, a nonaqueous electrolyte solution that is similar to that for the coin-type secondary battery can be used.

Since a positive electrode and a negative electrode that are used for a cylindrical storage battery are wound, active materials are preferably formed on both surfaces of a current collector. A positive electrode terminal (positive electrode current collecting lead) 603 is connected to the positive electrode 604, and a negative electrode terminal (negative electrode current collecting lead) 607 is connected to the negative electrode 606. For the positive electrode terminal 603, a metal material such as aluminum can be used. For the negative electrode terminal 607, a metal material such as copper can be used. The positive electrode terminal 603 and the negative electrode terminal 607 are resistance-welded to a safety valve mechanism 612 and the bottom of the battery can 602, respectively. The safety valve mechanism 612 is electrically connected to the positive electrode cap 601 through a PTC (Positive Temperature Coefficient) element 611. The safety valve mechanism 612 cuts off electrical connection between the positive electrode cap 601 and the positive electrode 604 when the internal pressure of the battery exceeds a predetermined threshold value. The PTC element 611, which is a thermally sensitive resistor whose resistance increases as temperature rises, limits the amount of current by increasing the resistance, in order to prevent abnormal heat generation. Barium titanate (BaTiO₃)-based semiconductor ceramics or the like can be used for the PTC element.

As illustrated in FIG. 26C, a plurality of secondary batteries 600 may be provided between a conductive plate 613 and a conductive plate 614 to form a module 615. The plurality of secondary batteries 600 may be connected in parallel, connected in series, or connected in series after being connected in parallel. With the module 615 including the plurality of secondary batteries 600, large electric power can be extracted.

FIG. 26D is a top view of the module 615. The conductive plate 613 is shown by a dotted line for clarity of the drawing. As illustrated in FIG. 26D, the module 615 may include a conductive wiring 616 that electrically connects the plurality of secondary batteries 600 to each other. The conductive plate 613 can be provided over and overlap the conductive wiring 616. In addition, a temperature control device 617 may be provided between the plurality of secondary batteries 600. The secondary batteries 600 can be cooled with the temperature control device 617 when overheated, whereas the secondary batteries 600 can be heated with the temperature control device 617 when cooled too much. Thus, the performance of the module 615 is unlikely to be affected by the outside temperature. A heating medium included in the temperature control device 617 preferably has an insulating property and incombustibility.

When the positive electrode active material described in the above embodiment is used in the positive electrode 604, the cylindrical secondary battery 600 with high discharge capacity and excellent cycle performance can be obtained.

### <Wound Secondary Battery>

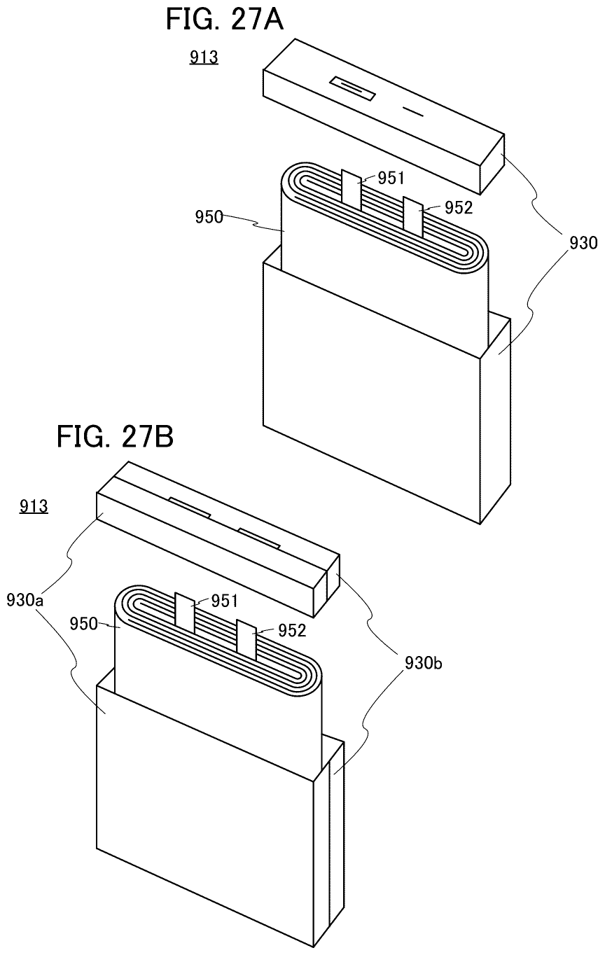

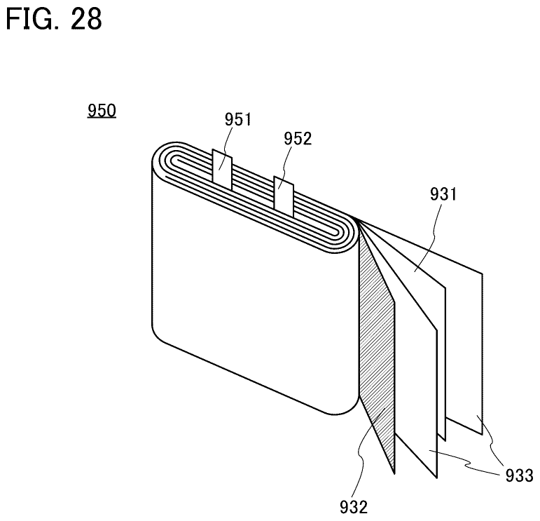

Furthermore, structure examples of a wound secondary battery 913 are described with reference to FIG. 27 and FIG. 28.

The secondary battery 913 illustrated in FIG. 27A includes a wound body 950 provided with a terminal 951 and a terminal 952 inside a housing 930. The wound body 950 is immersed in an electrolyte solution inside the housing 930. The terminal 952 is in contact with the housing 930. The use of an insulator or the like inhibits contact between the terminal 951 and the housing 930. Note that in FIG. 27A, the housing 930 divided into two pieces is illustrated for convenience; however, in the actual structure, the wound body 950 is covered with the housing 930, and the terminal 951 and the terminal 952 extend to the outside of the housing 930. For the housing 930, a metal material (e.g., aluminum) or a stack of a metal material and a resin material can be used.

Note that as illustrated in FIG. 27B, the housing 930 in FIG. 27A may be formed using a plurality of materials. For example, in the secondary battery 913 in FIG. 27B, a housing 930a and a housing 930b are attached to each other, and the wound body 950 is provided in a region surrounded by the housing 930a and the housing 930b.

For the housing 930a, a metal material (e.g., aluminum) or a stack of a metal material and a resin material can be used. For the housing 930b, a metal material (e.g., aluminum) or a stack of a metal material and a resin material can be used.

FIG. 28 illustrates the structure of the wound body 950. The wound body 950 includes a negative electrode 931, a positive electrode 932, and separators 933. The wound body 950 is obtained by winding a sheet of a stack in which the negative electrode 931 and the positive electrode 932 overlap each other with the separator 933 therebetween. Note that a plurality of stacks each including the negative electrode 931, the positive electrode 932, and the separators 933 may be further stacked.

When the positive electrode active material described in the above embodiment is used in the positive electrode 932, the secondary battery 913 with high discharge capacity and excellent cycle performance can be obtained.

This embodiment can be implemented in appropriate combination with any of the other embodiments.

### Embodiment 5

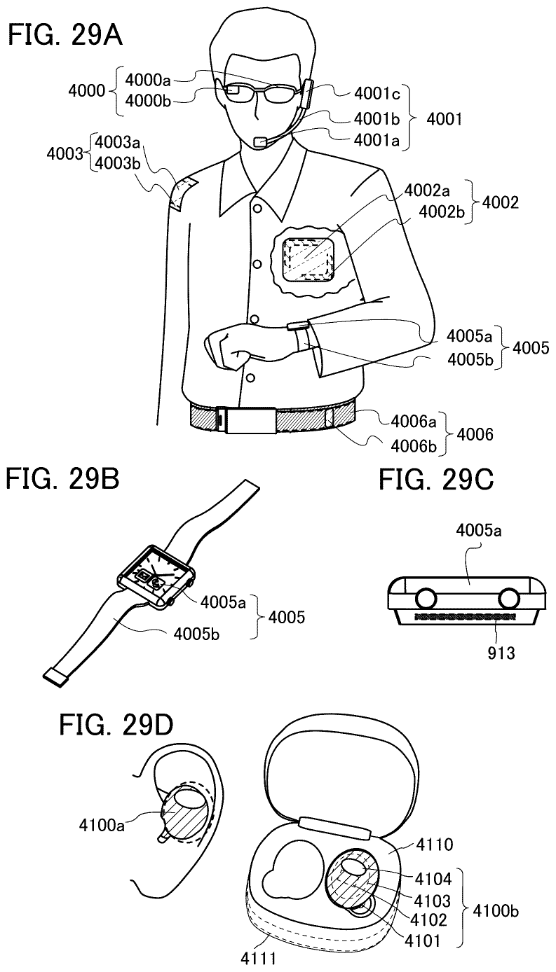

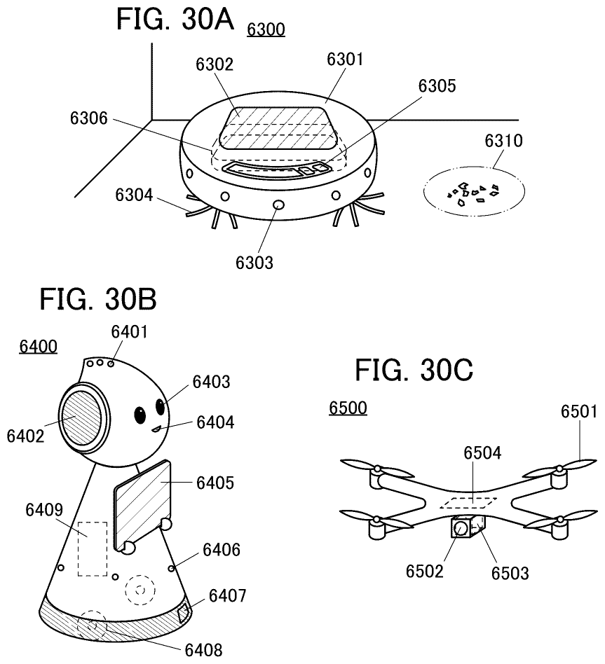

In this embodiment, examples of electronic devices each including the secondary battery described in the above embodiment are described with reference to FIG. 29A to FIG. 30C.

FIG. 29A illustrates examples of wearable devices. A secondary battery is used as a power source of a wearable device. To have improved splash resistance, water resistance, or dust resistance in daily use or outdoor use by a user, a wearable device is desirably capable of being charged with and without a wire whose connector portion for connection is exposed.

For example, the secondary battery of one embodiment of the present invention can be provided in a glasses-type device 4000 illustrated in FIG. 29A. The glasses-type device 4000 includes a frame 4000a and a display part 4000b. The secondary battery is provided in a temple of the frame 4000a having a curved shape, whereby the glasses-type device 4000 can be lightweight, can have a well-balanced weight, and can be used continuously for a long time. With the use of the secondary battery of one embodiment of the present invention, space saving required with downsizing of a housing can be achieved.

The secondary battery of one embodiment of the present invention can be provided in a headset-type device 4001. The headset-type device 4001 includes at least a microphone part 4001a, a flexible pipe 4001b, and an earphone portion 4001c. The secondary battery can be provided in the flexible pipe 4001b or the earphone portion 4001c. With the use of the secondary battery of one embodiment of the present invention, space saving required with downsizing of a housing can be achieved.

The secondary battery of one embodiment of the present invention can be provided in a device 4002 that can be attached directly to a body. A secondary battery 4002b can be provided in a thin housing 4002a of the device 4002. With the use of the secondary battery of one embodiment of the present invention, space saving required with downsizing of a housing can be achieved.

The secondary battery of one embodiment of the present invention can be provided in a device 4003 that can be attached to clothes. A secondary battery 4003b can be provided in a thin housing 4003a of the device 4003. With the use of the secondary battery of one embodiment of the present invention, space saving required with downsizing of a housing can be achieved.

The secondary battery of one embodiment of the present invention can be provided in a belt-type device 4006. The belt-type device 4006 includes a belt portion 4006a and a wireless power feeding and receiving portion 4006b, and the secondary battery can be provided inside the belt portion 4006a. With the use of the secondary battery of one embodiment of the present invention, space saving required with downsizing of a housing can be achieved.

The secondary battery of one embodiment of the present invention can be provided in a watch-type device 4005. The watch-type device 4005 includes a display portion 4005a and a belt portion 4005b, and the secondary battery can be provided in the display portion 4005a or the belt portion 4005b. With the use of the secondary battery of one embodiment of the present invention, space saving required with downsizing of a housing can be achieved.

The display portion 4005a can display various kinds of information such as time and reception information of an e-mail or an incoming call.

In addition, the watch-type device 4005 is a wearable device that is wound around an arm directly; thus, a sensor that measures the pulse, the blood pressure, or the like of the user may be incorporated therein. Data on the exercise quantity and health of the user can be stored to be used for health maintenance.

FIG. 29B is a perspective view of the watch-type device 4005 that is detached from an arm.

FIG. 29C is a side view. FIG. 29C illustrates a state where the secondary battery 913 is incorporated in the watch-type device 4005. The secondary battery 913 is the secondary battery described in Embodiment 4. The secondary battery 913, which is small and lightweight, overlaps with the display portion 4005a.

FIG. 29D illustrates an example of wireless earphones. The wireless earphones shown here consist of, but are not limited to, a pair of main bodies 4100a and 4100b.

Each of the main bodies 4100a and 4100b includes a driver unit 4101, an antenna 4102, and a secondary battery 4103. Each of the main bodies 4100a and 4100b may also include a display portion 4104. Moreover, each of the main bodies 4100a and 4100b preferably includes a substrate where a circuit such as a wireless IC is provided, a terminal for charge, and the like. Each of the main bodies 4100a and 4100b may also include a microphone.

A case 4110 includes a secondary battery 4111. Moreover, the case 4110 preferably includes a substrate where a circuit such as a wireless IC or a charge control IC is provided, and a terminal for charge. The case 4110 may also include a display portion, a button, and the like.

The main bodies 4100a and 4100b can communicate wirelessly with another electronic device such as a smartphone. Thus, sound data and the like transmitted from another electronic device can be played through the main bodies 4100a and 4100b. When the main bodies 4100a and 4100b include a microphone, sound captured by the microphone is transmitted to another electronic device, and sound data obtained by processing with the electronic device can be transmitted to and played through the main bodies 4100a and 4100b. Hence, the wireless earphones can be used as a translator, for example.

The secondary battery 4103 included in the main body 4100a and the main body 4100b can be charged by the secondary battery 4111 included in the case 4100. As the secondary battery 4111 and the secondary battery 4103, the coin-type secondary battery or the cylindrical secondary battery of the foregoing embodiment, for example, can be used. A secondary battery whose positive electrode includes the positive electrode active material 100 obtained in Embodiment 1 has a high energy density; thus, with the use of the secondary battery as the secondary battery 4103 and the secondary battery 4111, space saving required with downsizing of the wireless earphones can be achieved.

FIG. 30A illustrates an example of a cleaning robot. A cleaning robot 6300 includes a display portion 6302 placed on the top surface of a housing 6301, a plurality of cameras 6303 placed on the side surface of the housing 6301, a brush 6304, operation buttons 6305, a secondary battery 6306, a variety of sensors, and the like. Although not illustrated, the cleaning robot 6300 is provided with a tire, an inlet, and the like. The cleaning robot 6300 is self-propelled, detects dust 6310, and sucks up the dust through the inlet provided on the bottom surface.

For example, the cleaning robot 6300 can determine whether there is an obstacle such as a wall, furniture, or a step by analyzing images taken by the cameras 6303. In the case where the cleaning robot 6300 detects an object, such as a wire, that is likely to be caught in the brush 6304 by image analysis, the rotation of the brush 6304 can be stopped. The cleaning robot 6300 further includes a secondary battery 6306 of one embodiment of the present invention and a semiconductor device or an electronic component. The cleaning robot 6300 including the secondary battery 6306 of one embodiment of the present invention can be a highly reliable electronic device that can operate for a long time.

FIG. 30B illustrates an example of a robot. A robot 6400 illustrated in FIG. 30B includes a secondary battery 6409, an illuminance sensor 6401, a microphone 6402, an upper camera 6403, a speaker 6404, a display portion 6405, a lower camera 6406, an obstacle sensor 6407, a moving mechanism 6408, an arithmetic device, and the like.

The microphone 6402 has a function of detecting a speaking voice of a user, an environmental sound, and the like. The speaker 6404 has a function of outputting sound. The robot 6400 can communicate with a user using the microphone 6402 and the speaker 6404.

The display portion 6405 has a function of displaying various kinds of information. The robot 6400 can display information desired by a user on the display portion 6405. The display portion 6405 may be provided with a touch panel. Moreover, the display portion 6405 may be a detachable information terminal, in which case charge and data communication can be performed when the display portion 6405 is set at the home position of the robot 6400.

The upper camera 6403 and the lower camera 6406 each have a function of taking an image of the surroundings of the robot 6400. The obstacle sensor 6407 can detect an obstacle in the direction where the robot 6400 advances with the moving mechanism 6408. The robot 6400 can move safely by recognizing the surroundings with the upper camera 6403, the lower camera 6406, and the obstacle sensor 6407.

The robot 6400 further includes the secondary battery 6409 of one embodiment of the present invention and a semiconductor device or an electronic component. The robot 6400 including the secondary battery of one embodiment of the present invention can be a highly reliable electronic device that can operate for a long time.

FIG. 30C illustrates an example of a flying object. A flying object 6500 illustrated in FIG. 30C includes propellers 6501, a camera 6502, a secondary battery 6503, and the like and has a function of flying autonomously.

For example, image data taken by the camera 6502 is stored in an electronic component 6504. The electronic component 6504 can analyze the image data to detect whether there is an obstacle in the way of the movement. Moreover, the electronic component 6504 can estimate the remaining battery level from a change in the power storage capacity of the secondary battery 6503. The flying object 6500 further includes the secondary battery 6503 of one embodiment of the present invention. The flying object 6500 including the secondary battery of one embodiment of the present invention can be a highly reliable electronic device that can operate for a long time.

This embodiment can be implemented in appropriate combination with the other embodiments.

### Embodiment 6

In this embodiment, examples of vehicles each including the secondary battery of one embodiment of the present invention will be described.

The use of secondary batteries in vehicles enables production of next-generation clean energy vehicles such as hybrid electric vehicles (HVs), electric vehicles (EVs), and plug-in hybrid electric vehicles (PHVs).

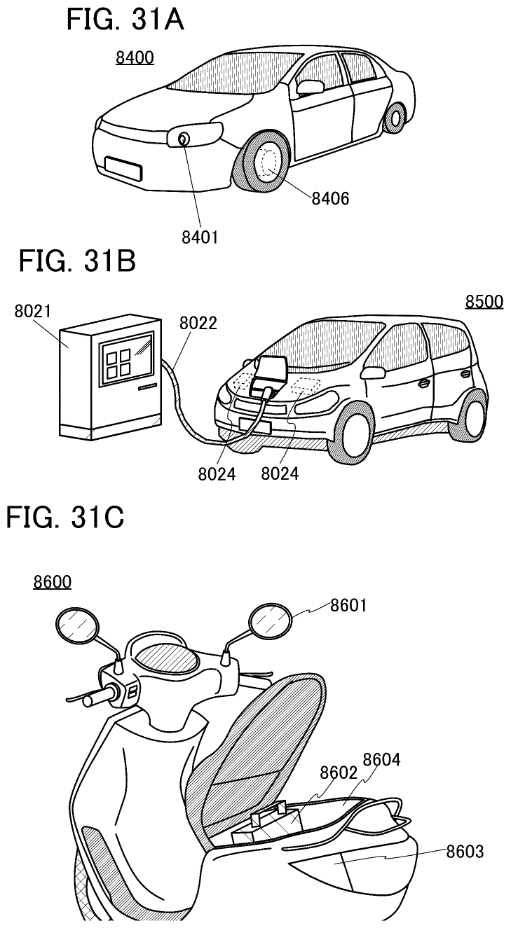

FIG. 31A to FIG. 31C illustrates examples of a vehicle including the secondary battery of one embodiment of the present invention. An automobile 8400 illustrated in FIG. 31A is an electric vehicle that runs on the power of an electric motor. Alternatively, the automobile 8400 is a hybrid electric vehicle capable of running appropriately using either an electric motor or an engine as a power source. The use of one embodiment of the present invention achieves a high-mileage vehicle. The automobile 8400 includes the secondary battery. As the secondary battery, the modules of the secondary batteries illustrated in FIG. 26C and FIG. 26D are preferably arranged to be used in a floor portion in the automobile. Alternatively, a battery pack in which a plurality of secondary batteries illustrated in FIG. 28 are combined may be placed in the floor portion in the automobile. The secondary battery can be used not only for driving an electric motor 8406, but also for supplying electric power to a light-emitting device such as a headlight 8401 or a room light (not illustrated).

The secondary battery can also supply electric power to a display device included in the automobile 8400, such as a speedometer or a tachometer. Furthermore, the secondary battery can supply electric power to a semiconductor device included in the automobile 8400, such as a navigation system.

An automobile 8500 illustrated in FIG. 31B can be charged when the secondary battery included in the automobile 8500 is supplied with electric power through external charge equipment by a plug-in system, a contactless power feeding system, and/or the like. FIG. 31B illustrates a state where a secondary battery 8024 included in the automobile 8500 is charged with the use of a ground-based charging apparatus 8021 through a cable 8022. Charge can be performed as appropriate by a given method such as CHAdeMO (registered trademark) or Combined Charging System as a charging method, the standard of a connector, or the like. It is preferable that the charging apparatus 8021 be a charge station provided in a commerce facility or a power supply in a house. For example, with the use of a plug-in technique, the secondary battery 8024 included in the automobile 8500 can be charged by being supplied with electric power from outside. The charge can be performed by converting AC electric power into DC electric power through a converter such as an ACDC converter.

Although not shown, the vehicle may include a power receiving device so that it can be charged by being supplied with electric power from an above-ground power transmitting device in a contactless manner. In the case of the contactless power feeding system, by fitting a power transmitting device in a road or an exterior wall, charge can be performed not only when the vehicle is stopped but also when driven. In addition, the contactless power feeding system may be utilized to perform transmission and reception of electric power between vehicles. Furthermore, a solar cell may be provided in the exterior of the vehicle to charge the secondary battery when the vehicle stops or moves. To supply electric power in such a contactless manner, an electromagnetic induction method or a magnetic resonance method can be used.

FIG. 31C illustrates an example of a motorcycle including the secondary battery of one embodiment of the present invention. A motor scooter 8600 illustrated in FIG. 31C includes a secondary battery 8602, side mirrors 8601, and direction indicators 8603. The secondary battery 8602 can supply electric power to the direction indicators 8603.

In the motor scooter 8600 illustrated in FIG. 31C, the secondary battery 8602 can be held in an under-seat storage 8604. The secondary battery 8602 can be held in the under-seat storage 8604 even when the under-seat storage 8604 is small. The secondary battery 8602 is detachable; thus, the secondary battery 8602 is carried indoors when charged, and can be stored before the motor scooter is driven.

According to one embodiment of the present invention, the secondary battery can have improved cycle performance and the discharge capacity of the secondary battery can be increased. Thus, the secondary battery itself can be made more compact and lightweight. The compact and lightweight secondary battery contributes to a reduction in the weight of a vehicle, and thus increases the mileage. Furthermore, the secondary battery included in the vehicle can be used as a power source for supplying electric power to products other than the vehicle. In such a case, the use of a commercial power supply can be avoided at peak time of electric power demand, for example. Avoiding the use of a commercial power supply at peak time of electric power demand can contribute to energy saving and a reduction in carbon dioxide emissions. Moreover, the secondary battery with excellent cycle performance can be used over a long period; thus, the use amount of rare metals typified by cobalt can be reduced.

This embodiment can be implemented in appropriate combination with the other embodiments.

### Example 1

### [AC Impedance Test and Nail Penetration Test]

A secondary battery using a positive electrode active material of one embodiment of the present invention in a fully charged state was subjected to an AC impedance test, and then a nail penetration test was performed as a safety test. A method for manufacturing the secondary battery used for the nail penetration test is described below.

### <Manufacture of Positive Electrode Active Material>

The positive electrode active materials manufactured in this example are described with reference to the manufacturing method shown in FIG. 21 and FIG. 22 to FIG. 22C.

As LiCoO₂ in Step S14 in FIG. 21, commercially available lithium cobalt oxide (CELLSEED C-10N manufactured by NIPPON CHEMICAL INDUSTRIAL CO., LTD.) including cobalt as the transition metal M and not including any additive element was prepared and sieved with an automatic sieving machine. As the initial heating in Step S15, heating was performed on the lithium cobalt oxide put in a saggar covered with a lid, in a roller hearth kiln simulator furnace (manufactured by NORITAKE CO., LIMITED) as a baking furnace at 850° C. for two hours. Air (compressed air which was sufficiently dried) was made to flow at 10 L/min in the furnace. Specifically, the width of an opening of an outlet was adjusted such that a differential pressure gauge in the furnace read 5 Pa. Cooling in the furnace was performed at a rate of 200° C./h, with the air keeping on flowing until the temperature reached 200° C.

In this example, in accordance with Step S21 shown in FIG. 22A, LiF and MgF₂ were prepared as the F source and the Mg source, respectively. Weighing was performed such that LiF:MgF₂=1:3 (molar ratio), and sieved by an automatic sieving machine. Then, the LiF and MgF₂ were mixed in dehydrated acetone at a rotational speed of 500 rpm for 20 hours to give an additive element source (A1 source).

Next, in Step S31, the A1 source and the lithium cobalt oxide after the initial heating were mixed by a dry method. The resulting mixture was stirred at a rotational speed of 3000 rpm for 10 minutes using a picobond (manufactured by HOSOKAWA MICRON CORPORATION) as a mixing means and sieved by an automatic sieving machine to give the mixture 903 (Step S32).

Next, as Step S33, the mixture 903 was heated. The heating conditions were 900° C. and 20 hours. During the heating, the sagger where the mixture 903 was put was covered with a lid. Covering the sagger with the lid makes it possible for the sagger to be filled with an atmosphere including oxygen and the leakage of the oxygen to be blocked (O₂ purging). As a heating furnace, a roller hearth kiln simulator furnace (manufactured by NORITAKE CO., LIMITED) was used. Oxygen was made to flow at 10 L/min in the furnace (O₂ flow). Specifically, the width of an opening of an outlet was adjusted such that a differential pressure gauge in the furnace read 5 Pa (the pressure in the furnace was positive). Cooling in the furnace was performed at a rate of 200° C./h, with the oxygen keeping on flowing until the temperature reached 200° C. In this manner, a composite oxide including Mg and F was obtained (Step S34a).

Then, nickel hydroxide subjected to a grinding step was prepared as a nickel source and aluminum hydroxide subjected to a grinding step was prepared as an aluminum source in accordance with Step S41 to Step S43 shown in FIG. 22C, and they were used as the additive element source (the A2 source). In accordance with Step S51, the nickel hydroxide, the aluminum hydroxide, and the composite oxide were weighed such that the nickel in the nickel hydroxide was 0.5 mol % with respect to the cobalt and the aluminum in the aluminum hydroxide was 0.5 mol % with respect to the cobalt, and the A2 source and the composite oxide were mixed by a dry method. As the mixing means, a picobond (manufactured by HOSOKAWA MICRON) was used and the mixture was stirred at a rotational speed of 3000 rpm for 10 minutes to give the mixture 904 (Step S52).

Next, in Step S53, the mixture 904 was heated. The heating conditions were 850° C. and 10 hours. During the heating, the sagger where the mixture 904 was put was covered with a lid. A roller hearth kiln simulator furnace (manufactured by NORITAKE CO., LIMITED) was used as a heating furnace, the saggar was put in the furnace, and heating was performed at the above heating temperature. Oxygen was made to flow at 10 L/min in the furnace (O₂ flow). The width of an opening of an outlet was adjusted such that a differential pressure gauge in the furnace read 5 Pa. Cooling in the furnace was performed at a rate of 200° C./h, with the oxygen keeping on flowing until the temperature reached 200° C. In this manner, lithium cobalt oxide including Mg, F, Ni, and Al was obtained (Step S54). The positive electrode active material 100 obtained in this manner was Sample 1.

### <Manufacture of Positive Electrode>

Sample 1 above, acetylene black (AB), and poly(vinylidene fluoride) (PVDF) were prepared as a positive electrode active material, a conductive material, and a binding agent, respectively. The PVDF prepared was one dissolved in advance in N-methyl-2-pyrrolidone (NMP) with a weight ratio of 5%. Next, a slurry was formed by performing mixing at the positive electrode active material:AB:PVDF=95:3:2 (weight ratio). As a solvent of the slurry, NMP was used. The slurry was applied to an aluminum positive electrode current collector, and then the solvent was volatilized. The aluminum positive electrode current collector had a thickness of 20 μm and was confirmed to have mirror surfaces.

After the solvent was volatilized, pressing treatment was performed with a roller press machine to increase the density of the positive electrode active material layer. As a pressing treatment condition, a linear pressure was 210 kN/m. Note that the temperature of each of an upper roll and a lower roll of the roller press machine was set to 120° C. At 120° C., PVDF was dissolved. After the pressing, the thickness of the positive electrode active material layer was larger than or equal to 76 μm and smaller than or equal to 77 μm.

Through the above process, a positive electrode including Sample 1 was obtained.

### <Manufacture of Negative Electrode>

As the negative electrode active material, a carbon material, specifically spherical natural graphite, was prepared. SBR and CMC were prepared as a binder and a thickener, respectively. Carbon fiber (VGCF (registered trademark) manufactured by SHOWA DENKO K.K.) was prepared as a conductive material. Then, slurry mixed at spherical natural graphite:VGCF:CMC:SBR=97:1:1:1 (weight ratio) was manufactured. As a solvent of the slurry, water was used. The slurry was applied to a copper negative electrode current collector, and then the solvent was volatilized. The thickness of the copper negative electrode current collector was 18 μm.

After that, pressing treatment was performed with a roller press machine to increase the density of the negative electrode active material layer after the solvent was volatilized. As a pressing treatment condition, a linear pressure was 28 KN/m, which was lower than the linear pressure for the positive electrode. After the pressing, the thickness of the negative electrode active material layer was larger than or equal to 122 μm and smaller than or equal to 124 μm.

Through the above process, the negative electrode was obtained.

### <Electrolyte>

As an electrolyte, an electrolyte solution was prepared by dissolving lithium hexafluorophosphate (LiPF₆) at 1 mol/L in a mixed organic solvent including EC (ethylene carbonate) and DEC (diethyl carbonate) at EC:DEC=30:70 (volume ratio). Note that no additive agent was used. The table below shows structure formulae, flash points, boiling points, and melting points of EC and DEC.

TABLE 2

| | EC | |
|---|---|---|
| | Ethylene | DEC |
| Name | Carbonate | Diethyl Carbonate |
| Structural formula | 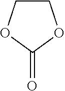 | 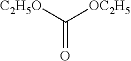 |
| Flash point (° C.) | 143 | 25 |
| Boiling point (° C.) | 238 | 127 |
| Melting point (° C.) | 38 | −43 |

Here, the injection amount of the electrolyte solution is described. In this example, in order to examine the influence of the injection amount on the nail penetration test, a cell including Electrolyte Solution A whose injection amount is appropriate for the secondary battery subjected to the nail penetration test (injection amount: 100%), a cell including Electrolyte Solution B whose injection amount is 75% of that of Electrolyte Solution A (a 25% reduction from Electrolyte Solution A), and a cell including Electrolyte Solution C whose injection amount is 50% of that of Electrolyte Solution A (a 50% reduction from Electrolyte Solution A) were prepared. That is, the injection amount of each of Electrolyte Solution B and Electrolyte Solution C was smaller than that of Electrolyte Solution A as appropriate. In the case where the volume of the stack of the positive electrode and the negative electrode of each of Cell A to Cell C was 16.7 cm³, the liquid amount of Electrolyte Solution A satisfied 89% of the above volume, the liquid amount of Electrolyte Solution B satisfied 75% of the above volume, and the liquid amount of Electrolyte Solution C satisfied 45% of the above volume.

### <Separator>

As the separator, a 25-μm-thick porous polypropylene film was used.

### <Exterior Body>

As the exterior body, an aluminum laminated film was used. The aluminum laminate film includes first polypropylene (with a thickness of 22.5 μm), second polypropylene (with a thickness of 22.5 μm), aluminum foil (with a thickness of 40 μm), an adhesive layer (with a thickness of 3 μm) and nylon (with a thickness of 25 μm) in this order from the inside of the exterior body.

### <Manufacture of Secondary Battery for Nail Penetration Test>

A lithium-ion secondary battery (Cell A) was manufactured using a positive electrode including Sample 1 formed above, the negative electrode formed above, Electrolyte Solution A described above, the separator, and the exterior body. Moreover, a lithium-ion secondary battery (Cell B) substituting Electrolyte Solution B for Electrolyte Solution A above was manufactured. A lithium-ion secondary battery (Cell C) substituting Electrolyte Solution C for Electrolyte Solution A above was manufactured. After electrolyte solutions with predetermined injection amounts were injected into Cell A to Cell C, the cells were sealed under reduced pressure at −60 kPa with the use of a degassing sealer capable of reducing pressure.

The outer sizes of Cell A, Cell B, and Cell C were 76 mm×89 mm. In each of the cells, the area of the positive electrode applied to one side of the current collector was approximately 20.5 cm² and the area of the negative electrode was approximately 23.8 cm². In each of the secondary batteries, the area of the negative electrode is preferably larger than the area of the positive electrode, and is preferably more than or equal to 1.1 times and less than or equal to 1.3 times the area of the positive electrode. Fifteen positive electrodes Fifteen positive electrodes in each of which both surfaces were coated with positive electrode active material layers were prepared. Fourteen negative electrodes in which both surfaces were coated with a negative electrode active material layer were prepared and two negative electrodes in which one surface was coated with a negative electrode active material layer were prepared. The positive electrodes and the negative electrodes were stacked so as to face each other. A separator was placed between the positive electrode and the negative electrode. Since the negative electrode in which one surface was coated with the negative electrode active material layer is positioned on the outermost surface, there was a region where the current collector of the negative electrode is in contact with the exterior body.

Each of the secondary batteries of Cell A, Cell B, and Cell C was assembled such that the positive electrode active material loading level and the negative electrode active material loading level were equal to each other. Specifically, adjustment was performed such that the targeted positive electrode active material loading level was higher than or equal to 20 mg/cm² and lower than or equal to 22 mg/cm² and the targeted negative electrode active material loading level was higher than or equal to 13 mg/cm² and lower than or equal to 15 mg/cm². Note that when the active material layers are formed on both surfaces of the current collector, the positive electrode active material loading level and the negative electrode active material loading level are represented by a value per active material layer on one surface of the current collector.

In each of Cell A, Cell B, and Cell C, the proportion of negative electrode capacity to positive electrode capacity (%) was higher than or equal to 80% and lower than or equal to 90%, preferably higher than or equal to 83% and lower than or equal to 85%. The proportion of negative electrode capacity to positive electrode capacity (%) refers to the proportion of the capacity of the negative electrode to the capacity of the positive electrode calculated on the assumption that the product of the loading level, the charge capacity of the active material (a capacity of 200 mAh/g per weight of the positive electrode active material and a capacity of 300 mAh/g per weight of the negative electrode active material at the time of charging at a charge voltage of 4.5 V (graphite counter electrode), and the area is the capacity.

The table below lists the manufacturing conditions of the secondary batteries for the nail penetration test.

TABLE 3

| Sample | | Cell A | Cell B | Cell C |
|---|---|---|---|---|
| Positive | Active material | LCO (Addition of Mg, F, Al, and Ni) | | |
| electrode | Binder | PVDF | | |
| | Conductive additive | Acetylene black | | |
| | Loading level (on one surface) | 21.5 mg/cm² | 21.3 mg/cm² | 21.4 mg/cm² |
| | Material property/thickness | Al (both mirror surfaces)/20 μm | | |
| | of current collector foil | | | |
| | Thickness of active material | 76 μm | 77 μm | 77 μm |
| | layer (average on one surface) | | | |
| | Pressing pressure condition | 210 kN/m | | |
| Negative | Active material | Spherical natural graphite | | |
| electrode | Binder and thickener | SBR and CMC | | |
| | Conductive additive | VGCF | | |
| | Loading level (on one surface) | 14.6 mg/cm² | 14.3 mg/cm² | 14.4 mg/cm² |
| | Material property/thickness | Cu/18 μm | | |
| | of current collector | | | |
| | Thickness of active material | 122 μm | 124 μm | 123 μm |
| | layer (average on one surface) | | | |
| | Pressing pressure condition | 28 kN/m | | |
| Separator | Material property/thickness | PP (polypropylene)/25 μm | | |
| Electrolyte | Main solvent/additive agent | EC:DEC (3:7)/not included | | |
| solution | Lithium salt | 1M LiPF₆ | | |
| Cell | Number of positive electrodes | 15 pieces (double-side coated) | | |
| condition | Number of negative electrodes | 14 pieces (double-side coated) + 2 pieces (one-side coated) | | |
| | | on outer side | | |
| | Exterior body | Aluminum laminated | | |
| | | (1_PP 22.5 μm\2_PP 22.5 μm\ | | |
| | | Al 40 μm\Adhesive layer 3 μm\ | | |
| | | Nylon 25 μm) | | |
| | Injection amount (ratio) | 100% | 75% | 50% |
| | Proportion of negative | 84.6 | 83.2 | 84.9 |
| | electrode capacity to positive | | | |
| | electrode capacity (%) | | | |

### <Aging>

First, aging was performed on Cell A, Cell B, and Cell C. The table below shows the aging methods of Cell 1A, Cell 1B, and Cell 1C. Note that aging is sometimes referred to as initial charging and discharging or conditioning. In the table below, 1 C is 200 mA/g (per weight of a positive electrode active material). Step A4 in the table below is referred to as degasification resealing. The ambient temperature in the table below allows an error of ±5° C.

TABLE 4

| | | |
|---|---|---|
| [symbol] | Charging/ | 0.01 C. Ambient temperature of 23° C. [symbol] |
| | discharging [symbol] | Terminated when either of termination voltage of |
| | | 4.5 V and termination capacitor of 15 mAh/g is |
| | | satisfied. [symbol] |
| Step A1 [symbol] | Constant current | 0.1 C. Ambient temperature of 23° C. [symbol] |
| | charging [symbol] | Terminated when either of termination voltage of |
| | | 4.5 V and termination capacitor of 105 mAh/g is |
| | | satisfied. [symbol] |
| Step A2 [symbol] | Constant current | Left to stand in thermostatic chamber at 60° C. for |
| | charging [symbol] | 24 hours. [symbol] |
| Step A3 [symbol] | Not performed [symbol] | Open one edge of cell in glove box and perform |
| | | resealing in reduced-pressure environment of −60 |
| | | kPa. [symbol] |
| Step A4 [symbol] | Not performed [symbol] | 0.1 C, 4.5 V. Ambient temperature of 23° C. [symbol] |
| | | Terminated when either of termination current of |
| | | 0.01 C or lower and termination time of 10 hours is |
| | | satisfied. [symbol] |
| Step A5 [symbol] | Constant current- | 0.2 C. Ambient temperature of 23° C. [symbol] |
| | constant voltage | Terminated when either of termination voltage of |
| | charging [symbol] | 2.5 V and termination time of 8 hours is satisfied. [symbol] |
| Step A6 [symbol] | Constant current | 0.2 C, 4.5 V. Ambient temperature of 23° C. [symbol] |
| | discharging [symbol] | Terminated when either of termination current of |
| | | 0.02 C or lower and termination time of 8 hours is |
| | | satisfied. [symbol] |
| Step A7 [symbol] | Constant current- | 0.2 C. Ambient temperature of 23° C. [symbol] |
| | constant voltage | Terminated when either of termination voltage of |
| | charging [symbol] | 2.5 V and termination time of 8 hours is satisfied. [symbol] |
| Step A8 [symbol] | Constant current | 0.01 C. Ambient temperature of 23° C. [symbol] |
| | discharging [symbol] | Terminated when either of termination voltage of |
| | | 4.5 V and termination capacitor of 15 mAh/g is |
| | | satisfied. [symbol] |

*Step A7 and Step A8 are each repeated three times in total. #z,35;

### <Charge Capacity Measurement>

After the aging treatment, Cell A to Cell C were fully charged in accordance with Step A7 in Table 4, and the charge capacity of the cells was measured. As a charge-discharge measuring instrument for measuring charge capacity, a charge-discharge measuring system (TOSCAT-3000) manufactured by TOYO SYSTEM Co., LTD. was used. The table below shows the charge capacity of Cell A to Cell C in a fully charged state. Since three cells were prepared under each condition, n=1, n=2, and n=3 are shown in the table below. In each of the cells, charge capacity showed a value close to a set capacity (also referred to as a design capacity) of 2500 mAh, and abnormality of the charge capacity was not observed in each of the cells.

TABLE 5

| Condition | n = 1 | n = 2 | n = 3 |
|---|---|---|---|
| Cell A | 2399 mAh | 2426 mAh | 2451 mAh |
| Cell B | 2432 mAh | 2391 mAh | 2390 mAh |
| Cell C | 2326 mAh | 2322 mAh | 2323 mAh |

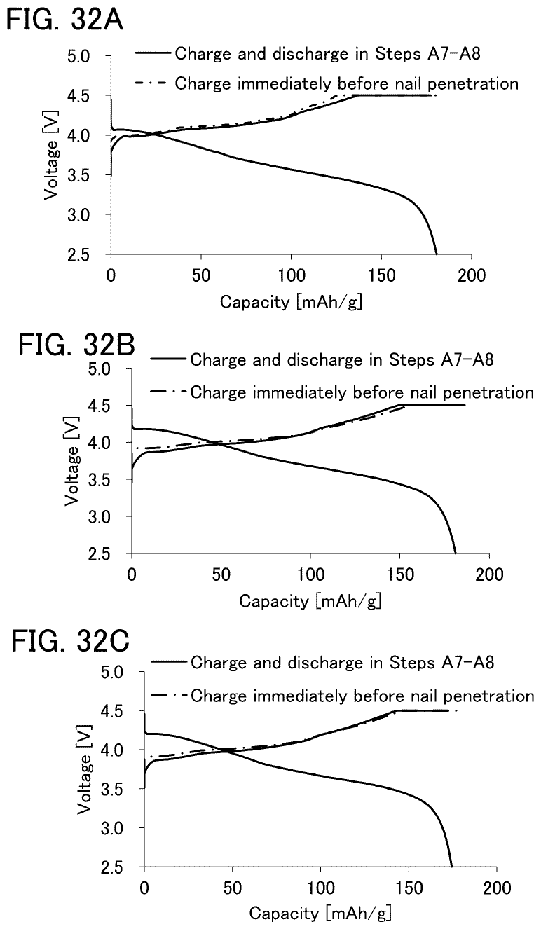

FIG. 32A shows a charge-discharge curve of Cell A at the time of aging treatment (Steps A7 to A8) and a charge curve immediately before nail penetration, which overlap with each other. FIG. 32B shows a charge-discharge curve of Cell B at the time of the aging treatment (Steps A7 to A8) and a charge curve immediately before nail penetration, which overlap with each other. FIG. 32C shows a charge-discharge curve of Cell A at the time of aging treatment (Steps A7 to A8) and a charge curve immediately before nail penetration, which overlap with each other. As for each of the charge-discharge curves, the horizontal axis represents capacity (mAh/g, capacity per weight of the positive electrode active material) and the vertical axis represents voltage (V). FIG. 32A to FIG. 32C show no abnormality in the charge-discharge curves of the cells, indicating that the charge capacity per weight of the positive electrode active material is higher than or equal to 170 mAh/g, preferably higher than or equal to 180 mAh/g at an upper limit voltage of 4.5 V.

### <AC Impedance Measurement>

Cell A to Cell C in the above fully charged state were subjected to AC impedance measurement. Specifically, the AC impedance measurement was started within two hours from the time when Cell A to Cell C were brought into the fully charged state. As an apparatus used for the AC impedance measurement, VMP3 (multi-Ch potentio/galvanostat) manufactured by Bio-Logic Science Instruments was used. The measurement conditions were as follows: the amplitude voltage was 10 mV, the frequency was swept in the range from 200 kHz to 10 mHz, and then an impedance value corresponding to 1 kHz was extracted. As the frequency closest to 1 kHz, 1001.6 Hz was used. Note that at the time of sweeping, 10 points were measured for one digit. The temperature of the measurement environment was set to 25° C.

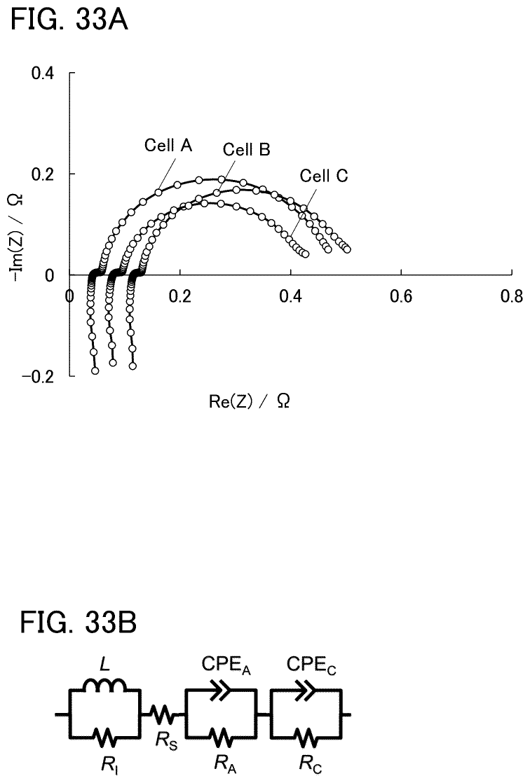

FIG. 33A shows a Nyquist diagram as the measurement results of the AC impedance measurement. FIG. 33B shows an equivalent circuit used for analysis of the measurement data of the AC impedance measurement. Fitting calculation was performed using the equivalent circuit in FIG. 33B on the basis of the Nyquist diagram in FIG. 33A. For analysis of the data including the data/that of the fitting calculation, measurement and analysis software EC-Lab Z fit manufactured by Bio-Logic Science Instruments was used.

Note that in FIG. 33B, R_{I}, L, R_{S}, R_{A}, R_{C}, and (CPE) constant phase elements are arranged in the equivalent circuit on the assumption that R₁ corresponds to the resistance due to a lead and a wiring of the battery, L corresponds to the inductance due to the lead and the wiring of the battery, R_{S} corresponds to the resistance of the electrolyte solution and the electric resistance of the electrode, R_{A} corresponds to the resistance due to a coating film on the positive electrode surface, the resistance due to a coating film on the negative electrode surface, and charge transfer resistance on the negative electrode surface (resistance due to solvation and desolvation of Li ions and extraction and insertion of Li ions from and into the active material), R_{C} corresponds to charge transfer resistance on the positive electrode surface (resistance due to solvation and desolvation of Li ions and extraction and insertion of Li ions from and into the active material), and CPEs correspond to capacitance components in the porous electrodes.

The table below shows the values of the impedance at a frequency of 1 kHz of Cell A to Cell C as the analysis results of the AC impedance measurement. The cell corresponding to n=1 of Cell B has a unique impedance value of 120 mΩ, but the others have impedance values less than 90 mΩ. A variation in the impedance at 1 KHz is small in Cell A but is large in each of Cell B and Cell C. This suggests that variations in impedance may be derived from the injection amount.

TABLE 6

| Condition | n = 1 | n = 2 | n = 3 |
|---|---|---|---|
| Cell A | 46 mΩ | 63 mΩ | 62 mΩ |
| Cell B | 120 mΩ | 45 mΩ | 59 mΩ |
| Cell C | 84 mΩ | 35 mΩ | 57 mΩ |

### <Nail Penetration Test>

After the AC impedance measurement, Cell A to Cell C in a fully charged state were subjected to a nail penetration test. For the nail penetration test, an advanced safety tester (manufactured by ESPEC CORP.) was used as the tester illustrated in FIG. 1A and FIG. 1B, and the tester was set in an environment at 25° C.

Before the nail penetration test, it was confirmed that the temperature of the exterior body of each of Cell A, Cell B, and Cell C was 22° C. In this example, a temperature sensor was placed at a distance of 2 cm from the nail hole, and the value obtained with the temperature sensor was used as the temperature of the exterior body. Note that by placing the temperature sensor in the same position, there is presumed to be no difference or an extremely small difference in the temperature of the exterior body among Cell A, Cell B, and Cell C even in the case where the temperature gradient in the exterior body is taken into consideration.

As the nail 1003 in FIG. 1A, a nail having a diameter of 3 mm was used. The nail penetration speed was 5 mm/sec. The depth of nail penetration was the thickness of the secondary battery+5 mm. The other conditions in the nail penetration test were compliant with SAE J2464, “Electric and Hybrid Electric Vehicle Rechargeable Energy Storage System (RESS) Safety and Abuse Testing”.

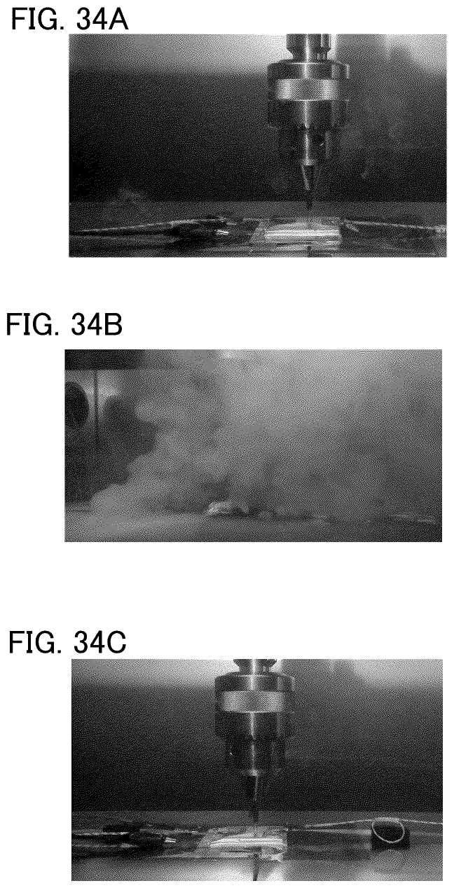

FIG. 34A shows the state of the nail penetration test of Cell A (n=1), FIG. 34B shows the state of the nail penetration test of Cell B (n=1), and FIG. 34C shows the state of the nail penetration test of Cell C (n=1). As shown in FIG. 34A and FIG. 34C, it was determined that Cell A (n=1) and Cell C (n=1) showed no ignition because they did not ignite or only a small amount of smoke from them was observed. A large amount of smoke and fire were observed from Cell B (n=1) and it was determined that Cell B ignited. Although the states of Cell A (n=2, 3) to Cell C (n=2, 3) are not shown, it was determined each of them did not ignite. The table below shows determination in the nail penetration test.

TABLE 7

| Condition | n = 1 | n = 2 | n = 3 |
|---|---|---|---|
| Cell A | No ignition | No ignition | No ignition |
| Cell B | Ignition | No ignition | No ignition |
| Cell C | No ignition | No ignition | No ignition |

Cell A to Cell C that satisfied an impedance value of less than 90 mΩ at 1 KHz did not ignite, whereas Cell A to Cell C that had a unique impedance value of 120 mΩ at 1 KHz ignited. That is, it is found that the impedance of a safe secondary battery that does not ignite in the nail penetration test in this example is preferably less than 90 mΩ, further preferably less than or equal to 80 mΩ, still further preferably less than or equal to 60 mΩ at 1 KHz. Unexpectedly, not the injection amount but the impedance value is found to relate to the conditions in which the secondary battery ignites in the nail penetration test.

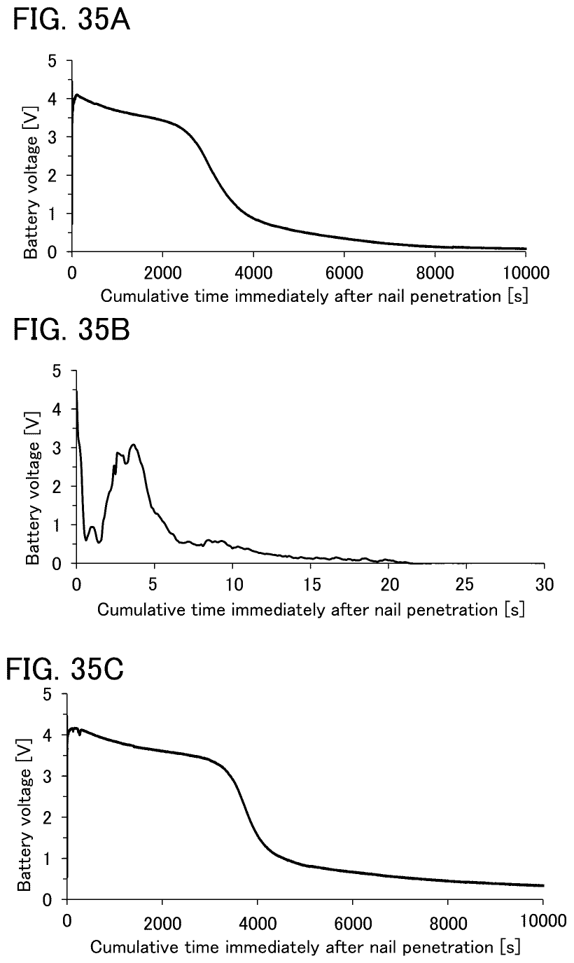

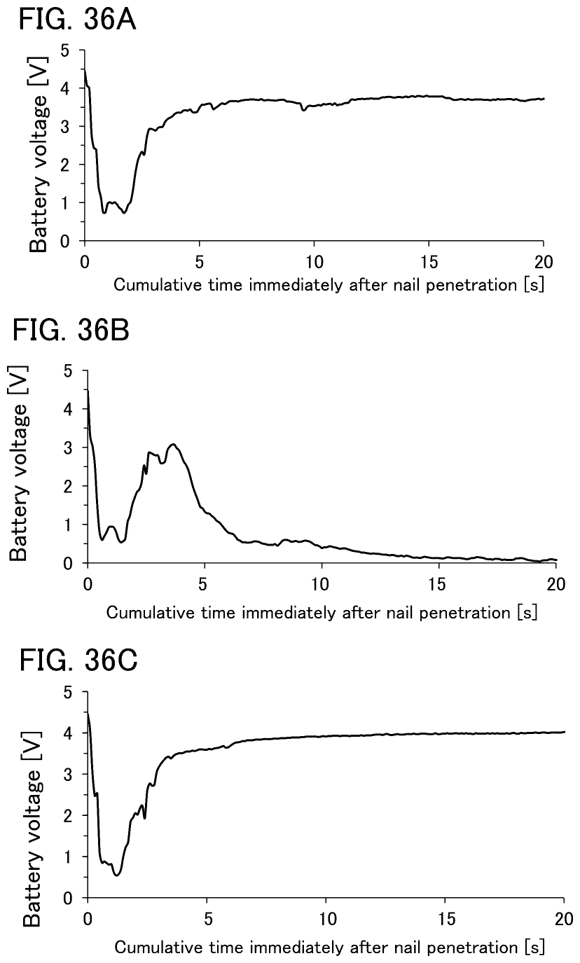

FIG. 35A is a graph showing a voltage change of Cell A (n=1) in the nail penetration test. FIG. 35B is a graph showing a voltage change of Cell B (n=1) in the nail penetration test. FIG. 35C is a graph showing a voltage change of Cell C (n=1) in the nail penetration test. FIG. 36A to FIG. 36C are graphs in which the maximum values on the horizontal axes in FIG. 35A to FIG. 35C are all set to 20 seconds.

It is found from FIG. 35A to FIG. 35C that the battery voltage decreases gradually in Cell A and Cell C immediately after the nail penetration operation. According to FIG. 36A to FIG. 36C, the battery voltage of Cell A to Cell C rapidly drops to approximately less than or equal to 1.0 V immediately after the nail penetration operation, specifically, before 2 seconds had elapsed, and the battery voltage of Cell A and Cell C exhibited unique behavior of increasing to approximately 3.0 V immediately after the rapid drop. The battery voltage of Cell B also increased to 3.0 V, and then rapidly decreased to 0 V.

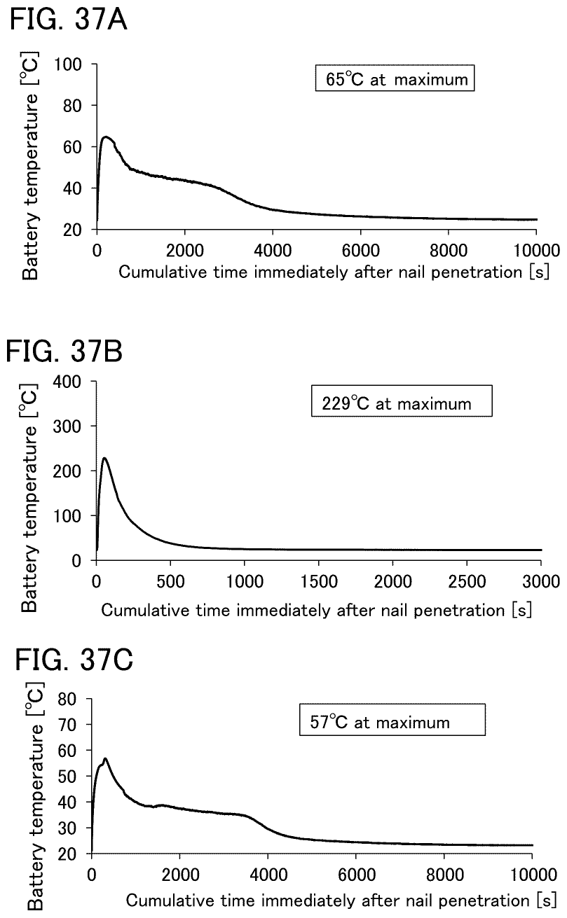

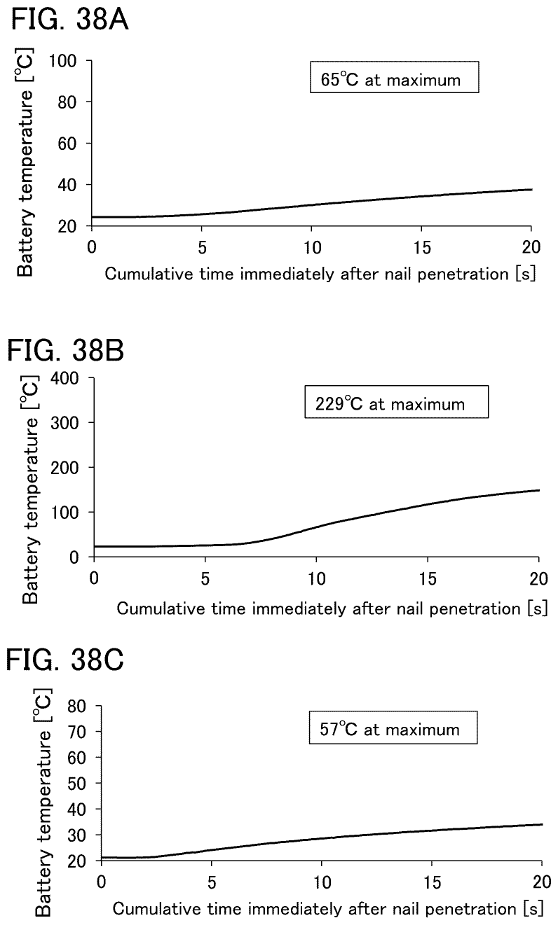

FIG. 37A shows a temperature change of Cell A (n=1) in the nail penetration test. FIG. 37B shows a temperature change of Cell B (n=1) in the nail penetration test. FIG. 37C shows a temperature change of Cell C (n=1) in the nail penetration test. FIG. 38A to FIG. 38C are graphs in which the maximum values on the horizontal axes in FIG. 37A to FIG. 37C are all set to 20 seconds. There was no difference in the temperature change between Cell A to Cell C until 20 seconds had elapsed, the temperature increased gradually after the nail penetration, and no rapid temperature change was observed.

The battery temperature (the temperature of the exterior body obtained from the temperature sensor) becomes the highest temperature immediately after the nail penetration operation, and the temperatures of Cell A, Cell B, and Cell C increased to 65° C., 229° C., and 57° C., respectively. The temperature which is presumed to be increased by heat generation in the nail penetration test is a difference obtained by subtracting 22° C. from the maximum value obtained with the temperature sensor (which is referred to as temperature rise ΔT). The temperature rise ΔT of Cell A was 43° C., the temperature rise ΔT of Cell B was 207° C., and the temperature rise ΔT of Cell C was 35° C. That is, it is found that the temperature rise ΔT of the cell is preferably lower than or equal to 50° C., further preferably lower than or equal to 45° C., still further preferably lower than or equal to 40° C., in order that no ignition was caused in the nail penetration test.

### REFERENCE NUMERALS

100: positive electrode active material, 100a: surface portion, 100b: inner portion, 100s: shell, 101: crystal grain boundary, 102: crack, 104: coating portion

1. A secondary battery comprising:
a positive electrode and a negative electrode,
wherein the positive electrode comprises a positive electrode active material,
wherein the positive electrode active material comprises lithium cobalt oxide comprising magnesium,
wherein a magnesium concentration in a surface portion of the positive electrode active material is higher than a magnesium concentration in an inner portion of the positive electrode active material,
wherein the negative electrode comprises a negative electrode active material,
wherein the negative electrode active material comprises a carbon material, and
wherein when the secondary battery is subjected to AC impedance measurement in a state where charging is performed until a voltage reaches 4.5 V, an AC impedance value at a frequency of 1 kHz is less than 90 mΩ.

2. A secondary battery comprising:
a positive electrode, a negative electrode, a separator, and an electrolyte,
wherein the positive electrode comprises a positive electrode active material,
wherein the positive electrode active material comprises lithium cobalt oxide comprising magnesium,
wherein a magnesium concentration in a surface portion of the positive electrode active material is higher than a magnesium concentration in an inner portion of the positive electrode active material,
wherein the negative electrode comprises a negative electrode active material,
wherein the negative electrode active material comprises a carbon material,
wherein a solvent of the electrolyte comprises ethylene carbonate and diethyl carbonate,
wherein the separator comprises polypropylene, and
wherein when the secondary battery is subjected to AC impedance measurement in a state where charging is performed until a voltage reaches 4.5 V, an AC impedance value at a frequency of 1 kHz is less than 90 mΩ.

3. A secondary battery comprising:
a positive electrode and a negative electrode,
wherein the positive electrode comprises a positive electrode active material,
wherein the positive electrode active material comprises lithium cobalt oxide comprising magnesium,
wherein a magnesium concentration in a surface portion of the positive electrode active material is higher than a magnesium concentration in an inner portion of the positive electrode active material,
wherein the negative electrode comprises a negative electrode active material,
wherein the negative electrode active material comprises a carbon material, and
wherein when the secondary battery is subjected to AC impedance measurement in a state where charging is performed until a voltage reaches 4.5 V and capacity is higher than or equal to 2000 mAh, an AC impedance value at a frequency of 1 kHz is less than 90 mΩ.

4. (canceled)

5. The secondary battery according to claim 1,
wherein when the secondary battery is subjected to a nail penetration test, a nail diameter is 3 mm, and a nail penetration speed is 5 mm/sec, a temperature rise ΔT of the secondary battery is preferably less than or equal to 50° C.

6. The secondary battery according to claim 1,
wherein the lithium cobalt oxide further comprises aluminum.

7. The secondary battery according to claim 1,
wherein the lithium cobalt oxide further comprises nickel.

8. The secondary battery according to claim 1,
wherein the lithium cobalt oxide further comprises fluorine.

9. The secondary battery according to claim 2,
wherein when the secondary battery is subjected to a nail penetration test, a nail diameter is 3 mm, and a nail penetration speed is 5 mm/sec, a temperature rise ΔT of the secondary battery is preferably less than or equal to 50° C.

10. The secondary battery according to claim 2,
wherein the lithium cobalt oxide further comprises aluminum.

11. The secondary battery according to claim 2,
wherein the lithium cobalt oxide further comprises nickel.

12. The secondary battery according to claim 2,
wherein the lithium cobalt oxide further comprises fluorine.

13. The secondary battery according to claim 3,
wherein when the secondary battery is subjected to a nail penetration test, a nail diameter is 3 mm, and a nail penetration speed is 5 mm/sec, a temperature rise ΔT of the secondary battery is preferably less than or equal to 50° C.

14. The secondary battery according to claim 3,
wherein the lithium cobalt oxide further comprises aluminum.

15. The secondary battery according to claim 3,
wherein the lithium cobalt oxide further comprises nickel.

16. The secondary battery according to claim 3,
wherein the lithium cobalt oxide further comprises fluorine.
